(19) United States
(12) Patent Application Publication
(10) Pub. No.: US 2017/0170399 A1
(43) Pub. Date: Jun. 15, 2017

(54) COMPOSITION FOR FORMING ORGANIC SEMICONDUCTOR FILM, ORGANIC SEMICONDUCTOR ELEMENT, AND METHOD FOR MANUFACTURING ORGANIC SEMICONDUCTOR ELEMENT

(71) Applicant: FUJIFILM CORPORATION, Tokyo (JP)

(72) Inventors: Kensuke MASUI, Kanagawa (JP); Toshihiro KARIYA, Kanagawa (JP); Yushi HONGO, Kanagawa (JP); Yuta SHIGENOI, Kanagawa (JP)

(21) Appl. No.: 15/444,330

(22) Filed: Feb. 28, 2017

Related U.S. Application Data
(63) Continuation of application No. PCT/JP2015/076661, filed on Sep. 18, 2015.

(30) Foreign Application Priority Data
Sep. 30, 2014 (JP) 2014-202209

(51) Int. Cl. H01L 51/00; C09D 11/108; C09D 11/03; C09D 11/52; C09D 11/38

(52) U.S. Cl. CPC H01L 51/0035; C09D 11/52; C09D 11/38; C09D 11/03; C09D 11/108; H01L 51/0074; H01L 51/0071; H01L 51/0068; H01L 51/0545

(57) ABSTRACT

An object of the present invention is to provide a composition for forming an organic semiconductor film that makes it possible to obtain an organic semiconductor film having excellent mobility and heat stability, an organic semiconductor element including an organic semiconductor film having excellent mobility and heat stability, and a method for manufacturing the organic semiconductor element.

The composition for forming an organic semiconductor film of the present invention contains a specific organic semiconductor as a component A, a binder polymer as a component B, a solvent having a naphthalene structure as a component C, and a solvent having a lower SP value than that of the component C by 2.0 MPa^{1/2} or greater and a lower boiling point than that of the component C, as a component D.

### CROSS-REFERENCE TO RELATED APPLICATIONS

This application is a continuation application of International Application No. PCT/JP2015/076661, filed Sep. 18, 2015, the disclosure of which is incorporated herein by reference in its entirety. Further, this application claims priority from Japanese Patent Application No. 2014-202209, filed Sep. 30, 2014, the disclosure of which is incorporated herein by reference in its entirety.

### BACKGROUND OF THE INVENTION

1. Field of the Invention

The present invention relates to a composition for forming an organic semiconductor film, an organic semiconductor element, and a method for manufacturing the organic semiconductor element.

2. Description of the Related Art

An organic transistor having an organic semiconductor film (organic semiconductor layer) is used in a field effect transistor (FET) used in a liquid crystal display or an organic EL display, a Radio Frequency Identifier (RFID, RF tag), and the like, because the use of the organic transistor makes it possible to achieve lightening of weight and cost reduction and to achieve flexibilization.

Various methods have been suggested as methods for preparing an organic semiconductor film. For example, as compositions for forming an organic semiconductor film, the compositions described in JP2013-516054A and JP2014-13920A are known.

### SUMMARY OF THE INVENTION

An object of the present invention is to provide a composition for forming an organic semiconductor film that makes it possible to obtain an organic semiconductor film having excellent mobility and heat stability.

Another object of the present invention is to provide an organic semiconductor element including an organic semiconductor film having excellent mobility and heat stability and a method for manufacturing the organic semiconductor element.

The above objects of the present invention were achieved by means described in the following <1>, <11>, or <12>. Preferred embodiments will be also described below in <2> to <10>.

<1> A composition for forming an organic semiconductor film comprising: an organic semiconductor as a component A; a binder polymer as a component B; a solvent having a naphthalene structure as a component C; and a solvent having a lower SP value than that of the component C by 2.0 MPa^{1/2} or greater and a lower boiling point than that of the component C, as a component D, in which the organic semiconductor has a condensed polycyclic aromatic group, the number of rings in the condensed polycyclic aromatic group is equal to or greater than 4, at least two rings in the condensed polycyclic aromatic group contains at least one atom selected from the group consisting of a sulfur atom, a nitrogen atom, a selenium atom, and an oxygen atom, and the condensed polycyclic aromatic group has, as a partial structure, at least one structure selected from the group consisting of a benzene ring, a naphthalene ring, and a phenanthrene ring.

<2> The composition for forming an organic semiconductor film described in <1>, in which the component D is alkane or cycloalkane having 6 to 20 carbon atoms.

<3> The composition for forming an organic semiconductor film described in <1>, in which the component D is alkylbenzene.

<4> The composition for forming an organic semiconductor film described in any one of <1> to <3>, in which surface energy E of the component B is equal to or lower than 30 mN/m².

<5> The composition for forming an organic semiconductor film described in any one of <1> to <4>, in which the component B is at least one resin selected from the group consisting of natural rubber, synthetic rubber, a silicone resin, a thermoplastic elastomer, and a urea resin.

<6> The composition for forming an organic semiconductor film described in any one of <1> to <5>, in which the component B is at least one selected from the group consisting of ethylene-propylene rubber, acrylonitrile-butadiene rubber, hydrogenated nitrile rubber, fluororubber, a perfluoroelastomer, a tetrafluoroethylene propylene copolymer, an ethyl ene-propyl ene-di en e copolymer, styrene-butadiene rubber, polychloroprene, polyneoprene, butyl rubber, a methyl•phenyl silicone resin, a methyl•phenylvinyl•silicone resin, a methyl•vinyl•silicone resin, a fluorosilicone resin, acrylic rubber, ethylene acrylic rubber, chlorosulfonated polyethylene, chloropolyethylene, an epichlorohydrin copolymer, a polyisoprene-natural rubber copolymer, polyisoprene rubber, a styrene-isoprene block copolymer, a polyester urethane copolymer, a polyether urethane copolymer, a polyetherester thermoplastic elastomer, and polybutadiene rubber.

<7> The composition for forming an organic semiconductor film described in any one of <1> to <6>, in which the number of rings in the condensed polycyclic aromatic group is 5 or 6.

<8> The composition for forming an organic semiconductor film described in any one of <1> to <7>, in which the organic semiconductor contains at least two heterocyclic rings, and the heterocyclic rings each contain one heteroatom.

<9> The composition for forming an organic semiconductor film described in any one of <1> to <8>, in which the organic semiconductor contains at least one kind of compound represented by any one of Formulae 1 to 16,

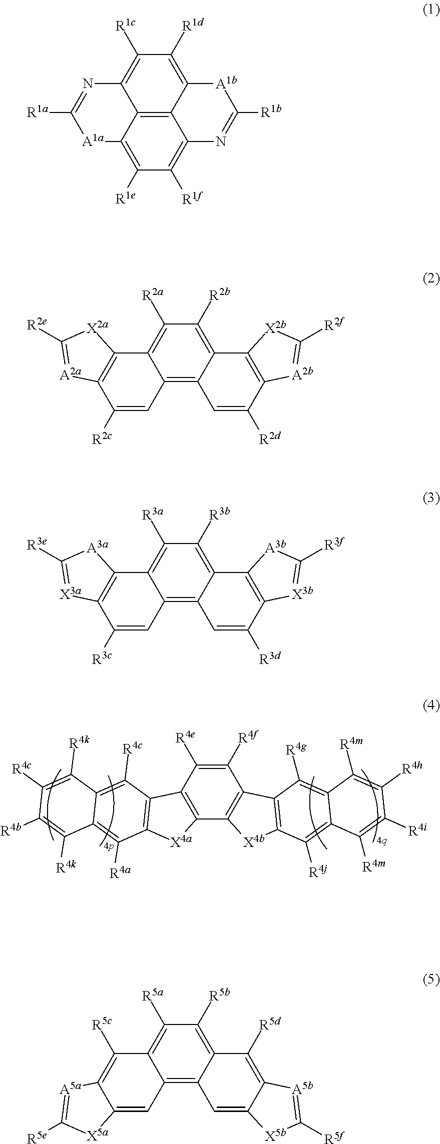

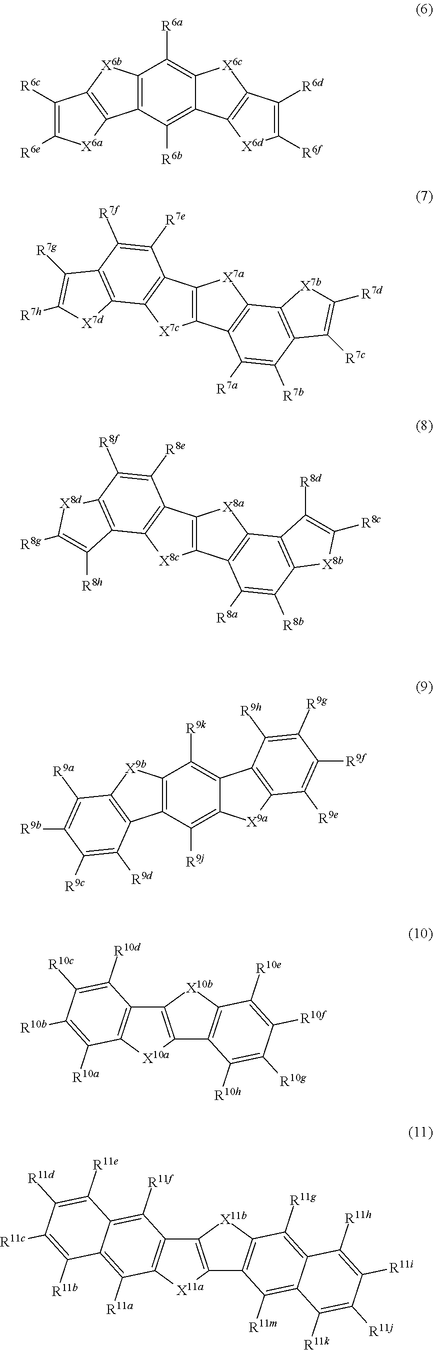

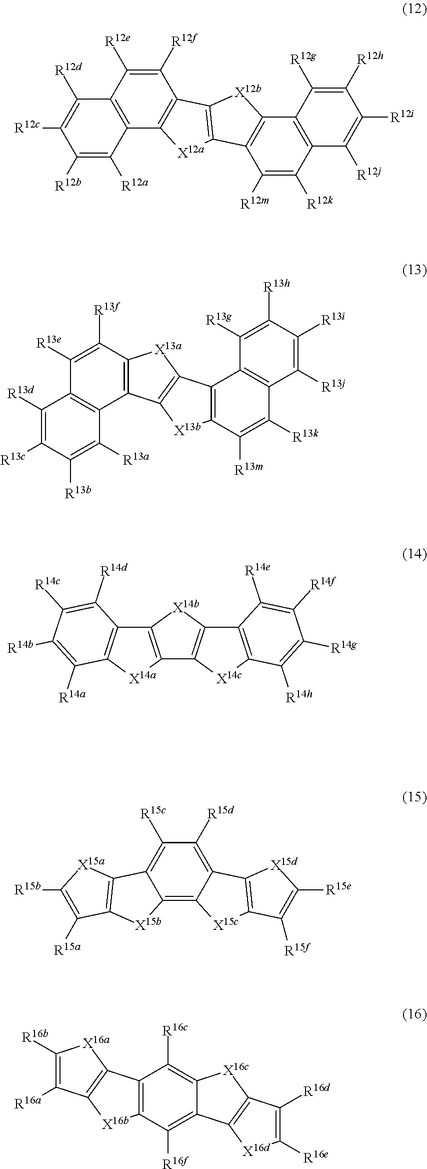

in Formula 1, A^{1a} and A^{1b} each independently represent a S atom, an O atom, or a Se atom, R^{1a} to R^{1f} each independently represent a hydrogen atom or a substituent, and at least one of R^{1a}, R^{1b}, R^{1c}, R^{1d}, R^{1e}, or R^{1f} is a group represented by the following Formula W,

-L^{W}-R^{W} (W)

in Formula W, L^{W} represents a divalent linking group which is represented by any one of the following Formula L-1 to L-25 or a divalent linking group in which two or more divalent linking groups represented by any one of the following Formulae L-1 to L-25 are bonded to each other, and R^{W} represents an alkyl group, a cyano group, a vinyl group, an ethynyl group, an oxyethylene group, an oligo-oxyethylene group in which a repetition number v of an oxyethylene unit is equal to or greater than 2, a siloxane group, an oligosiloxane group having two or more silicon atoms, or a trialkylsilyl group,

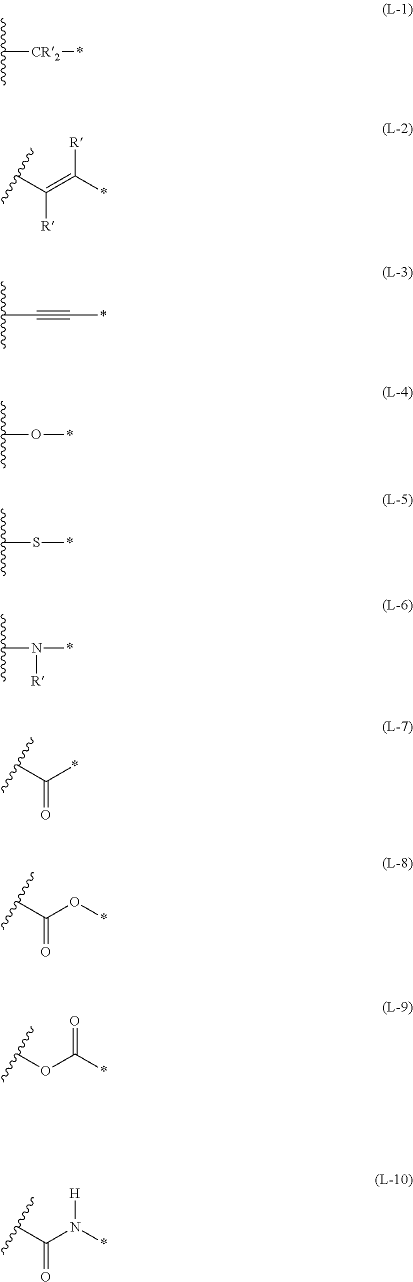

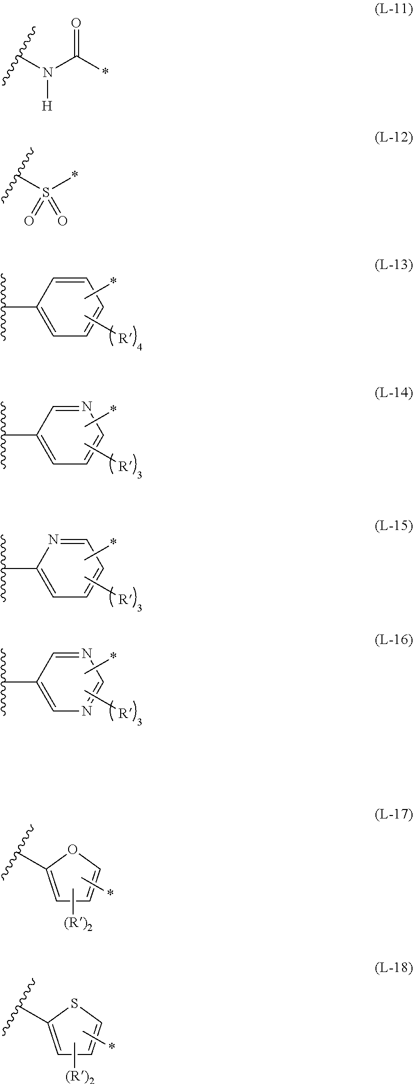

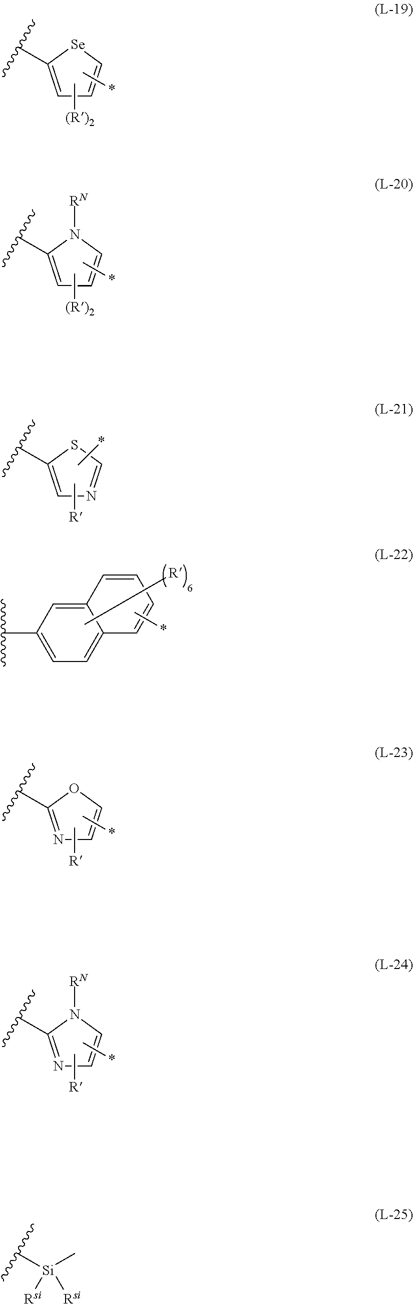

in Formulae L-1 to L-25, * represents a binding position for R^{W}, the portion of a wavy line represents the other binding position, R′ in Formulae L-1, L-2, L-6, and L-13 to L-24 each independently represent a hydrogen atom or a substituent, R^{N} in Formulae L-20 and L-24 represents a hydrogen atom or a substituent, and R^{si} in Formula L-25 each independently represent a hydrogen atom, an alkyl group, an alkenyl group, or an alkynyl group,

in Formula 2, X^{2a} and X^{2b} each independently represent NR²ⁱ, an O atom, or a S atom, A^{2a} represents CR^{2g} or a N atom, A^{2b} represents CR^{2h} or a N atom, R²ⁱ represents a hydrogen atom, an alkyl group, an alkenyl group, an alkynyl group, or an acyl group, R^{2a} to R^{2h} each independently represent a hydrogen atom or a substituent, and at least one of R^{2a}, R^{2b}, R^{2c}, R^{2d}, R^{2e}, R^{2f}, R^{2g}, or R^{2h} is a group represented by Formula W,

in Formula 3, X^{3a} and X^{3b} each independently represent a S atom, an O atom, or NR^{3g}, A^{3a} and A^{3b} each independently represent CR^{3h} or a N atom, R^{3a} to R^{3h} each independently represent a hydrogen atom or a substituent, and at least one of R^{3a}, R^{3b}, R^{3c}, R^{3d}, R^{3e}, R^{3f}, R^{3g}, or R^{3h} is a group represented by Formula W,

in Formula 4, X^{4a} and X^{4b} each independently represent an O atom, a S atom, or a Se atom, 4p and 4q each independently represent an integer of 0 to 2, R^{4a} to R^{4j}, R^{4k}, and R^{4m} each independently represent a hydrogen atom, a halogen atom, or a group represented by Formula W, at least one of R^{4a}, R^{4b}, R^{4c}, R^{4d}, R^{4e}, R^{4f}, R^{4g}, R^{4h}, R⁴ⁱ, R^{4j}, R^{4k}, or R^{4m} is a group represented by Formula W, and in a case where at least one of R^{4e} or R^{4f} is a group represented by Formula W, L^{W} in Formula W represented by R^{4e} and R^{4f} is a divalent linking group represented by Formula L-2 or L-3,

in Formula 5, X^{5a} and X^{5b} each independently represent NR⁵ⁱ, an O atom, or a S atom, A^{5a} represents CR^{5g} or a N atom, A^{5b} represents CR^{5h} or a N atom, R⁵ⁱ represents a hydrogen atom, an alkyl group, an alkenyl group, an alkynyl group, an acyl group, an aryl group, or a heteroaryl group, R^{5a} to R^{5h} each independently represent a hydrogen atom or a substituent, and at least one of R^{5a}, R^{5b}, R^{5c}, R^{5d}, R^{5e}, R^{5f}, R^{5g}, or R^{5h} is a group represented by Formula W,

in Formula 6, X^{6a} to X^{6d} each independently represent NR^{6g}, an O atom, or a S atom, R^{6g} represents a hydrogen atom, an alkyl group, an alkenyl group, an alkynyl group, an acyl group, an aryl group, or a heteroaryl group, R^{6a} to R^{6f} each independently represent a hydrogen atom or a substituent, and at least one of R^{6a}, R^{6b}, R^{6c}, R^{6d}, R^{6e}, or R^{6f} is a group represented by Formula W,

in Formula 7, X^{7a} and X^{7c} each independently represent a S atom, an O atom, a Se atom, or NR⁷ⁱ, X^{7b} and X^{7d} each independently represent a S atom, an O atom, or a Se atom, R^{7a} to R⁷ⁱ each independently represent a hydrogen atom or a substituent, and at least one of R^{7a}, R^{7b}, R^{7c}, R^{7d}, R^{7e}, R^{7f}, R^{7g}, R^{7h}, or R⁷ⁱ is a group represented by Formula W,

in Formula 8, X^{8a} and X^{8c} each independently represent a S atom, an O atom, a Se atom, or NR⁸ⁱ, X^{8b} and X^{8d} each independently represent a S atom, an O atom, or a Se atom, R^{8a} to R⁸ⁱ each independently represent a hydrogen atom or a substituent, and at least one of R^{8a}, R^{8b}, R^{8c}, R^{8d}, R^{8e}, R^{8f}, R^{8g}, R^{8h}, or R⁸ⁱ is a group represented by Formula W,

in Formula 9, X^{9a} and X^{9b} each independently represent an O atom, a S atom, or a Se atom, R^{9c}, R^{9d}, and R^{9g} to R^{9j} each independently represent a hydrogen atom, a halogen atom, or a group represented by Formula W, and R^{9a}, R^{9b}, R^{9e}, and R^{9f} each independently represent a hydrogen atom or a substituent,

in Formula 10, R^{10a} to R^{10h} each independently represent a hydrogen atom or a substituent, at least one of R^{10a}, R^{10b}, R^{10c}, R^{10d}, R^{10e}, R^{10f}, R^{10g}, or R^{10h} represents a substituent represented by Formula W, X^{10a} and X^{10b} each independently represent a S atom, an O atom, a Se atom, or NR¹⁰ⁱ, and R¹⁰ⁱ each independently represents a hydrogen atom or a group represented by Formula W,

in Formula 11, X^{11a} and X^{11b} each independently represent a S atom, an O atom, a Se atom, or NR¹¹ⁿ, R^{11a} to R^{11k}, R^{11m}, and R¹¹ⁿ each independently represent a hydrogen atom or a substituent, and at least one of R^{11a}, R^{11b}, R^{11c}, R^{11d}, R^{11e}, R^{11f}, R^{11g}, R^{11h}, R¹¹ⁱ, R^{11j}, R^{11k}, R^{11m}, or R¹¹ⁿ is a group represented by Formula W,

in Formula 12, X^{12a} and X^{12b} each independently represent a S atom, an O atom, a Se atom, or NR¹²ⁿ, R^{12a} to R^{12k}, R^{12m}, and R¹²ⁿ each independently represent a hydrogen atom or a substituent, and at least one of R^{12a}, R^{12b}, R^{12c}, R^{12d}, R^{12e}, R^{12f}, R^{12g}, R^{12h}, R¹²ⁱ, R^{12j}, R^{12k}, R^{12m} or R¹²ⁿ is a group represented by Formula W,

in Formula 13, X^{13a} and X^{13b} each independently represent a S atom, an O atom, a Se atom, or NR¹³ⁿ, R^{13a} to R^{13k}, R^{13m}, and R¹³ⁿ each independently represent a hydrogen atom or a substituent, and at least one of R^{13a}, R^{13b}, R^{13c}, R^{13d}, R^{13e}, R^{13f}, R^{13g}, R^{13h}, R¹³ⁱ, R^{13j}, R^{13k}, R^{13m} or R¹³ⁿ is a group represented by Formula W,

in Formula 14, X^{14a} to X^{14c} each independently represent a S atom, an O atom, a Se atom, or NR¹⁴ⁱ, R^{14a} to R¹⁴ⁱ each independently represent a hydrogen atom or a substituent, and at least one of R^{14a}, R^{14b}, R^{14c}, R^{14d}, R^{14e}, R^{14f}, R^{14g}, R^{14h}, or R¹⁴ⁱ is a group represented by Formula W,

in Formula 15, X^{15a} to X^{15d} each independently represent a S atom, an O atom, a Se atom or NR^{15g}, R^{15a} to R^{15g} each independently represent a hydrogen atom or a substituent, and at least one of R^{15a}, R^{15b}, R^{15c}, R^{15d}, R^{15e}, R^{15f} or R^{15g} is a group represented by Formula W, and

in Formula 16, X^{16a} to X^{16d} each independently represent a S atom, an O atom, a Se atom, or NR^{16g}, R^{16a} to R^{16g} each independently represent a hydrogen atom or a substituent, and at least one of R^{16a}, R^{16b}, R^{16c}, R^{16d}, R^{16e}, R^{16f}, or R^{16g} is a group represented by Formula W.

<10> The composition for forming an organic semiconductor film described in <9>, in which the organic semiconductor contains at least one kind of compound represented by any one of Formulae 1 to 9 and 15.

<11> A method for manufacturing an organic semiconductor element, comprising: a coating step of coating a substrate with the composition for forming an organic semiconductor film described in any one of <1> to <10>.

<12> An organic semiconductor element which is manufactured by the method for manufacturing an organic semiconductor element described in <11>.

According to the present invention, it is possible to provide a composition for forming an organic semiconductor film that makes it possible to obtain an organic semiconductor film having excellent mobility and heat stability.

Furthermore, according to the present invention, it is possible to provide an organic semiconductor element including an organic semiconductor film having has excellent mobility and heat stability and a method for manufacturing the organic semiconductor element.

### BRIEF DESCRIPTION OF THE DRAWINGS

FIG. 1 is a schematic cross-sectional view of an aspect of an organic semiconductor element of the present invention.

FIG. 2 is a schematic cross-sectional view of another aspect of the organic semiconductor element of the present invention.

FIG. 3 is a plan view of a metal mask used in examples.

### DESCRIPTION OF THE PREFERRED EMBODIMENTS

Hereinafter, the contents of the present invention will be specifically described. The constituents in the following description will be explained based on typical embodiments of the present invention, but the present invention is not limited to the embodiments. In the specification of the present application, “to” is used to mean that the numerical values listed before and after “to” are a lower limit and an upper limit respectively. Furthermore, in the present invention, an organic EL element refers to an organic electroluminescence element.

In the present specification, in a case where there is no description regarding whether a group (atomic group) is substituted or unsubstituted, the group includes both of a group having a substituent and a group not having a substituent. For example, an “alkyl group” includes not only an alkyl group not having a substituent (unsubstituted alkyl group) but also an alkyl group having a substituent (substituted alkyl group).

In the present specification, in some cases, a chemical structural formula is described as a simplified structural formula in which a hydrogen atom is omitted.

In the present invention, “mobility” refers to “carrier mobility” and means either of both of electron mobility and hole mobility.

In the present invention, “% by mass” and “% by weight” have the same definition, and “part by mass” and “part by weight” have the same definition.

In the present invention, a weight-average molecular weight (Mw) and a number-average molecular weight (Mn) is a polystyrene conversion value measured by gel permeation chromatography (GPC) in which HLC-8120 (manufactured by TOSOH CORPORATION) is used, TSK gel Multipore HXL-M (manufactured by TOSOH CORPORATION, 7.8 mm HD×30.0 cm) is used as a column, and tetrahydrofuran (THF) is used as a solvent.

In the present invention, a combination of preferred aspects is more preferable.

(Composition for Forming Organic Semiconductor Film)

A composition for forming an organic semiconductor film (hereinafter, simply referred to as a “composition” as well) of the present invention contains an organic semiconductor as a component A, a binder polymer as a component B, a solvent having a naphthalene structure as a component C, and a solvent having a lower SP value than that of the component C by 2.0 MPa^{1/2} or greater and a lower boiling point than that of the component C, as a component D, in which the organic semiconductor has a condensed polycyclic aromatic group, the number of rings in the condensed polycyclic aromatic group is equal to or greater than 4, at least two rings in the condensed polycyclic aromatic group contains at least one atom selected from the group consisting of a sulfur atom, a nitrogen atom, a selenium atom, and an oxygen atom, and the condensed polycyclic aromatic group has, as a partial structure, at least one structure selected from the group consisting of a benzene ring, a naphthalene ring, and a phenanthrene ring.

As a result of repeating intensive investigation, by incorporating a combination of an organic semiconductor having the aforementioned specific structure, the aforementioned specific polymer, and the aforementioned specific solvent into the composition, heat stability and mobility of the obtained organic semiconductor film become excellent. Based on this knowledge, the inventors accomplished the present invention.

The details of mechanism that brings about such effects are unclear. Presumably, since drying properties and wettability of the aforementioned organic semiconductor and the aforementioned polymer are controlled in a mixed solvent, uniform layer separation of the binder polymer and the organic semiconductor is realized, and as a result, mobility become excellent. In addition, presumably, the uniform layer separation makes it possible to relax the stress concentrated on a specific part of organic semiconductor crystals, and hence the heat stability becomes excellent.

<Component A: Organic Semiconductor>

The composition for forming an organic semiconductor film of the present invention contains an organic semiconductor which has a condensed polycyclic aromatic group and in which the number of rings in the condensed polycyclic aromatic group is equal to or greater than 4, at least two rings in the condensed polycyclic aromatic group contain at least one atom selected from the group consisting of a sulfur atom, a nitrogen atom, a selenium atom, and an oxygen atom, and the condensed polycyclic aromatic group has, as a partial structure, at least one structure selected from the group consisting of a benzene ring, a naphthalene ring, and a phenanthrene ring.

Here, the partial structure in the condensed polycyclic aromatic group in the component A does not contain an anthracene ring. In a case where the partial structure contains an anthracene ring, mobility and heat stability of the obtained organic semiconductor film become excellent, although the reason is unclear.

The condensed polycyclic aromatic group is a group obtained by the condensation of a plurality of aromatic rings.

Examples of the aromatic ring include an aromatic hydrocarbon ring (for example, a benzene ring) and an aromatic heterocyclic ring (for example, a thiophene ring, a furan ring, a pyrrole ring, a selenophene ring, or an imidazole ring).

The component A contains a condensed polycyclic aromatic group (condensed polycyclic aromatic structure), and it is preferable that this group is contained as a main component. Herein, being a main component means that a content of the condensed polycyclic aromatic group based on a molecular weight is equal to or greater than 30% of a total molecular weight of the component A. The content is preferably equal to or greater than 40%. An upper limit of the content is not particularly limited. In view of solubility, the upper limit is preferably equal to or less than 80%.

The condensed polycyclic aromatic group is a cyclic structure formed by the condensation of a plurality of rings and exhibits properties of an aromatic group.

The number of rings in the condensed polycyclic aromatic group in the component A is equal to or greater than 4. From the viewpoint of mobility thereof as an organic semiconductor, the number of rings is preferably 4 to 9, more preferably 4 to 7, and even more preferably 5 or 6.

At least two rings in the condensed polycyclic aromatic group contain at least one kind of atom selected from the group consisting of a sulfur atom, a nitrogen atom, a selenium atom, and an oxygen atom. From the viewpoint of mobility thereof as an organic semiconductor, the number of rings containing the aforementioned atom is preferably 2 to 6, and more preferably 2 to 4.

From the viewpoint of mobility thereof as an organic semiconductor, the condensed polycyclic aromatic group preferably contains at least two heterocyclic rings, and the heterocyclic rings preferably each have one heteroatom. The type of the heteroatom is not particularly limited, and examples thereof include an O atom (oxygen atom), a S atom (sulfur atom), a N atom (nitrogen atom), a Se atom (selenium atom), and the like.

The condensed polycyclic aromatic group in the component A contains, as a partial structure, at least one structure selected from the group consisting of a benzene ring, a naphthalene ring, and a phenanthrene ring. The condensed polycyclic aromatic group does not contain an anthracene ring as the partial structure.

From the viewpoint of mobility thereof as an organic semiconductor, the component A preferably has at least a thiophene ring structure and/or a selenophene ring structure, and more preferably has at least a thiophene ring structure. It is even more preferable that all of the heterocyclic structures contained in the component A are thiophene ring structures.

From the viewpoint of mobility thereof as an organic semiconductor, the condensed polycyclic aromatic group is preferably a condensed polycyclic aromatic group which contains, as a partial structure, at least one structure selected from the group consisting of a benzene ring, a naphthalene ring, and a phenanthrene ring, contains two or more thiophene rings, and has four or more rings. Particularly, the condensed polycyclic aromatic group is more preferably a condensed polycyclic aromatic group which contains a benzene ring and two or more thiophene rings as a partial structure and has four or more rings.

From the viewpoint of mobility thereof as an organic semiconductor, the number of thiophene rings in the condensed polycyclic aromatic group is preferably equal to or greater than 3, more preferably 3 to 5, even more preferably 3 or 4, and particularly preferably 3.

From the viewpoint of mobility thereof as an organic semiconductor, the number of rings in the condensed polycyclic aromatic group is preferably 4 to 6, more preferably 5 or 6, and even more preferably 5. The condensed polycyclic aromatic group is particularly preferably a condensed polycyclic aromatic group which contains two benzene rings and three thiophene rings and has 5 rings.

Preferred examples of the condensed polycyclic aromatic group include a group in which a ring (heterocyclic ring, preferably, a thiophene ring) containing at least one kind of atom selected from the group consisting of a sulfur atom, a nitrogen atom, a selenium atom, and an oxygen atom and a benzene ring are alternately condensed (fused) with each other (a group which is obtained by the alternate condensation of the aforementioned heterocyclic ring and a benzene ring).

From the viewpoint of mobility thereof as an organic semiconductor, the component A preferably contains at least one kind of compound represented by any one of Formulae 1 to 16. The component A is more preferably one or more kinds of compound represented by any one of Formulae 1 to 16.

The composition of the present invention may contain only one kind of component A or two or more kinds of component A.

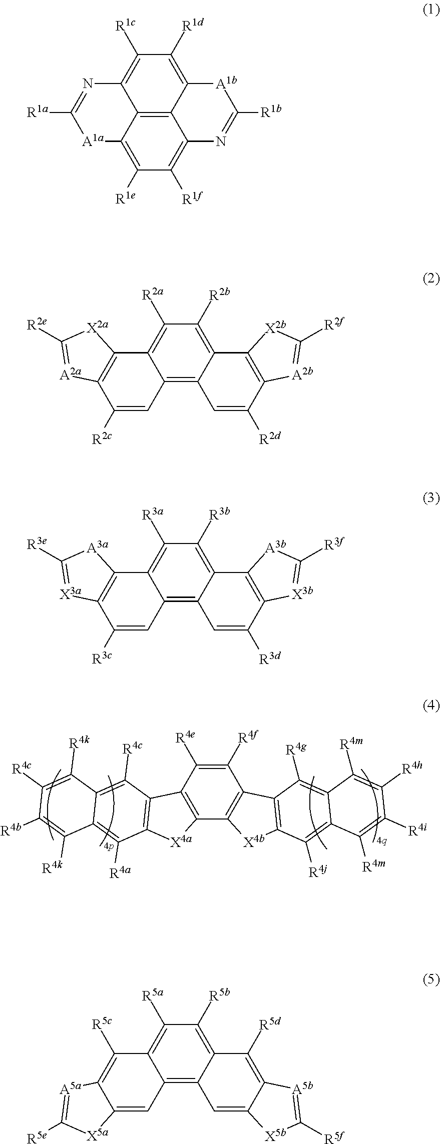

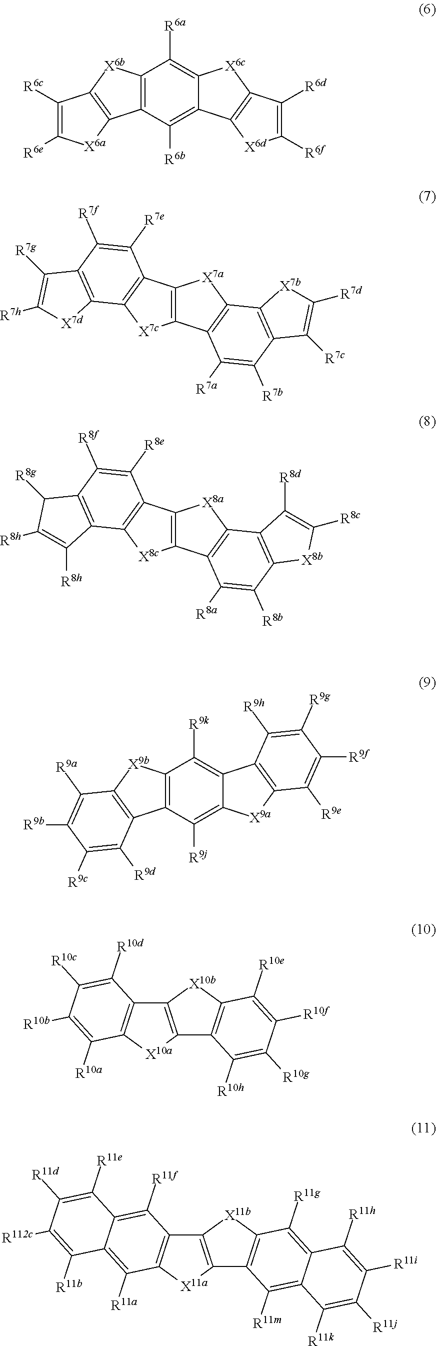

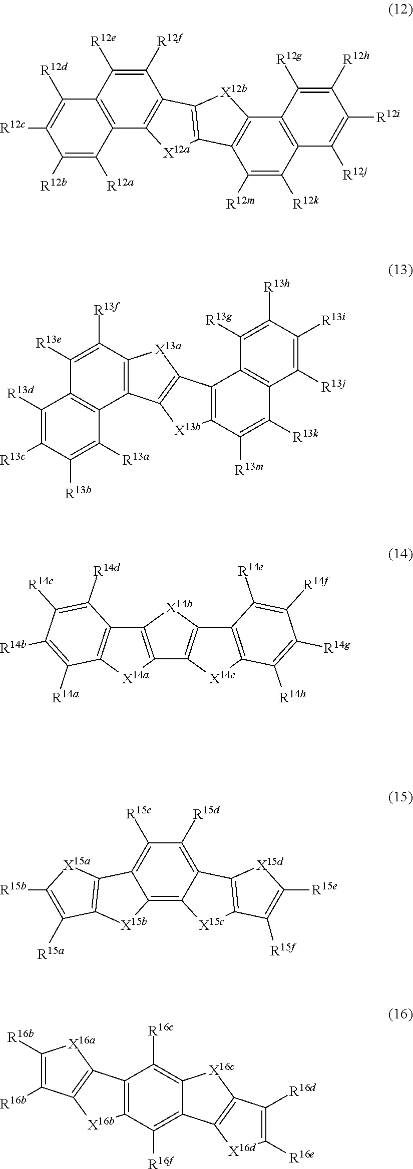

In Formula 1, A^{1a} and A^{1b} each independently represent a S atom, an O atom, or a Se atom, R^{1a} to R^{1f} each independently represent a hydrogen atom or a substituent, and at least one of R^{1a}, R^{1b}, R^{1c}, R^{1d}, R^{1e}, or R^{1f} is a group represented by the following Formula W.

-L^{W}-R^{W} (W)

In Formula W, L^{W} represents a divalent linking group which is represented by any one of the following Formulae L-1 to L-25 or a divalent linking group in which two or more divalent linking groups represented by any one of the following Formulae L-1 to L-25 are bonded to each other, and R^{W} represents an alkyl group, a cyano group, a vinyl group, an ethynyl group, an oxyethylene group, an oligo-oxyethylene group in which a repetition number v of an oxyethylene unit is equal to or greater than 2, a siloxane group, an oligosiloxane group having two or more silicon atoms, or a trialkylsilyl group.

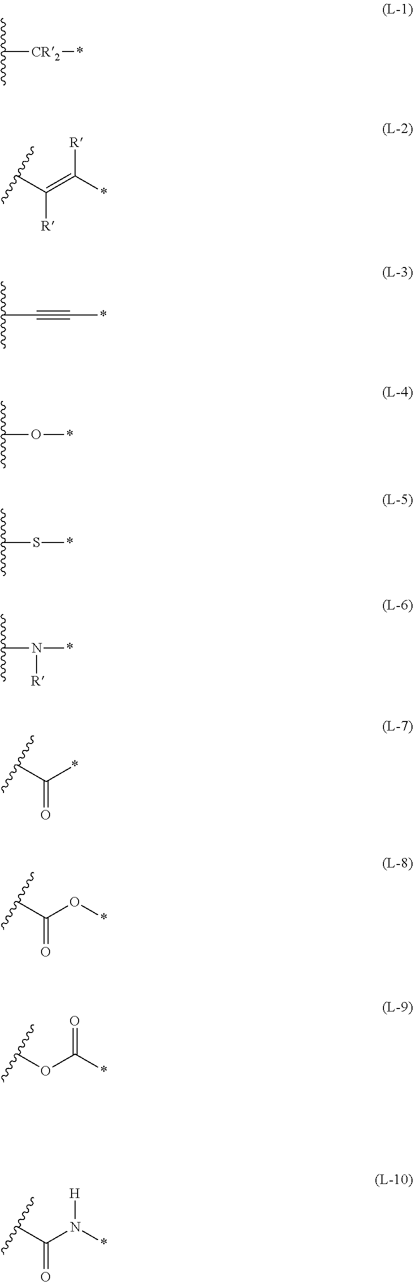

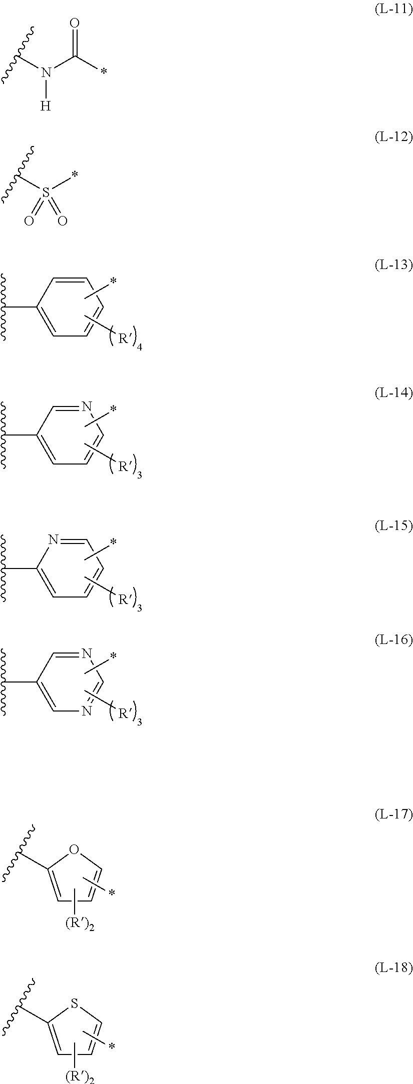

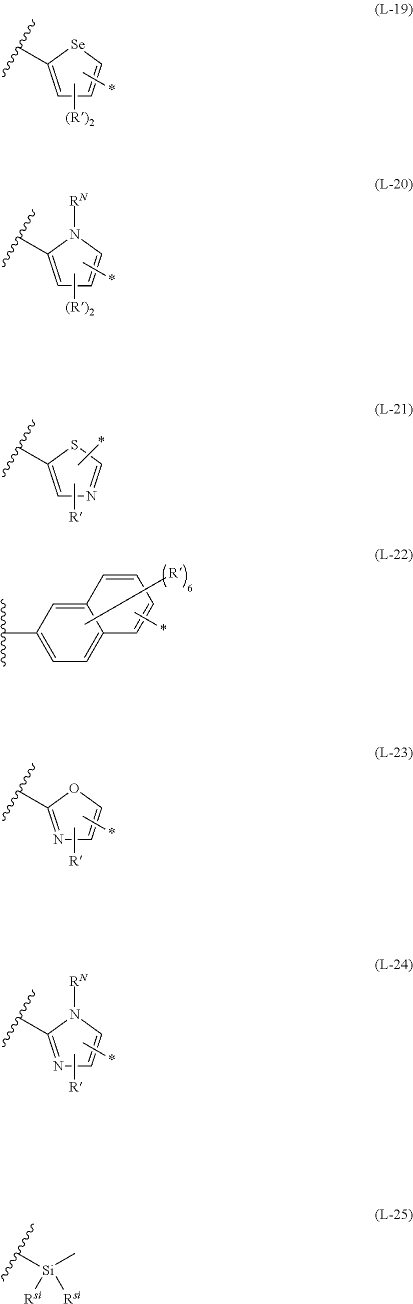

In Formulae L-1 to L-25, * represents a binding position for R, the portion of a wavy line represents the other binding position, R′ in Formulae L-1, L-2, L-6, and L-13 to L-24 each independently represents a hydrogen atom or a substituent, R^{N} in Formulae L-20 and L-24 represents a hydrogen atom or a substituent, and R^{si} in Formula L-25 each independently represents a hydrogen atom, an alkyl group, an alkenyl group, or an alkynyl group.

In Formula 2, X^{2a} and X^{2b} each independently represent NR²ⁱ, an O atom, or a S atom, A^{2a} represents CR^{2g} or a N atom, A^{2b} represents CR^{2h} or a N atom, R²ⁱ represents a hydrogen atom, an alkyl group, an alkenyl group, an alkynyl group, or an acyl group, R^{2a} to R^{2h} each independently represent a hydrogen atom or a substituent, and at least one of R^{2a}, R^{2b}, R^{2c}, R^{2d}, R^{2e}, R^{2f}, R^{2g}, or R^{2h} is a group represented by Formula W.

In Formula 3, X^{3a} and X^{3b} each independently represent a S atom, an O atom, or NR^{3g}, and A^{3a} and A^{3b} each independently represent CR^{3h} or a N atom. R^{3a} to R^{ah} each independently represent a hydrogen atom or a substituent, and at least one of R^{3a}, R^{3b}, R^{3e}, R^{3d}, R^{3e}, R^{3f}, R^{3g}, or R^{3h} is a group represented by Formula W.

In Formula 4, X^{4a} and X^{4b} each independently represent an O atom, a S atom, or a Se atom, 4p and 4q each independently represent an integer of 0 to 2, R^{4a} to R^{4j}, R^{4k}, and R^{4m} each independently represent a hydrogen atom, a halogen atom, or a group represented by Formula W, at least one of R^{4a}, R^{4b}, R^{4c}, R^{4d}, R^{4e}, R^{4f}, R^{4g}, R^{4h}, R⁴ⁱ, R^{4j}, R^{4k}, or R^{4m} is a group represented by Formula W. Here, in a case where at least one of R^{4e} or R^{4f} is a group represented by Formula W, L^{W} in Formula W represented by R^{4e} and R^{4f} is a divalent linking group represented by Formula L-2 or L-3.

In Formula 5, X^{5a} and X^{5b} each independently represent NR⁵ⁱ, an O atom, or a S atom, A^{5a} represents CR^{5g} or a N atom, A^{5b} represents CR^{5h} or a N atom, R⁵ⁱ represents a hydrogen atom, an alkyl group, an alkenyl group, an alkynyl group, an acyl group, an aryl group, or a heteroaryl group, R^{5a} to R^{5h} each independently represent a hydrogen atom or a substituent, and at least one of R^{5a}, R^{5b}, R^{5c}, R^{5d}, R^{5e}, R^{5f}, R^{5g}, or R^{5h} is a group represented by Formula W.

In Formula 6, X^{6a} to X^{6d} each independently represent NR^{6g}, an O atom, or a S atom, R^{6g} represents a hydrogen atom, an alkyl group, an alkenyl group, an alkynyl group, an acyl group, an aryl group, or a heteroaryl group, R^{6a} to R^{6f} each independently represent a hydrogen atom or a substituent, and at least one of R^{6a}, R^{6b}, R^{6c}, R^{6d}, R^{6e}, or R^{6f} is a group represented by Formula W.

In Formula 7, X^{7a} and X^{7c} each independently represent a S atom, an O atom, a Se atom, or NR⁷ⁱ, X^{7b} and X^{7d} each independently represent a S atom, an O atom, or a Se atom, R^{7a} to R⁷ⁱ each independently represent a hydrogen atom or a substituent, and at least one of R^{7a}, R^{7b}, R^{7c}, R^{7d}, R^{7e}, R^{7f}, R^{7g}, R^{7h}, or R⁷ⁱ is a group represented by Formula W.

In Formula 8, X^{8a} and X^{8c} each independently represent a S atom, an O atom, a Se atom, or NR⁸ⁱ, X^{8b} and X^{8d} each independently represent a S atom, an O atom, or a Se atom, R^{8a} to R⁸ⁱ each independently represent a hydrogen atom or a substituent, and at least one of R^{8a}, R^{8b}, R^{8c}, R^{8d}, R^{8e}, R^{8f}, R^{8g}, R^{8h}, or R⁸ⁱ is a group represented by Formula W.

In Formula 9, X^{9a} and X^{9b} each independently represent an O atom, a S atom, or a Se atom, R^{9c}, R^{9d}, and R^{9g} to R^{9j} each independently represent a hydrogen atom, a halogen atom, or a group represented by Formula W, and R^{9a}, R^{9b}, R^{e}, and R^{9f} each independently represent a hydrogen atom or a substituent.

In Formula 10, R^{10a} to R^{10h} each independently represent a hydrogen atom or a substituent, at least one of R^{10a}, R^{10b}, R^{10c}, R^{10d}, R^{10e}, R^{10f}, R^{10g}, or R^{10h} represents a substituent represented by Formula W, X^{10a} and X^{10b} each independently represent a S atom, an O atom, a Se atom, or NR¹⁰ⁱ, and R¹⁰ⁱ each independently represents a hydrogen atom or a group represented by Formula W.

In Formula 11, X^{11a} and X^{11b} each independently represent a S atom, an O atom, a Se atom, or NR¹¹ⁿ, R^{11a} to R^{11k}, R^{11m}, and R¹¹ⁿ each independently represent a hydrogen atom or a substituent, and at least one of R^{11a}, R^{11b}, R^{11c}, R^{11d}, R^{11e}, R^{11f}, R^{11g}, R^{11h}, R¹¹ⁱ, R^{11j}, R^{11k}, R^{11m}, or R¹¹ⁿ is a group represented by Formula W.

In Formula 12, X^{12a} and X^{12b} each independently represent a S atom, an O atom, a Se atom, or NR¹²ⁿ, R^{12a} to R^{12k}, R^{12m}, and R¹²ⁿ each independently represent a hydrogen atom or a substituent, and at least one of R^{12a}, R^{12b}, R^{12c}, R^{12d}, R^{12e}, R^{12f}, R^{12g}, R^{12h}, R¹²ⁱ, R^{12j}, R^{12k}, R^{12m} or R¹²ⁿ is a group represented by Formula W.

In Formula 13, X^{13a} and X^{13b} each independently represent a S atom, an O atom, a Se atom, or NR¹³ⁿ, R^{13a} to R^{13k}, R^{13m}, and R¹³ⁿ each independently represent a hydrogen atom or a substituent, and at least one of R^{13a}, R^{13b}, R^{13c}, R^{13d}, R^{13e}, R^{13f}, R^{13g}, R^{13h}, R¹³ⁱ, R^{13j}, R^{13k}, R^{13m} or R¹³ⁿ is a group represented by Formula W.

In Formula 14, X^{14a} to X^{14c} each independently represent a S atom, an O atom, a Se atom, or NR¹⁴ⁱ, R^{14a} to R¹⁴ⁱ each independently represent a hydrogen atom or a substituent, and at least one of R^{14a}, R^{14b}, R^{14c}, R^{14d}, R^{14e}, R^{14f}, R^{14g}, R^{14h}, or R¹⁴ⁱ is a group represented by Formula W.

In Formula 15, X^{15a} to X^{15d} each independently represent a S atom, an O atom, a Se atom, or NR^{15g}, R^{15a} to R^{15g} each independently represent a hydrogen atom or a substituent, and at least one of R^{15a}, R^{15b}, R^{15c}, R^{15d}, R^{15e}, R^{15f}, or R^{15g} is a group represented by Formula W.

In Formula 16, X^{16a} to X^{16d} each independently represent a S atom, an O atom, a Se atom, or NR^{16g}, R^{16a} to R^{16g} each independently represent a hydrogen atom or a substituent, and at least one of R^{16a}, R^{16b}, R^{16c}, R^{16d}, R^{16e}, R^{16f}, or R^{16g} is a group represented by Formula W.

—Compound Represented by Formula 1—

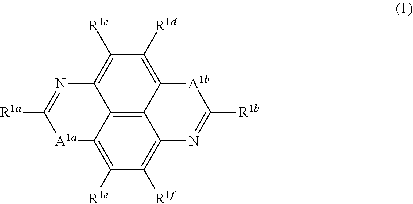

In Formula 1, A^{1a} and A^{1b} each independently represent a S atom (sulfur atom), an O atom (oxygen atom), or a Se atom (selenium atom). Each of A^{1a} and A^{1b} is preferably a S atom or an O atom. A^{1a} and A^{1b} may be the same as or different from each other, but it is preferable that they are the same as each other.

In Formula 1, R^{1a} to R^{1f} each independently represent a hydrogen atom or a substituent. Here, at least one of R^{1a}, R^{1b}, R^{1c}, R^{1d}, R^{1e}, or R^{1f} is a group represented by Formula W which will be described later.

The compound represented by Formula 1 may have substituents other than a group represented by Formula W which will be described later.

The type of the substituents which can be adopted as R^{1a} to R^{1f} in Formula 1 is not particularly limited, and examples thereof include a substituent X described below. Examples of the substituent X include a group represented by Formula W which will be described later, a halogen atom, an alkyl group (including a cycloalkyl group, a bicycloalkyl group, and a tricycloalkyl group), an alkenyl group (including a cycloalkenyl group and a bicycloalkenyl group), an alkynyl group, an aryl group, a heterocyclic group (may be referred to as a hetero ring group as well), a cyano group, a hydroxyl group, a nitro group, a carboxy group, an alkoxy group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an acylamino group, an aminocarbonylamino group, alkoxycarbonylamino group, an aryloxycarbonylamino group, a sulfamoylamino group, alkyl- and arylsulfonylamino groups, a mercapto group, an alkylthio group, an arylthio group, a heterocyclic thio group, a sulfamoyl group, a sulfo group, alkyl- and arylsulfinyl groups, alkyl- and arylsulfonyl groups, an acyl group, an aryloxycarbonyl group, an alkoxycarbonyl group, a carbamoyl group, aryl- and heterocyclic azo groups, an imido group, a phosphino group, a phosphinyl group, a phosphinyloxy group, a phosphinylamino group, a phosphono group, a silyl group, a hydrazino group, a ureido group, a boronic acid group (—B(OH)₂), a phosphato group (—OPO(OH)₂), a sulfato group (—OSO₃H), and other known substituents. In Formulae 1 to 16 of the present specification, preferred examples of a “substituent” include the aforementioned substituent X.

Among these, the groups other than a group represented by Formula W which will be described later are preferably a halogen atom, an alkyl group, an alkynyl group, an alkenyl group, an alkoxy group, an alkylthio group, and an aryl group, more preferably a fluorine atom, a substituted or unsubstituted alkyl group having 1 to 3 carbon atoms, a substituted or unsubstituted alkynyl group having 2 or 3 carbon atoms, a substituted or unsubstituted alkenyl group having 2 or 3 carbon atoms, a substituted or unsubstituted alkoxy group having one or two carbon atoms, a substituted or unsubstituted methylthio group, and a phenyl group, and particularly preferably a fluorine atom, a substituted or unsubstituted alkyl group having 1 to 3 carbon atoms, a substituted or unsubstituted alkynyl group having 2 or 3 carbon atoms, a substituted or unsubstituted alkenyl group having 2 or 3 carbon atoms, a substituted or unsubstituted alkoxy group having one or two carbon atoms, and a substituted or unsubstituted methylthio group.

In the compound represented by Formula 1, among R^{1a} to R^{1f}, the number of substituents other than a group represented by Formula W is preferably 0 to 4, more preferably 0 to 2, and particularly preferably 0.

These substituents may further have the above substituents X.

Among the above substituents, R^{1c} to R^{1f} each independently preferably represent a hydrogen atom, a fluorine atom, a substituted or unsubstituted alkyl group having 1 to 3 carbon atoms, a substituted or unsubstituted alkynyl group having 2 or 3 carbon atoms, a substituted or unsubstituted alkenyl group having two or three carbon atoms, a substituted or unsubstituted alkoxy group having one or two carbon atoms, or a substituted or unsubstituted methylthio group.

Next, a group represented by Formula W will be described.

-L^{W}-R^{W} (W)

In Formula W, L represents a divalent linking group which is represented by any one of the following Formulae L-1 to L-25 or a divalent linking group in which two or more divalent linking groups represented by any one of the following Formulae L-1 to L-25 are bonded to each other.

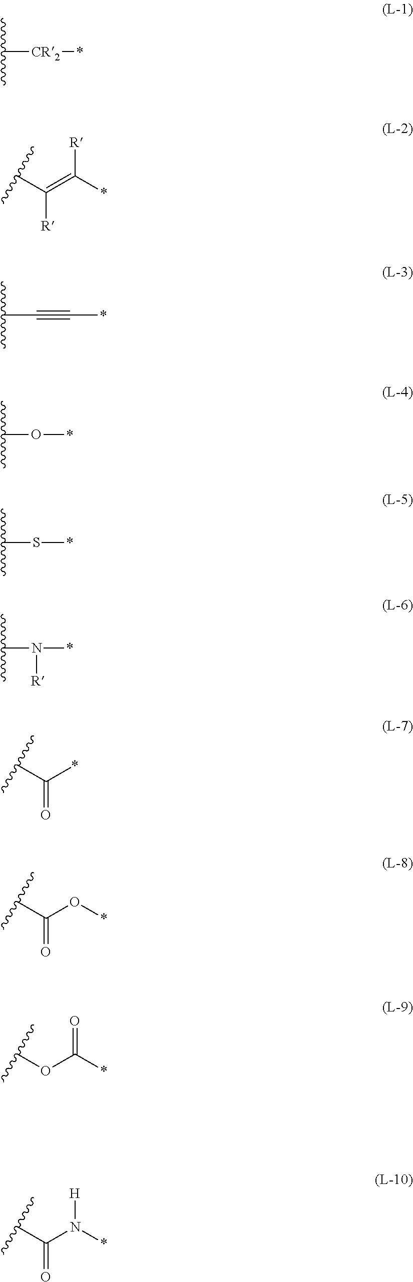

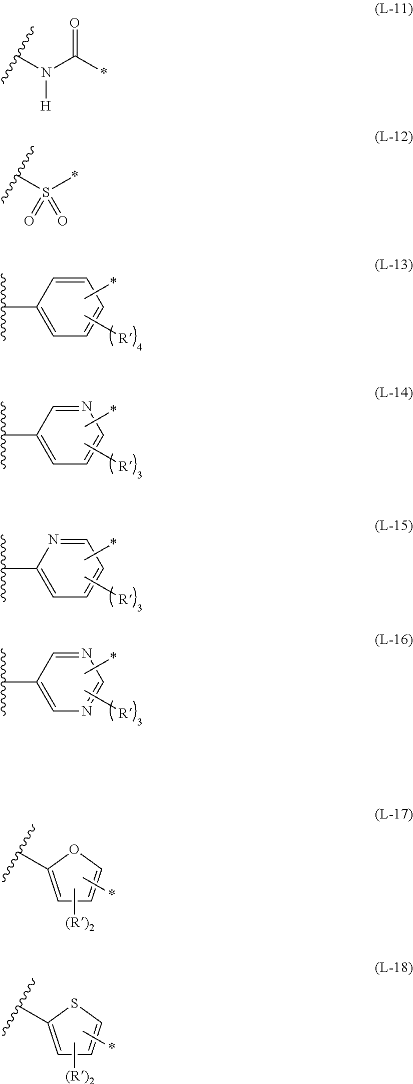

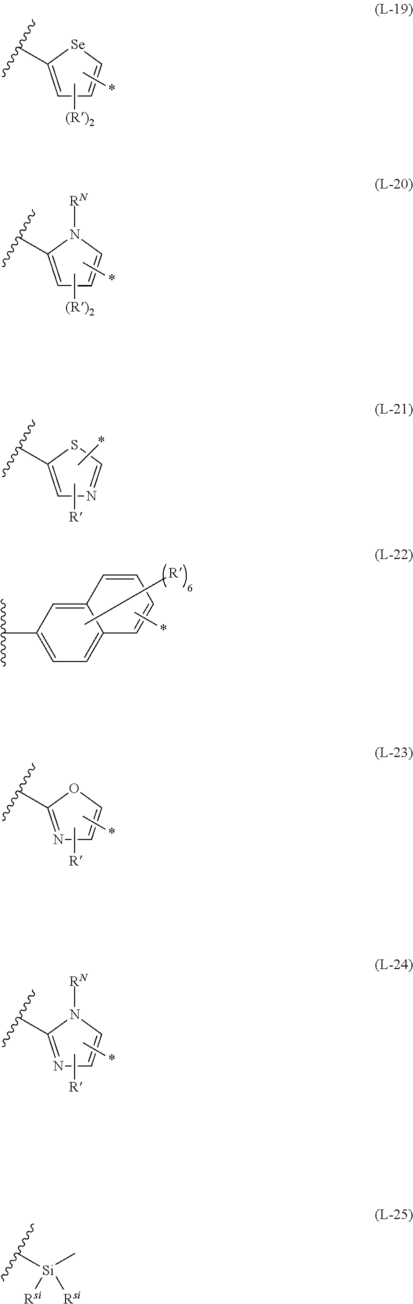

In Formulae L-1 to L-25, * represents a binding position for R^{W}, and the portion of a wavy line represents the other binding position. More specifically, in the compound represented by Formula 1, the portion of a wavy line is bonded to a ring forming a skeleton represented by Formula 1. As will be described later, in a case where Formula W is contained in other compounds, the portion of a wavy line is bonded to a ring forming a skeleton of each of the compounds.

In a case where L^{W} represents a divalent linking group in which two or more divalent linking groups represented by any one of Formulae L-1 to L-25 are bonded to each other, * of one linking group is bonded to the portion of a wavy line of the other linking group.

In Formulae L-13 to L-24, as the binding position of R′ and the binding position * for R^{W}, any position on an aromatic ring or a heterocyclic aromatic ring can be adopted.

R′ in Formulae L-1, L-2, L-6, and L-13 to L-24 each independently represents a hydrogen atom or a substituent. R^{N} in Formulae L-20 and L-24 represents a hydrogen atom or a substituent. R^{si} in Formula L-25 each independently represents a hydrogen atom, an alkyl group, an alkenyl group, or an alkynyl group.

Each R′ in Formulae L-1 and L-2 may form a fused ring by being bonded to R^{W} adjacent to L^{W}.

Among these, the divalent linking group represented by any one of Formulae L-17 to L-21, L-23, and L-24 is more preferably a divalent linking group represented by one of the following Formulae L-17A to L-21A, L-23A, and L-24A.

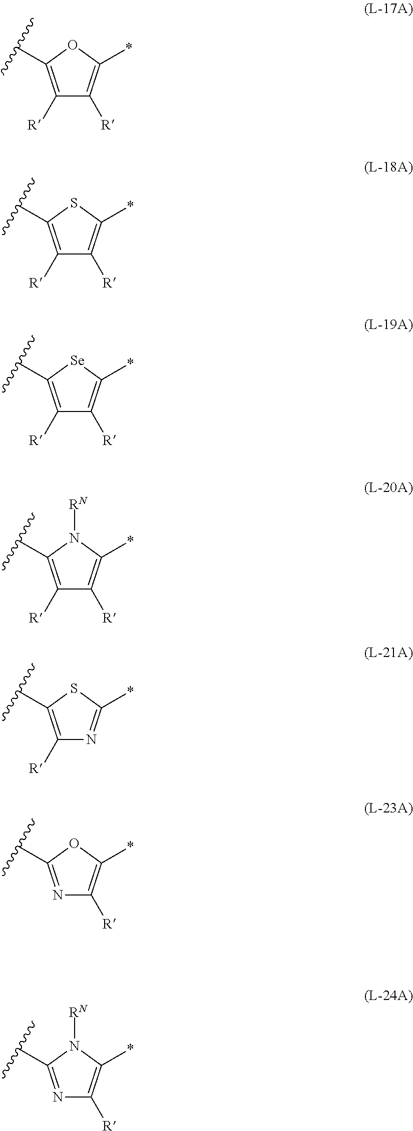

In a case where a substituted or unsubstituted alkyl group, an oxyethylene group, an oligo-oxyethylene group in which a repetition number v of an oxyethylene unit is equal to or greater than 2, a siloxane group, an oligosiloxane group having two or more silicon atoms, or a substituted or unsubstituted trialkylsilyl group is present on the terminal of a substituent, the substituent can be interpreted as a substituent consisting only of —R^{W} in Formula W or a substituent consisting of -L^{W}-R^{W} in Formula W.

In the present invention, in a case where a substituted or unsubstituted alkyl group having a main chain consisting of N carbon atoms is present on the terminal of a substituent, the substituent is interpreted as -L^{W}-R^{W} in Formula W including as many linking groups as possible from the terminal of the substituent. Specifically, the substituent is interpreted as a substituent in which “one group represented by Formula L-1 corresponding to L^{W} in Formula W” and “a substituted or unsubstituted alkyl group which corresponds to R^{W} in Formula W and has a main chain consisting of (N−1) carbon atoms” are bonded to each other. For example, in a case where a n-octyl group which is an alkyl group having eight carbon atoms is present on the terminal of a substituent, the substituent is interpreted as a substituent in which one group represented by Formula L-1, in which two R's represent hydrogen atoms, and a n-pentyl group having 7 carbon atoms are bonded to each other.

In contrast, in the present invention, in a case where an oxyethylene group, an oligo-oxyethylene group in which a repetition number v of an oxyethylene unit is equal to or greater than 2, a siloxane group, an oligosiloxane group having two or more silicon atoms, or a substituted or unsubstituted trialkylsilyl group is present on the terminal of a substituent, the substituent is interpreted as a substituent consisting only of R^{W} in Formula W including as many linking groups as possible from the terminal of the substituent. For example, in a case where a —(OCH₂CH₂)—(OCH₂CH₂)—(OCH₂CH₂)—OCH₃ group is present on the terminal of a substituent, the substituent is interpreted as a substituent consisting only of an oligo-oxyethylene group in which a repetition number v of an oxyethylene unit is 3.

In a case where L^{W} forms a linking group in which divalent linking groups represented by any one of Formulae L-1 to L-25 are bonded to each other, the number of bonded divalent linking groups represented by any one of Formulae L-1 to L-25 is preferably 2 to 4, and more preferably 2 or 3.

Examples of the substituent R′ in Formulae L-1, L-2, L-6, and L-13 to L-24 include those exemplified as substituents that can be adopted as R^{1a} to R^{1f} in Formula 1. The substituent R′ in Formula L-6 among the above formulae is preferably an alkyl group. In a case where R′ in Formula L-6 is an alkyl group, the number of carbon atoms of the alkyl group is preferably 1 to 9, more preferably 4 to 9 from the viewpoint of chemical stability and carrier transport properties, and even more preferably 5 to 9. In a case where R′ in Formula L-6 is an alkyl group, the alkyl group is preferably a linear alkyl group, because then carrier mobility can be improved.

R^{N} in Formula L-20 or L-24 represents a hydrogen atom or a substituent. Examples of R^{N} include those exemplified as substituents that can be adopted as R^{1a} to R^{1f} in Formula 1. R^{N} is preferably a hydrogen atom or a methyl group among the substituents.

R^{si} in Formula L-25 each independently represents a hydrogen atom, an alkyl group, an alkenyl group, or an alkynyl group, and preferably represents an alkyl group. The alkyl group that can be adopted as R^{si} is not particularly limited. A preferred range of the alkyl group that can be adopted as R^{si} is the same as a preferred range of an alkyl group that can be adopted in a trialkylsilyl group in a case where R represents a trialkylsilyl group. The alkenyl group that can be adopted as R^{si} is not particularly limited. The alkenyl group is preferably a substituted or unsubstituted alkenyl group and more preferably a branched alkenyl group, and the alkenyl group preferably has 2 or 3 carbon atoms. The alkynyl group that can be adopted as R^{si} is not particularly limited. The alkynyl group is preferably a substituted or unsubstituted alkynyl group and more preferably a branched alkynyl group, and the alkynyl group preferably has 2 or 3 carbon atoms.

L^{W} is preferably a divalent linking group which is represented by any one of Formulae L-1 to L-5, L-13, L-17, and L-18 or a divalent linking group in which two or more divalent linking groups represented by any one of Formulae L-1 to L-5, L-13, L-17, and L-18 are bonded to each other, more preferably a divalent linking group which is represented by any one of Formulae L-1, L-3, L-13, and L-18 or a divalent linking group in which two or more divalent linking groups represented by any one of Formulae L-1, L-3, L-13, and L-18 are bonded to each other, and particularly preferably a divalent linking group which is represented by any one of Formulae L-1, L-3, L-13, and L-18 or a divalent linking group in which a divalent linking group represented by any one of Formulae L-3, L-13, and L-18 and a divalent linking group represented by Formula L-1 are bonded to each other.

Regarding the divalent linking group, in which a divalent linking group represented by any one of Formulae L-3, L-13, and L-18 and a divalent linking group represented by Formula L-1 are bonded to each other, it is preferable that the divalent linking group represented by Formula L-1 is bonded to the R^{W} side.

From the viewpoint of chemical stability and carrier transport properties, L^{W} is particularly preferably a divalent linking group containing a divalent linking group represented by Formula L-1, and more particularly preferably a divalent linking group represented by Formula L-1. It is the most preferable that L^{W} is a divalent linking group represented by Formula L-1 and R^{W} is a substituted or unsubstituted alkyl group.

In Formula W, R^{W} represents a substituted or unsubstituted alkyl group, a cyano group, a vinyl group, an ethynyl group, an oxyethylene group, an oligo-oxyethylene group in which a repetition number v of an oxyethylene unit is equal to or greater than 2, a siloxane group, an oligosiloxane group having two or more silicon atoms, or a substituted or unsubstituted trialkylsilyl group.

In Formula W, in a case where L^{W} adjacent to R^{W} is a divalent linking group which is represented by Formula L-1, R^{W} is preferably a substituted or unsubstituted alkyl group, an oxyethylene group, an oligo-oxyethylene group in which a repetition number of an oxyethylene unit is equal to or greater than 2, a siloxane group, or an oligosiloxane group having two or more silicon atoms, and more preferably a substituted or unsubstituted alkyl group.

In Formula W, in a case where L^{W} adjacent to R^{W} is a divalent linking group which is represented by any one of Formula L-2 and Formulae L-4 to L-25, R^{W} is more preferably a substituted or unsubstituted alkyl group.

In Formula W, in a case where L^{W} adjacent to R^{W} is a divalent linking group which is represented by Formula L-3, R^{W} is preferably a substituted or unsubstituted alkyl group or a substituted or unsubstituted trialkylsilyl group.

In a case where R^{W} is a substituted or unsubstituted alkyl group, the number of carbon atoms thereof is preferably 4 to 17, more preferably 6 to 14 from the viewpoint of chemical stability and carrier transport properties, and even more preferably 6 to 12. It is preferable that R is a long-chain alkyl group having carbon atoms within the above range, particularly, a long-chain linear alkyl group, because then linearity of the molecule is improved, and hence carrier mobility can be improved.

In a case where R^{W} represents an alkyl group, the alkyl group may be linear, branched, or cyclic. It is preferable that the alkyl group is a linear alkyl group, because then linearity of the molecule is improved, and hence carrier mobility can be improved.

Particularly, from the viewpoint of improving carrier mobility, R^{W} and L^{W} in Formula W preferably form a combination in which L^{W} in Formula 1 is a divalent linking group represented by Formula L-1 and R^{W} is a linear alkyl group having 7 to 17 carbon atoms or a combination in which L^{W} is a divalent linking group, in which a divalent linking group represented by any one of Formulae L-3, L-13, and L-18 and a divalent linking group represented by Formula L-1 are bonded to each other, and R^{W} is a linear alkyl group.

In a case where L^{W} is a divalent linking group represented by Formula L-1 and R^{W} is a linear alkyl group having 7 to 17 carbon atoms, R^{W} is more preferably a linear alkyl group having 7 to 14 carbon atoms from the viewpoint of improving carrier mobility, and particularly preferably a linear alkyl group having 7 to 12 carbon atoms.

In a case where L^{W} is a divalent linking group, in which a divalent linking group represented by any one of Formulae L-3, L-13, and L-18 and a divalent linking group represented by Formula L-1 are bonded to each other, and R^{W} is a linear alkyl group, R^{W} is more preferably a linear alkyl group having 4 to 17 carbon atoms, even more preferably a linear alkyl group having 6 to 14 carbon atoms from the viewpoint of chemical stability and carrier transport properties, and particularly preferably a linear alkyl group having 6 to 12 carbon atoms from the viewpoint of improving carrier mobility.

In contrast, from the viewpoint of improving solubility in an organic solvent, R^{W} is preferably a branched alkyl group.

In a case where R^{W} is an alkyl group having a substituent, examples of the substituent include a halogen atom and the like, and the halogen atom is preferably a fluorine atom. In a case where R^{W} is an alkyl group having a fluorine atom, all of the hydrogen atoms of the alkyl group may be substituted with fluorine atoms such that a perfluoroalkyl group is formed. Here, R^{W} is preferably an unsubstituted alkyl group.

In the present specification, in a case where R^{W} is an oligo-oxyethylene group in which a repetition number of an oxyethylene unit is equal to or greater than 2, the “oligo-oxyethylene group” represented by R^{w} refers to a group represented by —(OCH₂CH₂)ᵥ—OY (the repetition number v of an oxyethylene unit represents an integer of equal to or greater than 2, and Y on the terminal represents a hydrogen atom or a substituent). In a case where Y on the terminal of the oligo-oxyethylene group is a hydrogen atom, the terminal becomes a hydroxyl group. The repetition number v of the oxyethylene unit is preferably 2 to 4, and more preferably 2 or 3.

It is preferable that the hydroxyl group on the terminal of the oligo-oxyethylene group is sealed. That is, it is preferable that Y represents a substituent. In this case, the hydroxyl group is preferably sealed with an alkyl group having 1 to 3 carbon atoms. That is, Y is preferably an alkyl group having 1 to 3 carbon atoms, more preferably a methyl group or an ethyl group, and particularly preferably a methyl group.

In a case where R^{W} is a siloxane group or an oligosiloxane group having two or more silicon atoms, a repetition number of the siloxane unit is preferably 2 to 4, and more preferably 2 or 3. Furthermore, it is preferable that a hydrogen atom or an alkyl group is bonded to each silicon atom (Si atom). In a case where an alkyl group is bonded to the silicon atom, the number of carbon atoms of the alkyl group is preferably 1 to 3. For example, it is preferable that a methyl group or an ethyl group is bonded to the silicon atom. The same alkyl groups may be bonded to the silicon atoms, or different alkyl groups or hydrogen atoms may be bonded to the silicon atoms. All of the siloxane units constituting the oligosiloxane group may be the same as or different from each other, but it is preferable that all of them are the same as each other.

In a case where L^{W} adjacent to R^{W} is a divalent linking group represented by Formula L-3, R^{W} is a substituted or unsubstituted trialkylsilyl group. In a case where R^{W} is a substituted or unsubstituted trialkylsilyl group, a substituent of the silyl group in the trialkylsilyl group is not particularly limited as long as the substituent is a substituted or unsubstituted alkyl group, but the substituent is more preferably a branched alkyl group. The number of carbon atoms of the alkyl group bonded to each silicon atom is preferably 1 to 3. For example, it is preferable that a methyl group, an ethyl group, or an isopropyl group is bonded to the silicon atoms. The same alkyl groups or different alkyl groups may be bonded to the silicon atom. In a case where R^{W} is a trialkylsilyl group further having a substituent on an alkyl group, the substituent is not particularly limited.

In Formula W, a total number of carbon atoms contained in L^{W} and R^{W} is preferably 5 to 18. If the total number of carbon atoms contained in L^{W} and R^{W} is equal to or greater than the lower limit of the above range, carrier mobility is improved, and driving voltage is lowered. If the total number of the carbon atoms contained in L^{W} and R^{W} is equal to or less than the upper limit of the above range, solubility in an organic solvent is improved.

The total number of carbon atoms contained in L^{W} and R^{W} is preferably 5 to 14, more preferably 6 to 14, even more preferably 6 to 12, and particularly preferably 8 to 12.

In the compound represented by Formula 1, among R^{1a} to R^{1f}, the number of groups represented by Formula W is preferably 1 to 4, more preferably 1 or 2, and particularly preferably 2.

In the present invention, at least one of R^{1a} or R^{1b} in Formula 1 is preferably a group represented by Formula W. It is considered that from the viewpoint of excellent chemical stability of the compound, the highest occupied molecular orbital (HOMO) level, and packing in a film of molecules, the positions of R^{1a} and R^{1b} are suitable as substitution positions in Formula 1. Particularly, in Formula 1, if a substituent is on the two sites of R^{1a} and R^{1b}, high carrier density can be obtained.

In Formula 1, R^{1c} to R^{1f} each independently preferably represent a hydrogen atom, a fluorine atom, a substituted or unsubstituted alkyl group having 1 to 3 carbon atoms, a substituted or unsubstituted alkynyl group having two or three carbon atoms, a substituted or unsubstituted alkenyl group having two or three carbon atoms, a substituted or unsubstituted alkoxy group having one or two carbon atoms, or a substituted or unsubstituted methylthio group.

—Compound Represented by Formula 2—

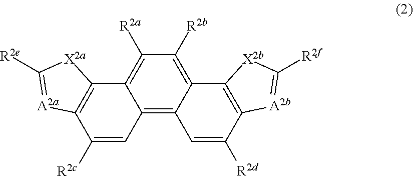

In Formula 2, X^{2a} and X^{2b} each independently represent NR²ⁱ (>N—R²ⁱ), an O atom, or a S atom. From the viewpoint of ease of synthesis, X^{2a} and X^{2b} each independently preferably represent an O atom or a S atom. In contrast, from the viewpoint of improving carrier mobility, at least one of X^{2a} or X^{2b} preferably represents a S atom.

X^{2a} and X^{2b} are preferably the same linking groups. It is more preferable that both of X^{2a} and X^{2b} are S atoms.

R²ⁱ represents a hydrogen atom, an alkyl group, an alkenyl group, an alkynyl group, or an acyl group. R²ⁱ is preferably a hydrogen atom or an alkyl group, more preferably an alkyl group having 1 to 14 carbon atoms, and particularly preferably an alkyl group having 1 to 4 carbon atoms.

In a case where R²ⁱ represents an alkyl group, the alkyl group may be linear, branched, or cyclic. It is preferable that the alkyl group is a linear alkyl group, because then linearity of the molecule is improved, and hence carrier mobility can be improved.

In Formula 2, A^{2a} represents CR^{2g} or a N atom, A^{2b} represents CR^{2h} or a N atom, and R^{2g} and R^{2h} each independently represent a hydrogen atom or a substituent. It is preferable that A^{2a} represents CR^{2g}, or A^{2b} represents CR^{2h}. It is more preferable that A^{2a} represents CR^{2g}, and A^{2b} represents CR^{2h}. A^{2a} and A^{2b} may be the same as or different from each other, but it is preferable that they are the same as each other.

In Formula 2, R^{2e} and R^{2g} may or may not for a ring by being bonded to each other, but it is preferable that they do not form a ring by being bonded to each other.

In Formula 2, R^{2f} and R^{2h} may or may not for a ring by being bonded to each other, but it is preferable that they do not form a ring by being bonded to each other.

In Formula 2, R^{2a} to R^{2h} each independently represent a hydrogen atom or a substituent, and at least one of R^{2a}, R^{2b}, R^{2c}, R^{2d}, R^{2e}, R^{2f}, R^{2g}, or R^{2h} represents a substituent represented by Formula W.

Examples of the substituent that R^{2a} to R^{2h} can each independently represent include the substituent X described above. The definition of the substituent represented by Formula W is as described above.

The substituent that R^{2a} to R^{2h} can each independently represent is preferably an alkyl group, an aryl group, an alkenyl group, an alkynyl group, a heterocyclic group, an alkoxy group, an alkylthio group, or a substituent represented by Formula W, more preferably an alkyl group having 1 to 12 carbon atoms, an aryl group having 6 to 20 carbon atoms, an alkenyl group having 2 to 12 carbon atoms, an alkynyl group having 2 to 12 carbon atoms, an alkoxy group having 1 to 11 carbon atoms, a heterocyclic group having 5 to 12 carbon atoms, an alkylthio group having 1 to 12 carbon atoms, or a group represented by Formula W, particularly preferably a group having a chain length of a linking group, which will be described later, of equal to or less than 3.7 Å or a group represented by Formula W, and more particularly preferably a group represented by Formula W.

In the compound represented by Formula 2, among R^{2a} to R^{2h}, the number of groups represented by Formula W is preferably 1 to 4 from the viewpoint of improving carrier mobility and improving solubility in an organic solvent, more preferably 1 or 2, and particularly preferably 2.

A group represented by Formula W can be positioned in any of R^{2a} to R^{2h} without particular limitation. From the viewpoint of improving carrier mobility and improving solubility in an organic solvent, the group represented by Formula W is preferably positioned in R^{2e} or R^{2f}.

Among R^{2a} to R^{2h}, the number of substituents other than a group represented by Formula W is preferably 0 to 4, more preferably 0 to 2, even more preferably 0 or 1, and particularly preferably 0.

In a case where R^{2a} to R^{2h} each represent a substituent other than a group represented by W, the substituent is preferably a group having a chain length of a linking group of equal to or less than 3.7 Å, more preferably a group having a chain length of a linking group of 1.0 to 3.7 Å, and even more preferably a group having a chain length of a linking group of 1.0 to 2.1 Å.

The chain length of a linking group refers to a length from a C atom to the terminal of a substituent R in a C (carbon atom)-R bond. The calculation for structural optimization can be performed using a density functional method (Gaussian 03 (Gaussian, Inc)/basis function: 6-31G*, exchange-correlation functional: B3LYP/LANL2DZ). Regarding a molecular length of typical substituents, a propyl group has a molecular length of 4.6 Å, a pyrrole group has a molecular length of 4.6 Å, a propynyl group has a molecular length of 4.5 Å, a propenyl group has a molecular length of 4.6 Å, an ethoxy group has a molecular length of 4.5 Å, a methylthio group has a molecular length of 3.7 Å, an ethenyl group has a molecular length of 3.4 Å, an ethyl group has a molecular length of 3.5 Å, an ethynyl group has a molecular length of 3.6 Å, a methoxy group has a molecular length of 3.3 Å, a methyl group has a molecular length of 2.1 Å, and a hydrogen atom has a molecular length of 1.0 Å.

In a case where R^{2a} to R^{2h} represent substituents other than a group represented by Formula W, the substituents each independently preferably represent a substituted or unsubstituted alkyl group having two or less carbon atoms, a substituted or unsubstituted alkynyl group having two or less carbon atoms, a substituted or unsubstituted alkenyl group having two or less carbon atoms, or a substituted or unsubstituted acyl group having two or less carbon atoms, and more preferably represent a substituted or unsubstituted alkyl group having two or less carbon atoms.

In a case where R^{2a} to R^{2h} represent substituents other than a group represented by Formula W, and the substituents each independently represent a substituted alkyl group having two or less carbon atoms, examples of substituents that the alkyl group can have include a cyano group, a fluorine atom, a deuterium atom, and the like. Among these, a cyano group is preferable. In a case where R^{2a} to R^{2h} represent substituents other than a group represented by Formula W, the substituted or unsubstituted alkyl group having two or less carbon atoms that is represented by each of the substituents is preferably a methyl group, an ethyl group, or a methyl group substituted with a cyano group, more preferably a methyl group or a methyl group substituted with a cyano group, and particularly preferably a methyl group substituted with a cyano group.

In a case where R^{2a} to R^{2h} represent substituents other than a group represented by Formula W, and the substituents each independently represent a substituted alkynyl group having two or less carbon atoms, examples of substituents that the alkynyl group can have include a deuterium atom and the like. In a case where R^{2a} to R^{2h} represent substituents other than a group represented by Formula W, examples of the substituted or unsubstituted alkynyl group having two or less carbon atoms that is represented by each of the substituents include an ethynyl group and an acetylene group substituted with a deuterium atom. Between these, an ethynyl group is preferable.

In a case where R^{2a} to R^{2h} represent substituents other than a group represented by Formula W, and the substituents each independently represent a substituted alkenyl group having two or less carbon atoms, examples of substituents that the alkenyl group can have include a deuterium atom and the like. In a case where R^{2a} to R^{2h} represent substituents other than a group represented by Formula W, examples of the substituted or unsubstituted alkenyl group having two or less carbon atoms that is represented by each of the substituents include an ethenyl group and an ethenyl group substituted with a deuterium atom. Between these, an ethenyl group is preferable.

In a case where R^{2a} to R^{2h} represent substituents other than a group represented by Formula W, and the substituents each independently represent a substituted acyl group having two or less carbon atoms, examples of substituents that the acyl group can have include a fluorine atom and the like. In a case where R^{2a} to R^{2h} represent substituents other than a group represented by Formula W, examples of the substituted or unsubstituted acyl group having two or less carbon atoms that is represented by each of the substituents include a formyl group, an acetyl group, and an acetyl group substituted with fluorine. Among these, a formyl group is preferable.

—Compound Represented by Formula 3—

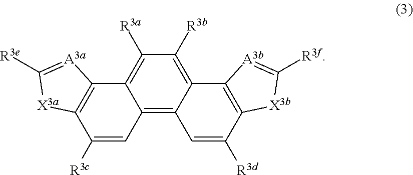

In Formula 3, R^{3a} to R^{3f} and R^{3g} and R^{3h}, which will be described later, each independently represent a hydrogen atom or a substituent. Here, at least one of R^{3a}, R^{3b}, R^{3c}, R^{3d}, R^{3e}, R^{3f}, R^{3g}, or R^{3h} represents a group represented by Formula W.

Examples of the substituent represented by R^{3a} to R^{3h} include the substituent X described above. The definition of a group represented by Formula W is as described above.

The substituent that R^{3a} to R^{3f} can each independently represent is preferably an alkyl group, an aryl group, an alkenyl group, an alkynyl group, a heterocyclic group, an alkoxy group, an alkylthio group, or a substituent represented by Formula W, and more preferably an alkyl group having 1 to 12 carbon atoms, an aryl group having 6 to 20 carbon atoms, an alkenyl group having 2 to 12 carbon atoms, an alkynyl group having 2 to 12 carbon atoms, an alkoxy group having 1 to 11 carbon atoms, a heterocyclic group having 5 to 12 carbon atoms, an alkylthio group having 1 to 12 carbon atoms, or a group represented by Formula W.

In Formula 3, X^{3a} and X^{3b} each independently represent a S atom, an O atom, or NR^{3g} (>N—R^{3g}), and R^{3g} represents a hydrogen atom or a substituent. X is preferably a S atom or an O atom. In Formula 3, X^{3a} and X^{3b} are preferably the same as each other.

R^{3g} is preferably a hydrogen atom, an alkyl group, or an aryl group, more preferably an alkyl group having 1 to 14 carbon atoms, and particularly preferably an alkyl group having 4 to 12 carbon atoms. It is preferable that R^{3g} is a long-chain alkyl group having carbon atoms within the above range, particularly, a long-chain linear alkyl group, because then linearity of the molecule is improved, and hence carrier mobility can be improved.

In a case where R^{3g} is an alkyl group, the alkyl group may be linear, branched, or cyclic. It is preferable that the alkyl group is a linear alkyl group, because then linearity of the molecule is improved, and hence carrier mobility can be improved.

In Formula 3, A^{3a} and A^{3b} each independently represent CR^{3h} or a N atom. It is preferable that A^{3a} and A^{3b} each independently represent CR^{3h}. In Formula 3, A^{3a} and A^{3b} may be the same as or different from each other, but it is preferable that they are the same as each other.

R^{3h} is a group having a chain length of a linking group of equal to or less than 3.7 Å, more preferably a group having a chain length of a linking group of 1.0 to 3.7 Å, and even more preferably a group having a chain length of a linking group of 1.0 to 2.1 Å. The definition of a chain length of a linking group is as described above.

R^{3h} is preferably a hydrogen atom, a substituted or unsubstituted alkyl group having two or less carbon atoms, a substituted or unsubstituted alkynyl group having two or less carbon atoms, a substituted or unsubstituted alkenyl group having two or less carbon atoms, or a substituted or unsubstituted acyl group having two or less carbon atoms, more preferably a hydrogen atom or a substituted or unsubstituted alkyl group having two or less carbon atoms, and particularly preferably a hydrogen atom.

In a case where R^{3h} represents a substituted alkyl group having two or less carbon atoms, examples of substituents that the alkyl group can have include a cyano group, a fluorine atom, a deuterium atom, and the like. Among these, a cyano group is preferable. The substituted or unsubstituted alkyl group having two or less carbon atoms that is represented by R^{3h} is preferably a methyl group, an ethyl group, or a methyl group substituted with a cyano group, more preferably a methyl group or a methyl group substituted with a cyano group, and particularly preferably a methyl group substituted with a cyano group.

In a case where R^{3h} represents a substituted alkynyl group having two or less carbon atoms, examples of substituents that the alkynyl group can have include a deuterium atom and the like. Examples of the substituted or unsubstituted alkynyl group having two or less carbon atoms that is represented by R^{3h} include an ethynyl group and an acetylene group substituted with a deuterium atom. Between these, an ethynyl group is preferable.

In a case where R^{3h} represents a substituted alkenyl group having two or less carbon atoms, examples of substituents that the alkenyl group can have include a deuterium atom and the like. Examples of the substituted or unsubstituted alkenyl group having two or less carbon atoms that is represented by R^{3h} include an ethenyl group and an ethenyl group substituted with a deuterium atom. Between these, an ethenyl group is preferable.

In a case where R^{3h} represents a substituted acyl group having two or less carbon atoms, examples of substituents that the acyl group can have include a fluorine atom and the like. Examples of the substituted or unsubstituted acyl group having two or less carbon atoms that is represented by R^{3h} include a formyl group, an acetyl group, and an acetyl group substituted with a fluorine atom. Among these, a formyl group is preferable.

—Compound Represented by Formula 4—

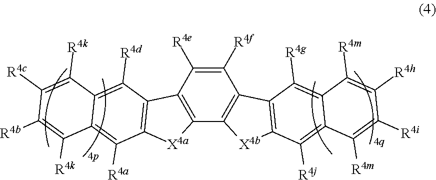

In Formula 4, X^{4a} and X^{4b} each independently represent an O atom, a S atom, or a Se atom.

It is preferable that X^{4a} and X^{4b} each independently represent an O atom or a S atom. From the viewpoint of improving carrier mobility, it is more preferable that at least one of X^{4a} or X^{4b} is a S atom. It is preferable that X^{4a} and X^{4b} are the same linking groups. It is particularly preferable that both of X^{4a} and X^{4b} are S atoms.

In Formula (4), 4p and 4q each independently represent an integer of 0 to 2. It is preferable that 4p and 4q each independently represent 0 or 1, because then mobility and solubility can be achieved at the same time. It is more preferable that 4p=4q=0 or 4p=4q=1.

In Formula 4, R^{4a} to R^{4k} and R^{4m} each independently represent a hydrogen atom, a halogen atom, or a group represented by Formula W, and at least one of R^{4a}, R^{4b}, R^{4c}, R^{4d}, R^{4e}R^{4f}, R^{4g}, R^{4h}, R⁴ⁱ, R^{4j}, R^{4k}, or R^{4m} is a group represented by Formula W. Here, in a case where at least one of R^{4e} or R^{4f} is a group represented by Formula W, in W represented by R^{4e} and R^{4f}, L^{W} is a divalent linking group represented by Formula L-2 or L-3. The definition of a group represented by Formula W is as described above.

The case where at least one of R^{4e} or R^{4f} is a group represented by Formula W corresponds to a case where none of R^{4e} and R^{4f} are a hydrogen atom or a halogen atom.

In a case where at least one of R^{4e} or R^{4f} is a group represented by Formula W, in W represented by R^{4e} or R^{4f}, L^{W} is preferably a divalent linking group represented by Formula L-3.

In a case where at least one of R^{4e} or R^{4f} is a group represented by Formula W, both of R^{4e} and R^{4f} preferably represent a group represented by Formula W.

In a case where both of R^{4e} and R^{4f} represent a hydrogen atom or a halogen atom, R^{4a} to R^{4d}, R^{4g} to R^{4k}, and R^{4m} each independently represent a hydrogen atom, a halogen atom, or a group represented by Formula W, and at least one or more out of R^{4a}, R^{4b}, R^{4c}, R^{4d}, R^{4g}, R^{4h}, R⁴ⁱ, R^{4j}, R^{4k}, or R^{4m} is a group represented by Formula W.

Examples of the halogen atom represented by R^{4a} to R^{4k} and R^{4m} in Formula 4 include a fluorine atom, a chlorine atom, a bromine atom, and an iodine atom. The halogen atom is preferably a fluorine atom, a chlorine atom, or a bromine atom, more preferably a fluorine atom or a chlorine atom, and particularly preferably a fluorine atom.

In R^{4a} to R^{4k} and R^{4m} in the compound represented by Formula 4, the number of halogen atoms is preferably 0 to 4, more preferably 0 to 2, even more preferably 0 or 1, and particularly preferably 0.

In the compound represented by Formula 4, among R^{4a} to R^{4k} and R^{4m}, the number of groups represented by Formula W is preferably 1 to 4 from the viewpoint of improving carrier mobility and improving solubility in an organic solvent, more preferably 1 or 2, and particularly preferably 2.

A group represented by Formula W can be positioned in any of R^{4a} to R^{4k} and R^{4m} without particular limitation. In the present invention, from the viewpoint of improving carrier mobility and improving solubility in an organic solvent, it is preferable that, in Formula 4, R^{4a}, R^{4d} to R^{4g}, R^{4j}, R^{4k}, and R^{4m} each independently represent a hydrogen atom or a halogen atom, R^{4b}, R^{4c}, R^{4h}, and R⁴ⁱ each independently represent a hydrogen atom, a halogen atom, or a group represented by Formula W, and at least one of R^{4b}, R^{4c}, R^{4h}, or R⁴ⁱ is a group represented by Formula W.

In the present invention, it is more preferable that R^{4a}, R^{4c} to R^{4h}, and R^{4j} each independently represent a hydrogen atom or a halogen atom, R^{4b} and R⁴ⁱ each independently represent a hydrogen atom, a halogen atom, or a group represented by Formula W, and at least one of R^{4b} or R⁴ⁱ is a group represented by Formula W.

In the present invention, it is even more preferable that both of R^{4b} and R⁴ⁱ represent a group represented by Formula W, both of R^{4c} and R^{4h} represent a hydrogen atom or a halogen atom, or both of R^{4c} and R^{4h} represent a group represented by Formula W, and both of R^{4b} and R⁴ⁱ represent a hydrogen atom or a halogen atom.

In the present invention, it is particularly preferable that both of R^{4b} and R⁴ⁱ represent a group represented by Formula W and both of R^{4c} and R^{4h} represent a hydrogen atom or a halogen atom, or both of R^{4c} and R^{4h} represent a group represented by Formula W and both of R^{4b} and R⁴ⁱ represent a hydrogen atom and a halogen atom.

In Formula 4, two or more groups among R^{4a} to R^{4k} and R^{4m} may or may not form a ring by being bonded to each other, but it is preferable that they do not form a ring by being bonded to each other.

—Compound Represented by Formula 5—

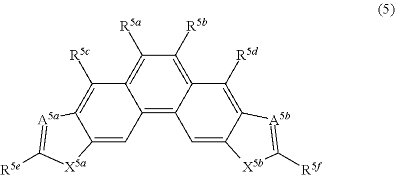

In Formula 5, X^{5a} and X^{5b} each independently represent NR⁵ⁱ, an O atom, or a S atom. From the viewpoint of ease of synthesis, it is preferable that X^{5a} and X^{5b} each independently represent an O atom or a S atom. In contrast, from the viewpoint of improving carrier mobility, it is preferable that at least one of X^{5a} or X^{5b} is a S atom. It is preferable that X^{5a} and X^{5b} are the same linking groups. It is more preferable that both of X^{5a} and X^{5b} are S atoms.

R⁵ⁱ represents a hydrogen atom, an alkyl group, an alkenyl group, an alkynyl group, an acyl group, an aryl group, or a heteroaryl group. R⁵ⁱ is preferably a hydrogen atom, an alkyl group, an alkenyl group, an alkynyl group, or an acyl group, more preferably a hydrogen atom or an alkyl group, even more preferably an alkyl group having 1 to 14 carbon atoms, and preferably an alkyl group having 1 to 4 carbon atoms.

In a case where R⁵ⁱ is an alkyl group, the alkyl group may be linear, branched, or cyclic. It is preferable that R⁵ⁱ is a linear alkyl group, because then linearity of the molecule is improved, and hence carrier mobility can be improved.

In Formula 5, A^{5a} represents CR^{5g} or a N atom, A^{5b} represents CR^{5h} or a N atom, and R^{5g} and R^{5h} each independently represent a hydrogen atom or a substituent. It is preferable that A^{5a} represents CR^{5g} or A^{5b} represents CR^{5h}. It is more preferable that A^{5a} represents CR^{5g} and A^{5b} represents CR^{5h}. A^{5a} and A^{5b} may be the same as or different from each other, but it is preferable that they are the same as each other.

In Formula 5, R^{5e} and R^{5g} may or may not form a ring by being bonded to each other, but it is preferable that they do not form a ring by being bonded to each other.

In Formula 5, R^{5e} and R⁵ⁱ may or may not form a ring by being bonded to each other, but it is preferable that they do not form a ring by being bonded to each other.

In Formula 5, R^{5f} and R^{5h} may or may not form a ring by being bonded to each other, but it is preferable that they do not form a ring by being bonded to each other.

In Formula 5, R^{5f} and R⁵ⁱ may or may not form a ring by being bonded to each other, but it is preferable that they do not form a ring by being bonded to each other.

In Formula 5, R^{5a} to R^{5h} each independently represent a hydrogen atom or a substituent, and at least one of R^{5a}, R^{5b}, R^{5c}, R^{5d}, R^{5e}, R^{5f}, R^{5g}, or R^{5h} is a group represented by Formula W. Examples of the substituent represented by R^{5a} to R^{5h} include the substituent X described above. The definition of a group represented by Formula W is as described above.

In the compound represented by Formula 5, among R^{5a} to R^{5h}, the number of groups represented by Formula W is preferably 1 to 4 from the viewpoint of improving carrier mobility and improving solubility in an organic solvent, more preferably 1 or 2, and particularly preferably 2.

A group represented by Formula W can be positioned in any of R^{5a} to R^{5h} without particular limitation. From the viewpoint of improving carrier mobility and improving solubility in an organic solvent, the group represented by Formula W is preferably positioned in R^{5e} or R^{5f}.

Among R^{5a} to R^{5h}, the number of substituents other than a group represented by Formula W is preferably 0 to 4, more preferably 0 to 2, particularly preferably 0 or 1, and more particularly preferably 0.

In a case where R^{5a} to R^{5h} represent substituents other than a group represented by Formula W, each of the substituents is preferably a group having a chain length of a linking group of equal to or less than 3.7 Å, more preferably a group having a chain length of a linking group of 1.0 to 3.7 Å, even more preferably a group having a chain length of a linking group of 1.0 to 2.1 Å. The definition of a chain length of a linking group is as described above.

In a case where R^{5a} to R^{5h} represent substituents other than a group represented by Formula W, the substituents each independently preferably represent a substituted or unsubstituted alkyl group having two or less carbon atoms, a substituted or unsubstituted alkynyl group having two or less carbon atoms, a substituted or unsubstituted alkenyl group having two or less carbon atoms, or a substituted or unsubstituted acyl group having two or less carbon atoms, and more preferably represent a substituted or unsubstituted alkyl group having two or less carbon atoms.

In a case where R^{5a} to R^{5h} represent substituents other than a group represented by Formula W, and the substituents each independently represent a substituted alkyl group having two or less carbon atoms, examples of substituents that the alkyl group can have include a cyano group, a fluorine atom, a deuterium atom, and the like. Among these, a cyano group is preferable. In a case where R^{5a} to R^{5h} represent substituents other than a group represented by Formula W, the substituted or unsubstituted alkyl group having two or less carbon atoms that is represented by each of the substituents is preferably a methyl group, an ethyl group, or a methyl group substituted with a cyano group, more preferably a methyl group or a methyl group substituted with a cyano group, and particularly preferably a methyl group substituted with a cyano group.

In a case where R^{5a} to R^{5h} represent substituents other than a group represented by Formula W, and the substituents each independently represent a substituted alkynyl group having two or less carbon atoms, examples of substituents that the alkynyl group can have include a deuterium atom and the like. In a case where R^{5a} to R^{5h} represent substituents other than a substituent represented by Formula W, examples of the substituted or unsubstituted alkynyl group having two or less carbon atoms that is represented by each of the substituents include an ethynyl group or an acetylene group substituted with a deuterium atom. Between these, an ethynyl group is preferable.

In a case where R^{5a} to R^{5h} represent substituents other than a group represented by Formula W, and the substituents each independently represent a substituted alkenyl group having two or less carbon atoms, examples of substituents that the alkenyl group can have include deuterium atom and the like. In a case where R^{5a} to R^{5h} represent substituents other than a group represented by Formula W, examples of the substituted or unsubstituted alkenyl group having two or less carbon atoms that is represented by each of the substituents include an ethenyl group and an ethenyl group substituted with a deuterium atom. Between these, an ethenyl group is preferable.

In a case where R^{5a} to R^{5h} represent substituents other than a group represented by Formula W, and the substituents each independently represent a substituted acyl group having two or less carbon atoms, examples of substituents that the acyl group can have include a fluorine atom and the like. In a case where R^{5a} to R^{5h} represent substituents other than a group represented by Formula W, examples of the substituted or unsubstituted acyl group having two or less carbon atoms that is represented by each of the substituents include a formyl group, an acetyl group, and an acetyl group substituted with a fluorine atom. Among these, a formyl group is preferable.

—Compound Represented by Formula 6—

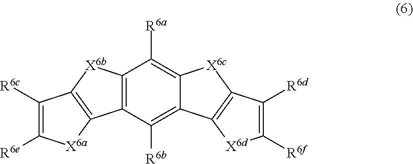

In Formula 6, X^{6a} to X^{6d} each independently represent NR^{6g}, an O atom, or a S atom, and R^{6g} represents a hydrogen atom, an alkyl group, an alkenyl group, an alkynyl group, an acyl group, an aryl group, or a heteroaryl group.

From the viewpoint of ease of synthesis, it is preferable that X^{6a} to X^{6d} each independently represent an O atom or a S atom. In contrast, from the viewpoint of improving carrier mobility, at least one of X^{6a}, X^{6b}, X^{6c}, or X^{6d} is a S atom. It is preferable that X^{6a} to X^{6d} are the same linking groups. It is more preferable that all of X^{6a} to X^{6d} are S atoms.

R^{6g} represents a hydrogen atom, an alkyl group, an alkenyl group, an alkynyl group, an acyl group, an aryl group, or a heteroaryl group. R^{6g} is preferably a hydrogen atom, an alkyl group, an alkenyl group, an alkynyl group, or an acyl group, more preferably a hydrogen atom or an alkyl group, even more preferably an alkyl group having 1 to 14 carbon atoms, and particularly preferably an alkyl group having 1 to 4 carbon atoms.

In a case where R^{6g} represents an alkyl group, the alkyl group may be linear, branched, or cyclic. However, it is preferable that R^{6g} is a linear alkyl group, because then linearity of the molecule is improved, and hence carrier mobility can be improved.

In Formula 6, R^{6a} to R^{6f} each independently represent a hydrogen atom or a substituent, and at least one of R^{6a}, R^{6b}, R^{6c}, R^{6d}, R^{6e}, or R^{6f} represents a group represented by Formula W.

Examples of the substituents represented by R^{6a} to R^{6f} include the substituent X described above. The definition of a group represented by Formula W is as described above.

Among the substituents, the substituent that R^{6a} to R^{6f} can each independently represent is preferably an alkyl group, an aryl group, an alkenyl group, an alkynyl group, a heterocyclic group, an alkoxy group, an alkylthio group, or a group represented by Formula W, more preferably an alkyl group having 1 to 12 carbon atoms, an aryl group having 6 to 20 carbon atoms, an alkenyl group having 2 to 12 carbon atoms, an alkynyl group having 2 to 12 carbon atoms, an alkoxy group having 1 to 11 carbon atoms, a heterocyclic group having 5 to 12 carbon atoms, an alkylthio group having 1 to 12 carbon atoms, or a group represented by Formula W, even more preferably a group, which will be described later, having a chain length of a linking group of equal to or less than 3.7 Å or a group represented by Formula W, and particularly preferably a group represented by Formula W.

In the compound represented by Formula 6, among R^{6a} to R^{6f}, the number of groups represented by Formula W is preferably 1 to 4 from the viewpoint of improving carrier mobility and improving solubility in an organic solvent, more preferably 1 or 2, and particularly preferably 2.

A group represented by Formula W can be positioned in any of R^{6a} to R^{6f} without particular limitation, but the group represented by Formula W is preferably positioned in R^{6c} to R^{6f}. From the viewpoint of improving carrier mobility and improving solubility in an organic solvent, the group represented by Formula W is more preferably positioned in R^{6e} or R^{6f}

Among R^{6a} to R^{6f}, the number of substituents other than a group represented by Formula W is preferably 0 to 4, more preferably 0 to 2, even more preferably 0 or 1, and particularly preferably 0.

In a case where R^{6a} to R^{6f} represent substituents other than a group represented by Formula W, each of the substituents is preferably a group having a chain length of a linking group of equal to or less than 3.7 Å, more preferably a group having a chain length of a linking group of 1.0 to 3.7 Å, and even more preferably a group having a chain length of a linking group of 1.0 to 2.1 Å. The definition of a chain length of a linking group is as described above.

In a case where R^{6a} to R^{6f} represent substituents other than a group represented by Formula W, the substituents each independently preferably represent a substituted or unsubstituted alkyl group having two or less carbon atoms, a substituted or unsubstituted alkynyl group having two or less carbon atoms, a substituted or unsubstituted alkenyl group having two or less carbon atoms, or a substituted or unsubstituted acyl group having two or less carbon atoms, and more preferably a substituted or unsubstituted alkyl group having two or less carbon atoms.

In a case where R^{6a} to R^{6f} represent substituents other than a group represented by Formula W, and the substituents each independently represent a substituted alkyl group having two or less carbon atoms, examples of substituents that the alkyl group can have include a cyano group, a fluorine atom, a deuterium atom, and the like. Among these, a cyano group is preferable. In a case where R^{6a} to R^{6f} represent substituents other than a group represented by Formula W, the substituted or unsubstituted alkyl group having two or less carbon atoms that is represented by each of the substituents is preferably a methyl group, an ethyl group, or a methyl group substituted with a cyano group, more preferably a methyl group or a methyl group substituted with a cyano group, and particularly preferably a methyl group substituted with a cyano group.

In a case where R^{6a} to R^{6f} represent substituents other than a group represented by Formula W, and the substituents each independently represent a substituted alkynyl group having two or less carbon atoms, examples of substituents that the alkynyl group can have include a deuterium atom and the like. In a case where R^{6a} to R^{6f} represent substituents other than a group represented by Formula W, examples of the substituted or unsubstituted alkynyl group having two or less carbon atoms that is represented by each of the substituents include an ethynyl group and an acetylene group substituted with a deuterium atom. Between these, an ethynyl group is preferable.

In a case where R^{6a} to R^{6f} represent substituents other than a group represented by Formula W, and the substituents each independently represent a substituted alkenyl group having two or less carbon atoms, examples of substituents that the alkenyl group can have include a deuterium atom and the like. In a case where R^{6a} to R^{6f} represent substituents other than a group represented by Formula W, examples of the substituted or unsubstituted alkenyl group having two or less carbon atoms that is represented by each of the substituents include ethenyl group and an ethenyl group substituted with a deuterium atom. Among these, an ethenyl group is preferable.

In a case where R^{6a} to R^{6f} represent substituents other than a group represented by Formula W, and the substituents each independently represent a substituted acyl group having two or less carbon atoms, examples of substituents that the acyl group can have include a fluorine atom and the like. In a case where R^{6a} to R^{6f} represent substituents other than a group represented by Formula W, examples of the substituted or unsubstituted acyl group having two or less carbon atoms that is represented by each of the substituents include a formyl group, an acetyl group, and an acetyl group substituted with a fluorine atom. Among these, a formyl group is preferable.

—Compound Represented by Formula 7—

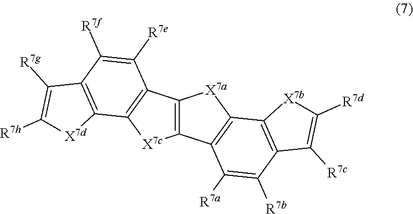

In Formula 7, X^{7a} and X^{7c} each independently represent a S atom, an O atom, a Se atom, or NR⁷ⁱ (>N—R⁷ⁱ), and X^{7b} and X^{7d} each independently represent a S atom, an O atom, or a Se atom. From the viewpoint of ease of synthesis, it is preferable that X^{7a} to X^{7d} each independently represent an O atom or a S atom. In contrast, from the viewpoint of improving carrier mobility, it is preferable that at least one of X^{7a}, X^{7b}, X^{7c}, or X^{7d} is a S atom. It is preferable that X^{7a} to X^{7d} are the same linking groups. It is more preferable that all of X^{7a} to X^{7d} are S atoms.

In Formula 7, R^{7a} to R⁷ⁱ each independently represent a hydrogen atom or a substituent, and at least one of R^{7a}, R^{7b}, R^{7c}, R^{7d}, R^{7e}, R^{7f}, R^{7g}, R^{7h}, or R⁷ⁱ is a group represented by Formula W.

Examples of the substituent represented by R^{7a} to R⁷ⁱ include the substituent X described above. The definition of a group represented by Formula W is as described above.

R⁷ⁱ is preferably a hydrogen atom or an alkyl group, more preferably an alkyl group having 5 to 12 carbon atoms, and particularly preferably an alkyl group having 8 to 10 carbon atoms.

In a case where R⁷ⁱ represents an alkyl group, the alkyl group may be linear, branched, or cyclic. However, from the viewpoint of overlapping of HOMO, it is preferable that R⁷ⁱ is a linear alkyl group.

In R^{7a} to R⁷ⁱ in the compound represented by Formula 7, the number of substituents represented by Formula W is preferably 1 to 4 from the viewpoint of improving carrier mobility and improving solubility in an organic solvent, more preferably 1 or 2, and particularly preferably 2.

A group represented by Formula W can be positioned in any of R^{7a} to R⁷ⁱ without particular limitation. The group represented by Formula W is preferably positioned in R^{7d} or R^{7h} from the viewpoint of improving carrier mobility and improving solubility in an organic solvent, and more preferably positioned in R^{7d} and R^{7h}.

Among R^{7a} to R⁷ⁱ of Formula 7, the number of substituents other than a group represented by Formula W is preferably 0 to 4, more preferably 0 to 2, even more preferably 0 or 1, and particularly preferably 0.

In a case where R^{7a} to R⁷ⁱ are substituents other than a group represented by Formula W, each of the substituents is preferably a group having a chain length of a linking group of equal to or less than 3.7 Å, more preferably a group having a chain length of a linking group of 1.0 to 3.7 Å, and even more preferably a group having a chain length of a linking group of 1.0 to 2.1 Å. The definition of a chain length of a linking group is as described above.

In a case where R^{7a} to R⁷ⁱ are substituents other than a group represented by Formula W, the substituents each independently preferably represent a substituted or unsubstituted alkyl group having two or less carbon atoms, a substituted or unsubstituted alkynyl group having two or less carbon atoms, a substituted or unsubstituted alkenyl group having two or less carbon atoms, or a substituted or unsubstituted acyl group having two or less carbon atoms, and more preferably represent a substituted or unsubstituted alkyl group having two or less carbon atoms.

In a case where R^{7a} to R⁷ⁱ are substituents other than a group represented by Formula W, and the substituents each independently represent a substituted alkyl group having two or less carbon atoms, examples of substituents that the alkyl group can have include a cyano group, a fluorine atom, a deuterium atom, and the like. Among these, a cyano group is preferable. In a case where R^{7a} to R⁷ⁱ are substituents other than a group represented by Formula W, the substituted or unsubstituted alkyl group having two or less carbon atoms that is represented by each of the substituents is preferably a methyl group, an ethyl group, or a methyl group substituted with a cyano group, more preferably a methyl group or a methyl group substituted with a cyano group, and particularly preferably a methyl group substituted with a cyano group.

In a case where R^{7a} to R⁷ⁱ are substituents other than a group represented by Formula W, and the substituents each independently represent a substituted alkynyl group having two or less carbon atoms, examples of substituents that the alkynyl group can have include a deuterium atom and the like. In a case where R^{7a} to R⁷ⁱ are substituents other than a substituent represented by Formula W, examples of the substituted or unsubstituted alkynyl group having two or less carbon atoms that is represented by each of the substituents include an ethynyl group and an acetylene group substituted with a deuterium atom. Between these, an ethynyl group is preferable.

In a case where R^{7a} to R⁷ⁱ are substituents other than a group represented by Formula W, and the substituents each independently represent a substituted alkenyl group having two or less carbon atoms, examples of substituents that the alkenyl group can have include a deuterium atom and the like. In a case where R^{7a} to R⁷ⁱ are substituents other than a substituent represented by Formula W, examples of the substituted or unsubstituted alkenyl group having two or less carbon atoms that is represented by each of the substituents include an ethenyl group and an ethenyl group substituted with a deuterium atom. Between these, an ethenyl group is preferable.

In a case where R^{7a} to R⁷ⁱ are substituents other than a group represented by Formula W, and the substituents each independently represent a substituted acyl group having two or less carbon atoms, examples of substituents that the acyl group can have include a fluorine atom and the like. In a case where R^{7a} to R⁷ⁱ are substituents other than a substituent represented by Formula W, examples of the substituted or unsubstituted acyl group having two or less carbon atoms that is represented by each of the substituents include a formyl group, an acetyl group, and an acetyl group substituted with a fluorine atom. Among these, a formyl group is preferable.

—Compound Represented by Formula 8—

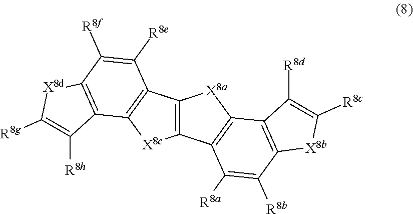

In Formula 8, X^{8a} and X^{8c} each independently represent a S atom, an O atom, a Se atom, or NR⁸ⁱ, and X^{8b} and X^{8d} each independently represent a S atom, an O atom, or a Se atom. From the viewpoint of ease of synthesis, it is preferable that X^{8a} to X^{8d} each independently represent an O atom or a S atom. In contrast, from the viewpoint of improving carrier mobility, it is preferable that at least one of X^{8a}, X^{8b}, X^{8c}, or X^{8d} is a S atom. It is preferable that X^{8a} to X^{8d} are the same linking groups. It is more preferable that all of X^{8a} to X^{8d} are S atoms.

In Formula 8, R^{8a} to R⁸ⁱ each independently represent a hydrogen atom or a substituent, and at least one of R^{8a}, R^{8b}, R^{8c}, R^{8d}, R^{8e}, R^{8f}, R^{8g}, R^{8h}, or R⁸ⁱ is a group represented by Formula W.

Examples of the substituent represented by R^{8a} to R⁸ⁱ include the substituent X described above. The definition of a group represented by Formula W is as described above.

R⁸ⁱ is preferably a hydrogen atom or an alkyl group, more preferably an alkyl group having 5 to 12 carbon atoms, and particularly preferably an alkyl group having 8 to 10 carbon atoms.

In a case where R⁸ⁱ is an alkyl group, the alkyl group may be linear, branched, or cyclic. From the viewpoint of the overlapping of HOMO, R⁸ⁱ is preferably a linear alkyl group.

In the compound represented by Formula 8, among R^{8a} to R⁸ⁱ, the number of substituents represented by Formula W is preferably 1 to 4 from the viewpoint of improving carrier mobility and improving solubility in an organic solvent, more preferably 1 or 2, and particularly preferably 2.

A group represented by Formula W can be positioned in any of R^{8a} to R⁸ⁱ without particular limitation. The group represented by Formula W is preferably positioned in R^{8c} or R^{8g} from the viewpoint of improving carrier mobility and improving solubility in an organic solvent, and more preferably positioned in R^{8c} and R^{8g}.

Among R^{8a} to R⁸ⁱ of Formula 8, the number of substituents other than a group represented by Formula W is preferably 0 to 4, more preferably 0 to 2, even more preferably 0 or 1, and particularly preferably 0.

In a case where R^{8a} to R⁸ⁱ are substituents other than a group represented by Formula W, each of the substituents is preferably a group having a chain length of a linking group of equal to or less than 3.7 Å, more preferably a group having a chain length of a linking group of 1.0 to 3.7 Å, and even more preferably a group having a chain length of a linking group of 1.0 to 2.1 Å. The definition of a chain length of a linking group is as described above.

In a case where R^{8a} to R⁸ⁱ are substituents other than a group represented by Formula W, the substituents each independently preferably represent a substituted or unsubstituted alkyl group having two or less carbon atoms, a substituted or unsubstituted alkynyl group having two or less carbon atoms, a substituted or unsubstituted alkenyl group having two or less carbon atoms, or a substituted or unsubstituted acyl group having two or less carbon atoms, and more preferably represent a substituted or unsubstituted alkyl group having two or less carbon atoms.

In a case where R^{8a} to R⁸ⁱ are substituents other than a group represented by Formula W, and the substituents each independently represent a substituted alkyl group having two or less carbon atoms, examples of substituents that the alkyl group can have include a cyano group, a fluorine atom, a deuterium atom, and the like. Among these, a cyano group is preferable. In a case where R^{8a} to R⁸ⁱ are substituents other than a group represented by Formula W, the substituted or unsubstituted alkyl group having two or less carbon atoms that is represented by each of the substituents is preferably methyl group, an ethyl group, or a methyl group substituted with a cyano group, more preferably a methyl group or a methyl group substituted with a cyano group, and particularly preferably a methyl group substituted with a cyano group.

In a case where R^{8a} to R⁸ⁱ are substituents other than a group represented by Formula W, and the substituents each independently represent a substituted alkynyl group having two or less carbon atoms, examples of substituents that the alkynyl group can have include a deuterium atom and the like. In a case where R^{8a} to R⁸ⁱ are substituents other than a group represented by Formula W, examples of the substituted or unsubstituted alkynyl group having two or less carbon atoms that is represented by each of the substituents include an ethynyl group and an acetylene group substituted with a deuterium atom. Between these, an ethynyl group is preferable.

In a case where R^{8a} to R⁸ⁱ are substituents other than a group represented by Formula W, and the substituents each independently represent a substituted alkenyl group having two or less carbon atoms, examples of substituents that the alkenyl group can have include a deuterium atom and the like. In a case where R^{8a} to R⁸ⁱ are substituents other than a group represented by Formula W, examples of the substituted or unsubstituted alkenyl group having two or less carbon atoms that is represented by each of the substituents include an ethenyl group and an ethenyl group substituted with a deuterium atom. Between these, an ethenyl group is preferable.

In a case where R^{8a} to R^{gi} are substituents other than a group represented by Formula W, and the substituents each independently represent a substituted acyl group having two or less carbon atoms, examples of substituents that the acyl group can have include a fluorine atom and the like. In a case where R^{8a} to R⁸ⁱ are substituents other than a group represented by Formula W, examples of the substituted or unsubstituted acyl group having two or less carbon atoms that is represented by each of the substituents include a formyl group, an acetyl group, and an acetyl group substituted with a fluorine atom. Among these, a formyl group is preferable.

—Compound Represented by Formula 9—

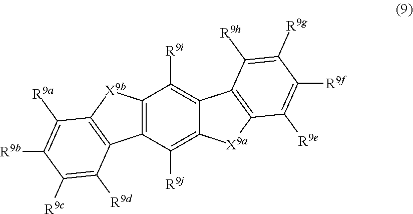

In Formula 9, X^{9a} and X^{9b} each independently represent an O atom, a S atom, or a Se atom. Among these, a S atom is preferable.

R^{9c}, R^{9d}, and R^{9g} to R^{9j} each independently represent a hydrogen atom, a halogen atom, or a substituent represented by Formula W. The definition of a group represented by Formula W is as described above.

R^{9a}, R^{9b}, R^{9e}, and R^{9f} each independently represent a hydrogen atom or a substituent. Examples of the substituent represented by R^{9a}, R^{9b}, R^{9e}, and R^{9f} include the substituent X described above.

It is preferable that R^{9c}, R^{9d}, and R^{9g} to R^{9j} each independently represent a hydrogen atom, a halogen atom, or a group represented by Formula W (here, L^{W} is a group represented by any one of Formulae L-3, L-5, L-7 to L-9, and L-12 to L-24). Among these, R^{9c}, R^{9d}, and R^{9g} to R^{9j} are more preferably represent a hydrogen atom.

L^{W} is preferably a group represented by any one of Formulae L-3, L-5, L-13, L-17, and L-18.

It is preferable that at least one of R^{9a}, R^{9b}, R^{9c}, R^{9d}, R^{9e}, R^{9f}, R^{9g}, R^{9h}, or R⁹ⁱ is a group represented by Formula W.

In the compound represented by Formula 9, among R^{9a} to R⁹ⁱ, the number of substituents represented by Formula W is preferably 1 to 4 from the viewpoint of improving carrier mobility and improving solubility in an organic solvent, more preferably 1 or 2, and particularly preferably 2.

A group represented by Formula W can be positioned in any of R^{9a} to R⁹ⁱ without particular limitation. The group represented by Formula W is preferably positioned in R^{9b} or R^{9f} from the viewpoint of improving carrier mobility and improving solubility in an organic solvent, and more preferably positioned in R^{9b} and R^{9f}.

Among R^{9a} to R⁹ⁱ of Formula 9, the number of substituents other than a group represented by Formula W is preferably 0 to 4, more preferably 0 to 2, particularly preferably 0 or 1, and more particularly preferably 0.

—Compound Represented by Formula 10—

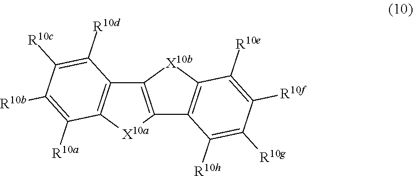

In Formula 10, R^{10a} to R^{10h} each independently represent a hydrogen atom or a substituent, and at least one of R^{10a}, R^{10b}, R^{10c}, R^{10d}, R^{10e}, R^{10f}, R^{10g}, or R^{10h} represents a group represented by Formula W. Examples of the substituent represented by R^{10a} to R^{10h} include the substituent X described above. The definition of a substituent represented by Formula W is as described above.

It is preferable that R^{10a} to R^{10h} each independently represent a hydrogen atom, a halogen atom, or a substituent, and at least one of R^{10a}, R^{10b}, R^{10c}, R^{10d}, R^{10e}, R^{10f}, R^{10g}, or R^{10h} is a substituted or unsubstituted arylthio group, a substituted or unsubstituted heteroarylthio group, a substituted or unsubstituted alkyloxycarbonyl group, a substituted or unsubstituted aryloxycarbonyl group, or a substituted or unsubstituted alkylamino group.

Among R^{10a} to R^{10h} of Formula 10, at least one of R^{10b} or R^{10f} is preferably a substituted or unsubstituted arylthio group, a substituted or unsubstituted heteroarylthio group, a substituted or unsubstituted alkyloxycarbonyl group, a substituted or unsubstituted aryloxycarbonyl group, or a substituted or unsubstituted alkylamino group, and more preferably a substituted or unsubstituted arylthio group or a substituted or unsubstituted heteroaryl group. It is even more preferable that both of R^{10b} and R^{10f} represent a substituted or unsubstituted arylthio group or a substituted or unsubstituted heteroarylthio group. It is particularly preferable that both of R^{10b} and R^{10f} represent a substituted or unsubstituted phenylthio group or a heteroarylthio group selected from the following group A. It is the most preferable that both of R^{10b} and R^{10f} represent a substituted or unsubstituted phenylthio group or a heteroarylthio group represented by the following Formula A-17, A-18, or A-20.

The arylthio group is preferably a group in which a sulfur atom is linked to an aryl group having 6 to 20 carbon atoms, more preferably a naphthylthio group or a phenylthio group, and particularly preferably a phenylthio group.

The heteroarylthio group is preferably a group in which a sulfur atom is linked to a 3- to 10-membered heteroaryl group, more preferably a group in which a sulfur atom is linked to a 5- or 6-membered heteroaryl group, and particularly preferably the following group A.

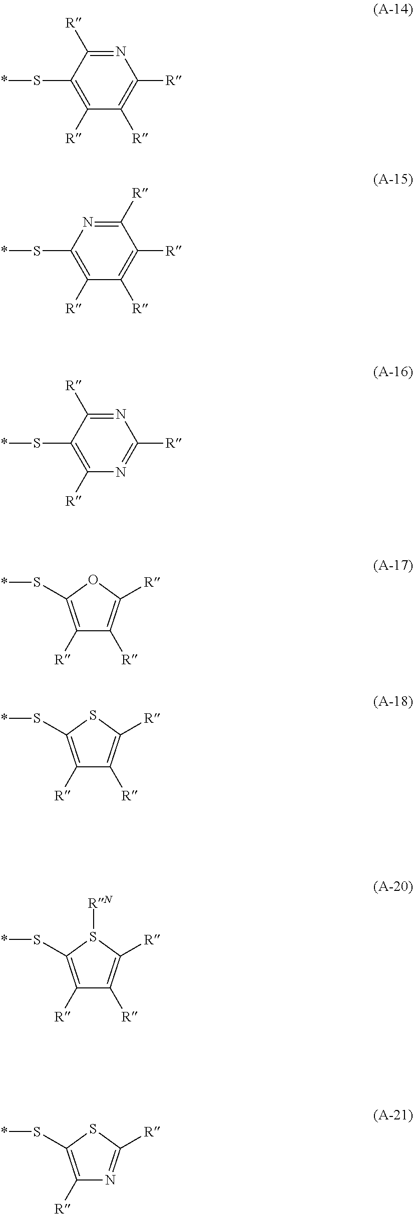

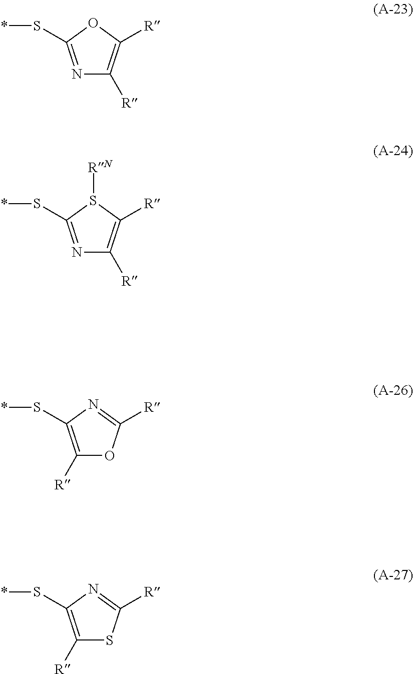

In the group A, R″ and R″^{N} each independently represent a hydrogen atom or a substituent.

It is preferable that R″ in the group A each independently represents a hydrogen atom or a group represented by Formula W.

R″^{N} in the group A preferably represents a substituent, more preferably represents an alkyl group, an aryl group, or a heteroaryl group, even more preferably represents an alkyl group, an aryl group substituted with an alkyl group, or a heteroaryl group substituted with an alkyl group, and particularly preferably represents an alkyl group having 1 to 4 carbon atoms, a phenyl group substituted with an alkyl group having 1 to 4 carbon atoms, or a 5-membered heteroaryl group substituted with an alkyl group having 1 to 4 carbon atoms.

As the alkyloxycarbonyl group, a group in which a carbonyl group is linked to an alkyl group having 1 to 20 carbon atoms is preferable. The number of carbon atoms of the alkyl group is more preferably 2 to 15, and particularly preferably 5 to 10.

As the aryloxycarbonyl group, a group in which a carbonyl group is linked to an aryl group having 6 to 20 carbon atoms is preferable. The number of carbon atoms of the aryl group is more preferably 6 to 15, and particularly preferably 8 to 12.

As the alkylamino group, a group in which an amino group is linked to an alkyl group having 1 to 20 carbon atoms is preferable. The number of carbon atoms of the alkyl group is more preferably 2 to 15, and particularly preferably 5 to 10.

Among R^{10a} to R^{10h}, the number of substituents (hereinafter, referred to as other substituents as well) other than a substituted or unsubstituted arylthio group, a substituted or unsubstituted heteroarylthio group, a substituted or unsubstituted alkyloxycarbonyl group, a substituted or unsubstituted aryloxycarbonyl group, or a substituted or unsubstituted alkylamino group is preferably 0 to 4, more preferably 0 to 2, particularly preferably 0 or 1, and more particularly preferably 0.

X^{10a} and X^{10b} each independently represent a S atom, an O atom, a Se atom, or NR^{x} (>N—R^{x}). From the viewpoint of improving carrier mobility, it is preferable that at least one of X^{10a} or X^{10b} is a S atom. It is preferable that X^{10a} and X^{10b} are the same linking groups. It is more preferable that both of X^{10a} and X^{10b} are S atoms.

R^{X} each independently represents a hydrogen atom or a group represented by Formula W. The definition of a group represented by Formula W is as described above.

—Compound Represented by Formula 11—

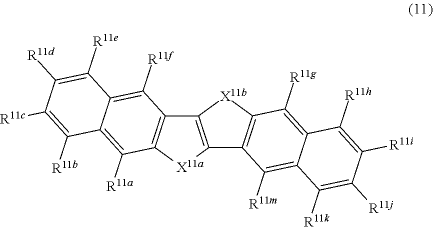

In Formula 11, X^{11a} and X^{11b} each independently represent a S atom, an O atom, a Se atom, or NR¹¹ⁿ, R^{11a} to R^{11k}, R^{11m}, and R¹¹ⁿ each independently represent a hydrogen atom or a substituent, and at least one of R^{11a}, R^{11b}, R^{11c}, R^{11d}, R^{11e}, R^{11f}, R^{11g}, R^{11h}, R¹¹ⁱ, R^{11j}, R^{11k}, R^{11m}, or R¹¹ⁿ represents a group represented by Formula W. Examples of the substituent include the substituent X described above. The definition of a substituent represented by Formula W is as described above.

In Formula 11, from the viewpoint of improving carrier mobility, at least one of X^{11a} or X^{11b} is a S atom. It is preferable that X^{11a} and X^{11b} are the same linking groups. It is more preferable that both of X^{11a} and X^{11b} are S atoms.

Among R^{11a} to R^{11k} and Rum of Formula 11, at least one of R^{11c} or R¹¹ⁱ is preferably a substituted or unsubstituted alkyl group, a substituted or unsubstituted arylthio group, a substituted or unsubstituted heteroarylthio group, a substituted or unsubstituted alkyloxycarbonyl group, a substituted or unsubstituted aryloxycarbonyl group, or a substituted or unsubstituted alkylamino group and more preferably a substituted or unsubstituted alkyl group. It is even more preferable that both of R^{11c} and R¹¹ⁱ represent a substituted or unsubstituted alkyl group.

—Compound Represented by Formula 12—

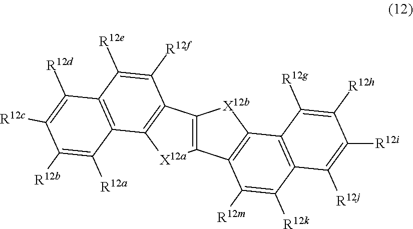

In Formula 12, X^{12a} and X^{12b} each independently represent a S atom, an O atom, a Se atom, or NR¹²ⁿ, R^{12a} to R^{12k}, R^{12m} and R¹²ⁿ each independently represent a hydrogen atom or a substituent, and at least one of R^{12a}, R^{12b}, R^{12c}, R^{12d}, R^{12e}, R^{12f}, R^{12g}, R^{12h}, R¹²ⁱ, R^{12j}, R^{12k}, R^{12m}, or R¹²ⁿ represents a group represented by Formula W. Examples of the substituent include the substituent X described above. The definition of a substituent represented by Formula W is as described above.

In Formula 12, from the viewpoint of improving carrier mobility, at least one of X^{12a} or X^{12b} is preferably a S atom. It is preferable that X^{12a} and X^{12b} are the same linking groups. It is more preferable that both of X^{12a} and X^{12b} are S atoms.

Among R^{12a} to R^{12k} and R^{12m} of Formula 12, at least one of R^{12c} or R¹²ⁱ is preferably a substituted or unsubstituted alkyl group, a substituted or unsubstituted arylthio group, a substituted or unsubstituted heteroarylthio group, a substituted or unsubstituted alkyloxycarbonyl group, a substituted or unsubstituted aryloxycarbonyl group, or a substituted or unsubstituted alkylamino group, and more preferably a substituted or unsubstituted alkyl group. It is even more preferable that both of R^{12c} and R¹²ⁱ represent a substituted or unsubstituted alkyl group.

—Compound Represented by Formula 13—

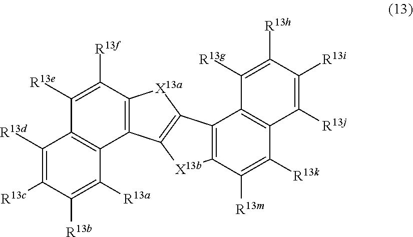

In Formula 13, X^{13a} and X^{13b} each independently represent a S atom, an O atom, a Se atom, or NR¹³ⁿ, R^{13a} to R^{13k}, R^{13m}, and R¹³ⁿ each independently represent a hydrogen atom or a substituent, and at least one of R^{13a}, R^{13b}, R^{13c}, R^{13d}, R^{13e}, R^{13f}, R^{13g}, R^{13h}, R¹³ⁱ, R^{13j}, R^{13k}, R^{13m} or R¹³ⁿ represents a group represented by Formula W. Examples of the substituent include the substituent X described above. The definition of a group represented by Formula W is as described above.

In Formula 13, from the viewpoint of improving carrier mobility, at least one of X^{13a} or X^{13b} is preferably a S atom. It is preferable that X^{13a} and X^{13b} are the same linking groups. It is more preferable that both of X^{13a} and X^{13b} are S atoms.

Among R^{13a} to R^{13k} and R^{13m} of Formula 13, at least one of R^{13c} or R¹³ⁱ is preferably a substituted or unsubstituted alkyl group, a substituted or unsubstituted arylthio group, a substituted or unsubstituted heteroarylthio group, a substituted or unsubstituted alkyloxycarbonyl group, a substituted or unsubstituted aryloxycarbonyl group, or a substituted or unsubstituted alkylamino group, and more preferably a substituted or unsubstituted alkyl group. It is even more preferable that both of R^{13c} and R¹³ⁱ represent a substituted or unsubstituted alkyl group.

—Compound Represented by Formula 14—

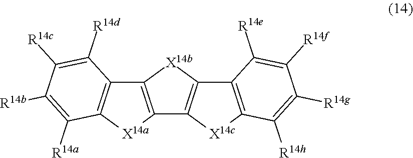

In Formula 14, X^{14a} to X¹⁴ each independently represent a S atom, an O atom, a Se atom, or NR¹⁴ⁱ, R^{14a} to R¹⁴ⁱ each independently represent a hydrogen atom or a substituent, and at least one of R^{14a}, R^{14b}, R^{14c}, R^{14d}, R^{14e}, R^{14f}, R^{14g}, R^{14h}, or R¹⁴ⁱ represents a group represented by Formula W. Examples of the substituent include the substituent X described above. The definition of a group represented by Formula W is as described above.

In a case where at least one of R^{14a}, R^{14b}, R^{14c}, R^{14d}, R^{14e}, R^{14f}, R^{14g}, or R^{14h} is a group represented by Formula W, and R^{W} is an alkyl group, L^{W} is preferably a group represented by any one of Formulae L-2 to L-25.

In Formula 14, from the viewpoint of improving carrier mobility, it is preferable that at least one of X^{14a}, X^{14b}, or X^{14c} is a S atom. It is preferable that X^{14a} to X^{14c} are the same linking groups. It is more preferable that all of X^{14a} to X^{14c} are S atoms.

In a case where R^{W} is an alkyl group, L^{W} is preferably a group represented by any one of Formulae L-2 to L-5, L-13, L-17, and L-18, and more preferably a group represented by any one of Formulae L-3, L-13, and L-18.

Among R^{14a} to R^{14h} of Formula 14, at least one of R^{14b} or R^{14g} is preferably a group represented by Formula W. It is more preferable that both of R^{14b} and R^{14g} represent a group represented by Formula W.

—Compound Represented by Formula 15—

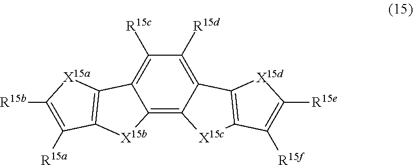

In Formula 15, X^{15a} to X^{15d} each independently represent a S atom, an O atom, a Se atom, or NR^{15g}, R^{15a} to R^{15g} each independently represent a hydrogen atom or a substituent, and at least one of R^{15a}, R^{15b}, R^{15c}, R^{15d}, R^{15e}, R^{15f}, or R^{15g} represents a group represented by Formula W. Examples of the substituent include the substituent X described above. The definition of a group represented by Formula W is as described above.

In Formula 15, from the viewpoint of improving carrier mobility, at least one of X^{15a}, X^{15b}, X^{15c}, or X^{15d} is preferably a S atom. It is preferable that X^{15a} to X^{15d} are the same linking groups. It is more preferable that all of X^{15a} to X^{15d} are S atoms.

Among R^{15a} to R^{15f} of Formula 15, at least one of R^{15b} or R^{15e} is preferably a group represented by Formula W. It is more preferable that both of R^{15b} and R^{15e} represent a group represented by Formula W.

—Compound Represented by Formula 16—

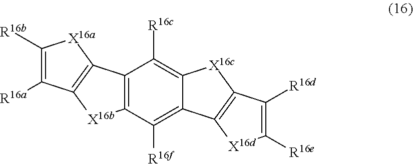

In Formula 16, X^{16a} to X^{16d} each independently represent a S atom, an O atom, a Se atom, or NR^{16g}. R^{16a} to R^{16g} each independently represent a hydrogen atom or a substituent, and at least one of R^{16a}, R^{16b}, R^{16c}, R^{16d}, R^{16e}, R^{16f}, or R^{16g} represents a group represented by Formula W. Examples of the substituent include the substituent X described above. The definition of a group represented by Formula W is as described above.

R^{16c} and R^{16f} preferably represent a hydrogen atom, a halogen atom, or a group represented by Formula W (here, L^{W} is a group represented by any one of Formulae L-3, L-5, L-7 to L-9, and L-12 to L-24). It is preferable that R^{16a}, R^{16b}, R^{16d}, R^{16e}, and R^{16g} each independently represent a hydrogen atom or a substituent.

In Formula 16, L^{W} is a group represented by any one of Formulae L-3, L-5, L-7 to L-9, and L-12 to L-24. In a case where R^{16c} and R^{16f} each independently represent a group represented by Formula W, L^{W} is preferably a group represented by any one of Formulae L-3, L-5, L-13, L-17, and L-18.

In Formula 16, from the viewpoint of improving carrier mobility, at least one of X^{16a}, X^{16b}, X^{16c}, or X^{16d} is a S atom. It is preferable that X^{16a} to X^{16d} are the same linking groups. It is more preferable that all of X^{16a} to X^{16d} are S atoms.

It is preferable that at least one of R^{16a} or R^{16d} among R^{16a} to R^{16f} Of Formula 16 represents a group represented by Formula W. It is more preferable that both of R^{16a} and R^{16d} represent a group represented by Formula W.

Furthermore, it is preferable that R^{16c} and R^{16f} represent a hydrogen atom.

The component A preferably has an alkyl group, more preferably has an alkyl group having 6 to 20 carbon atoms, and even more preferably has an alkyl group having 7 to 14 carbon atoms, on a condensed polycyclic aromatic ring in the aforementioned condensed polycyclic aromatic group. If the above aspect is adopted, mobility and heat stability of the obtained organic semiconductor are further improved.

The component A preferably has one or more alkyl groups, more preferably has 2 to 4 alkyl groups, and even more preferably has 2 alkyl groups, on a condensed polycyclic aromatic ring in the aforementioned condensed polycyclic aromatic group. If the above aspect is adopted, mobility and heat stability of the obtained organic semiconductor are further improved.

A molecular weight of the component A is not particularly limited, but is preferably equal to or less than 3,000, more preferably equal to or less than 2,000, even more preferably equal to or less than 1,000, and particularly preferably equal to or less than 850. If the molecular weight is equal to or less than the upper limit described above, solubility in a solvent can be improved. In contrast, from the viewpoint of film quality stability of a thin film, the molecular weight is preferably equal to or greater than 300, more preferably equal to or greater than 350, and even more preferably equal to or greater than 400.

A method for synthesizing the component A is not particularly limited, and the component A can be synthesized with reference to known methods. Examples of methods for synthesizing the compounds represented by Formulae 1 to 16 include the methods disclosed in Journal of American Chemical Society, 116, 925 (1994), Journal of Chemical Society, 221 (1951), Org. Lett., 2001, 3, 3471, Macromolecules, 2010, 43, 6264, Tetrahedron, 2002, 58, 10197, JP2012-513459A, JP2011-46687A, Journal of Chemical Research. Miniprint, 3, 601-635 (1991), Bull. Chem. Soc. Japan, 64, 3682-3686 (1991), Tetrahedron Letters, 45, 2801-2803 (2004), EP2251342A, EP2301926A, EP2301921A, KR10-2012-0120886A, J. Org. Chem., 2011, 696, Org. Lett., 2001, 3, 3471, Macromolecules, 2010, 43, 6264, J. Org. Chem., 2013, 78, 7741, Chem. Eur. J., 2013, 19, 3721, Bull. Chem. Soc. Jpn., 1987, 60, 4187, J. Am. Chem. Soc., 2011, 133, 5024, Chem. Eur. J. 2013, 19, 3721, Macromolecules, 2010, 43, 6264-6267, J. Am. Chem. Soc., 2012, 134, 16548-16550, and the like.

From the viewpoint of mobility in an organic semiconductor, the component A preferably contains at least one kind of compound represented by any one of Formulae 1 to 9, 14, and 15.

Specific preferred examples of the component A will be shown below, but it goes without saying that the present invention is not limited thereto.

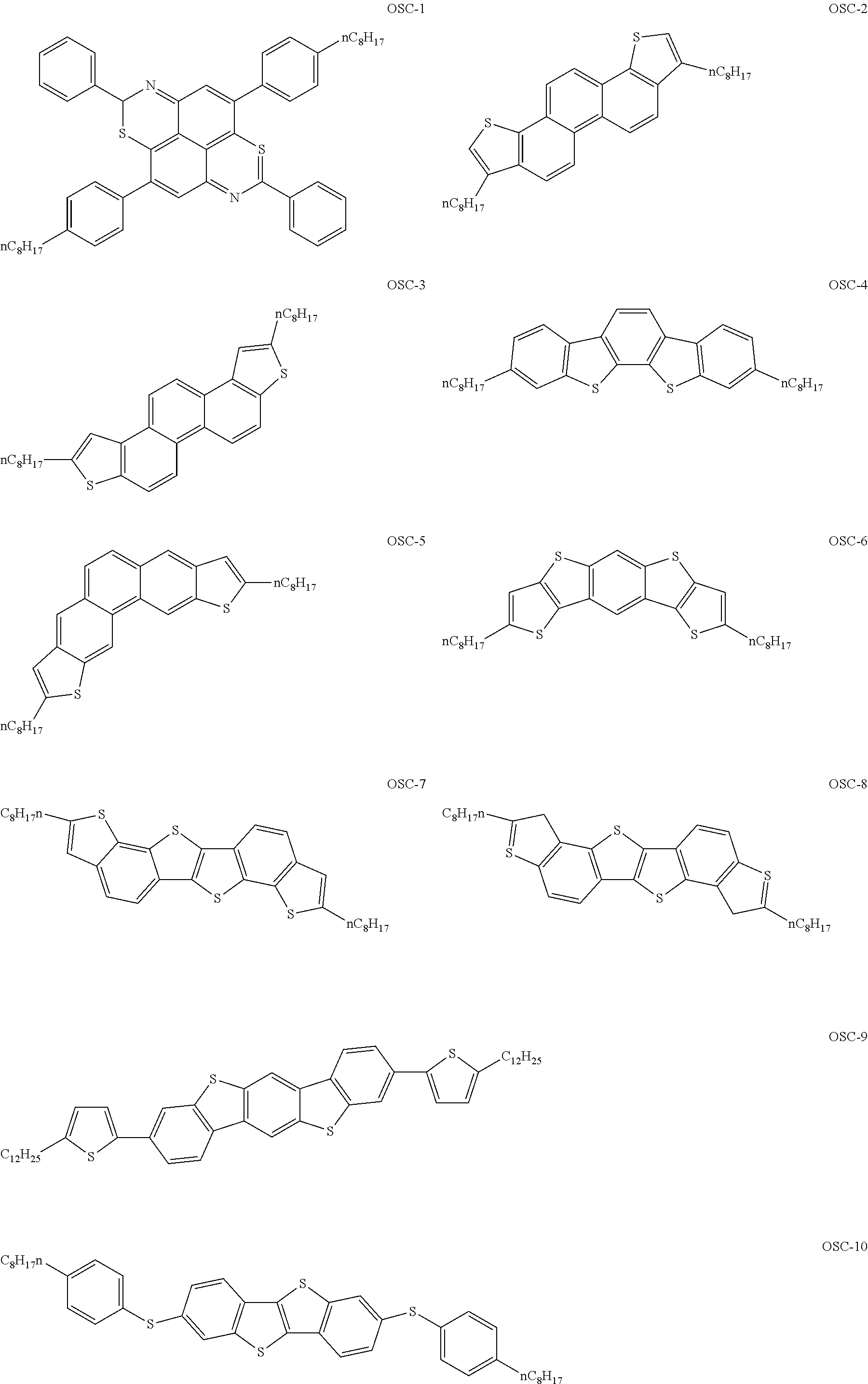

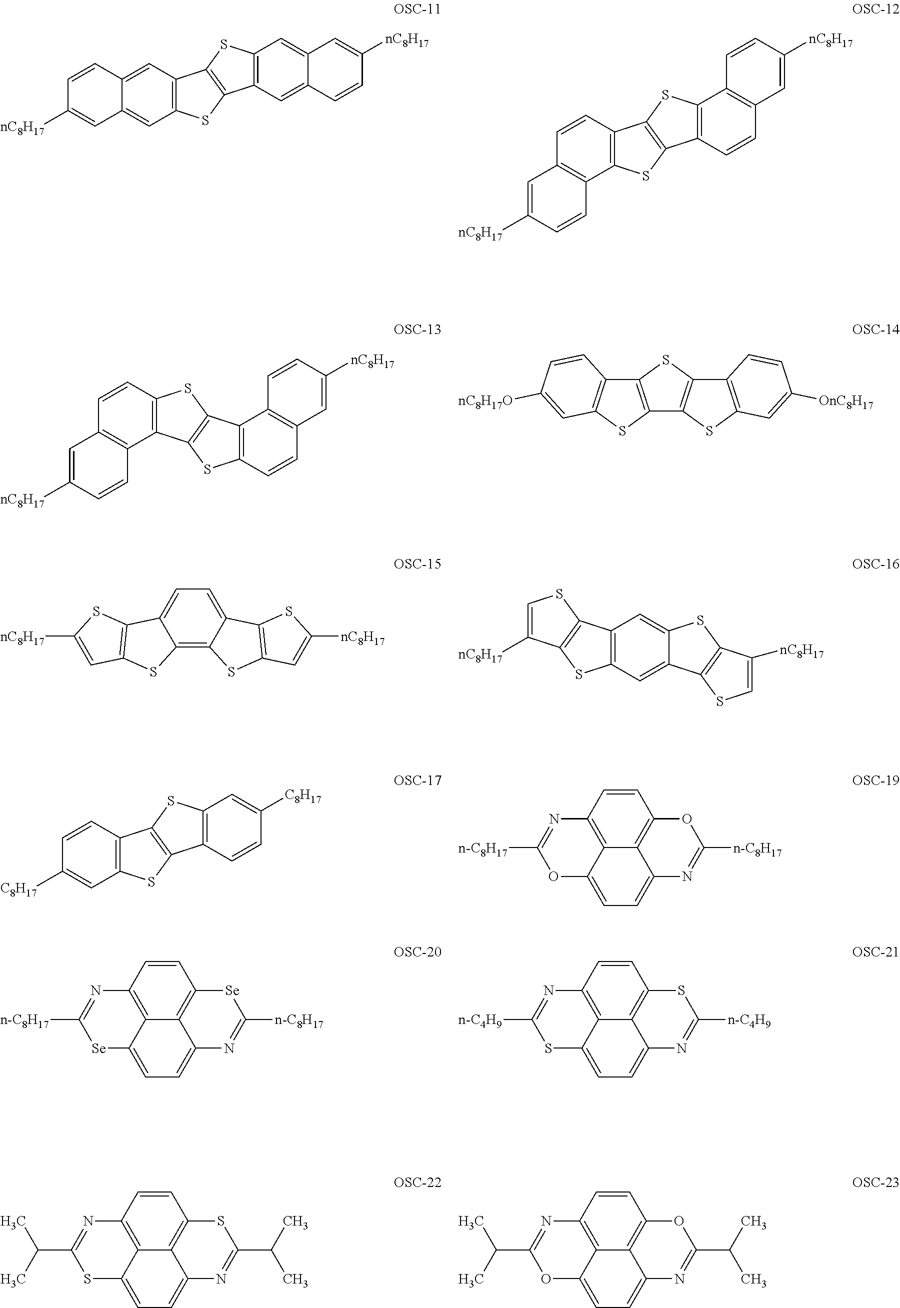

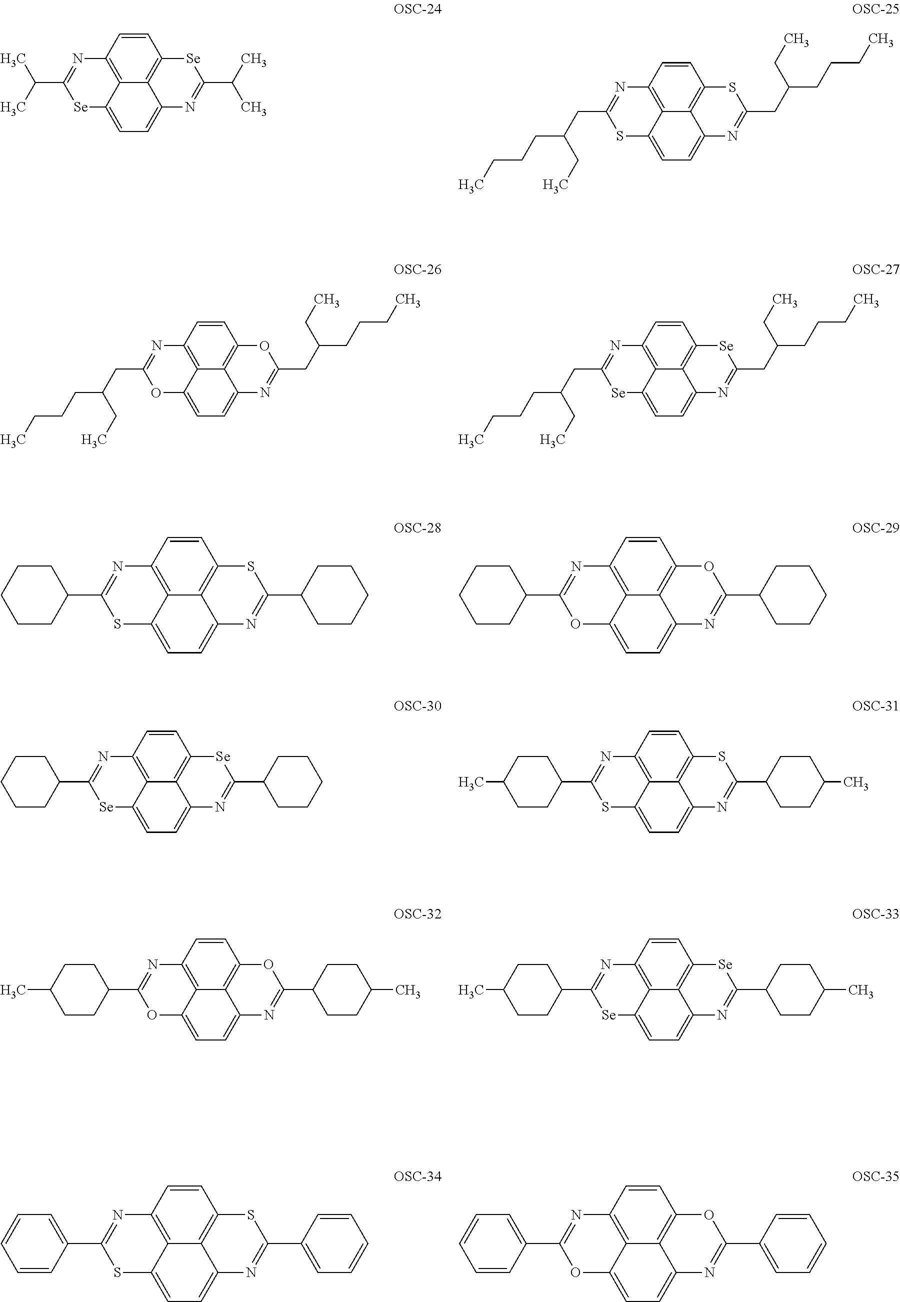

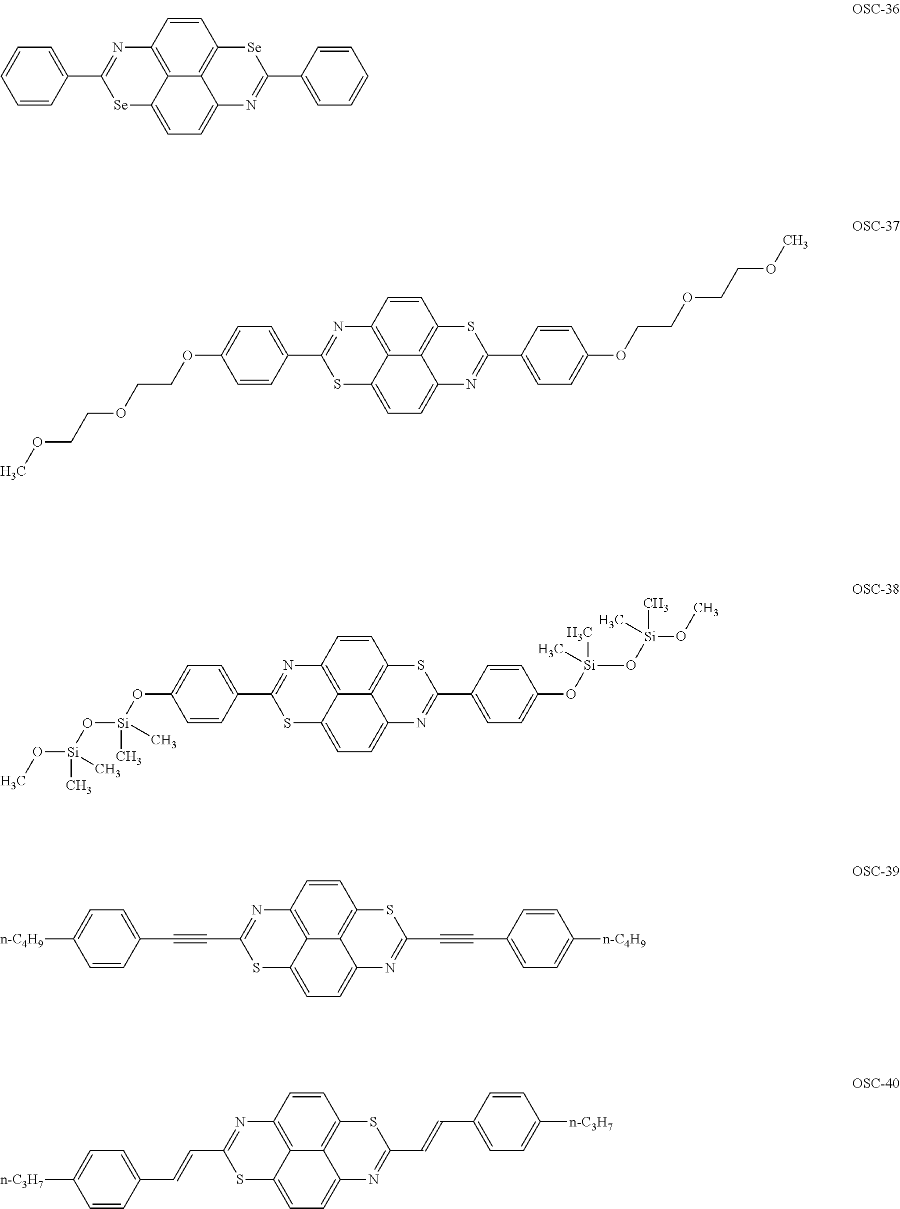

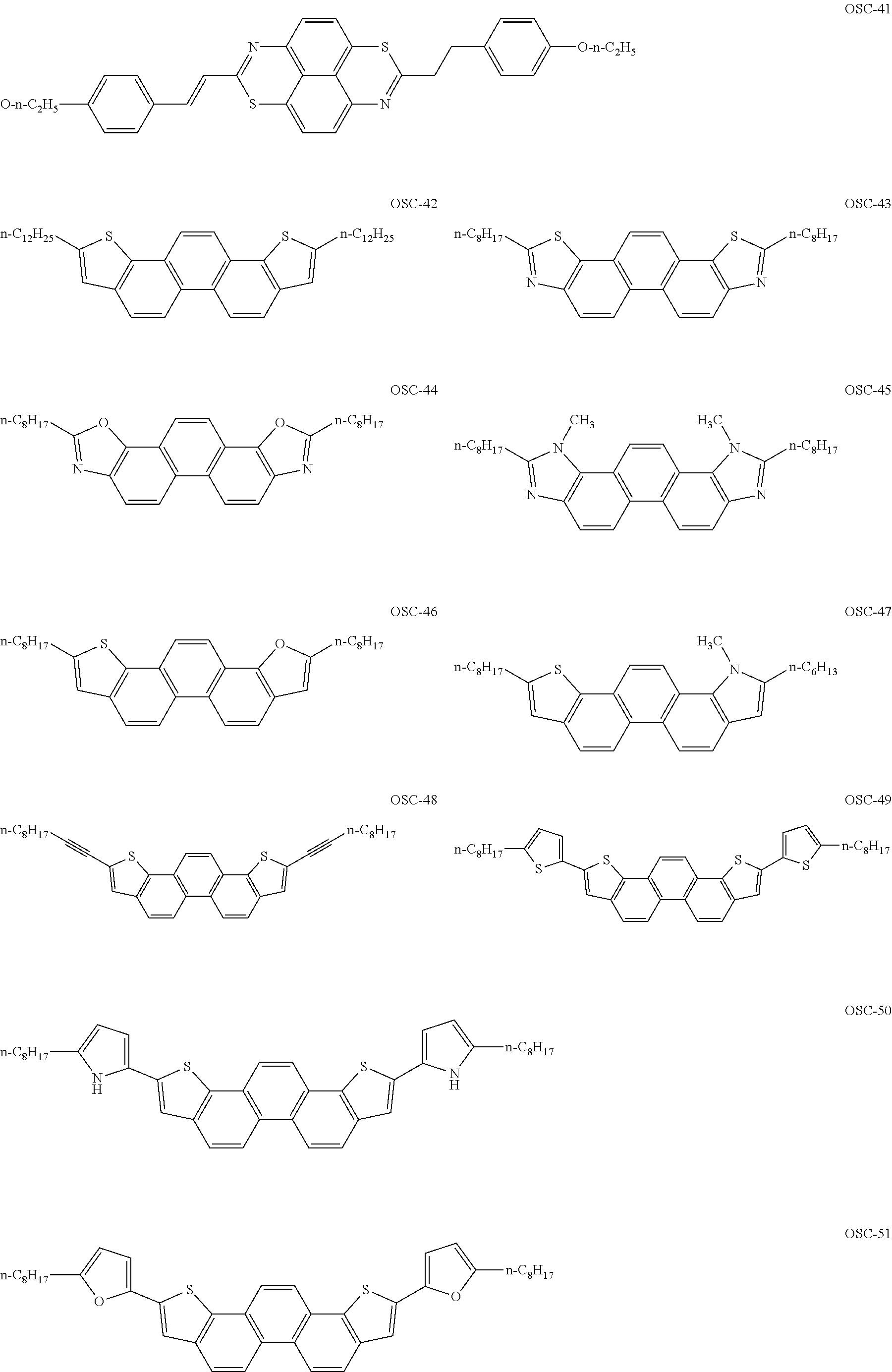

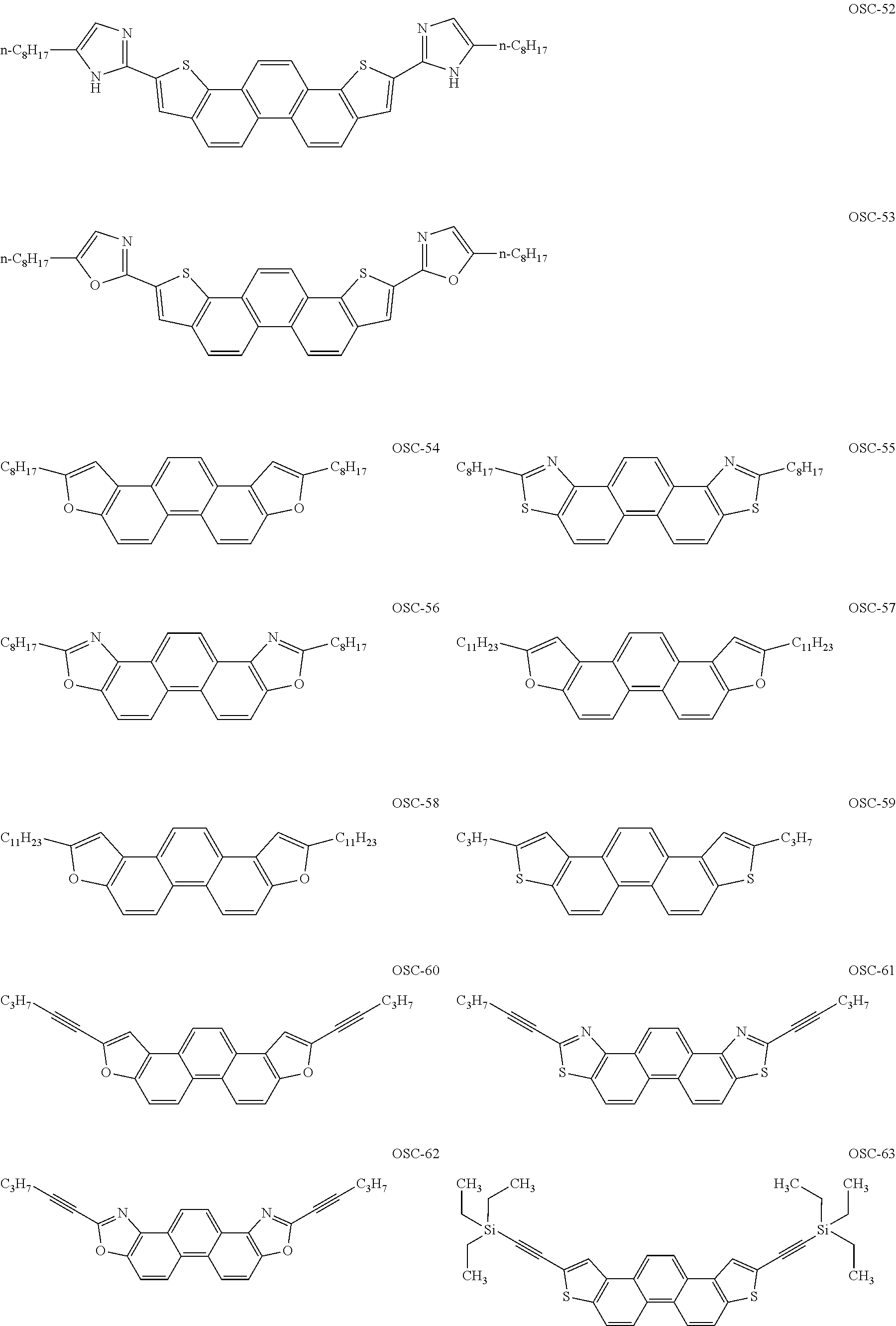

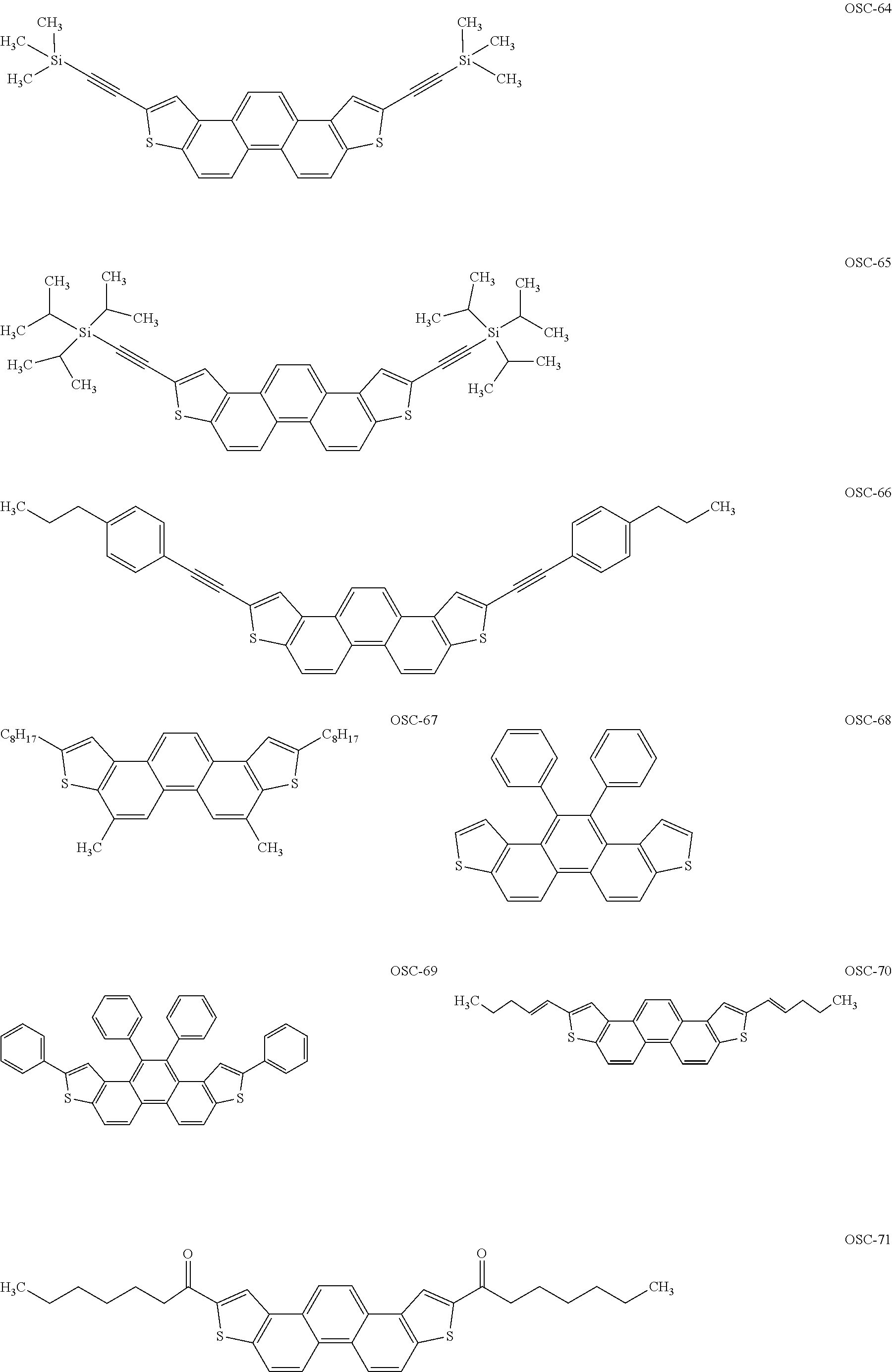

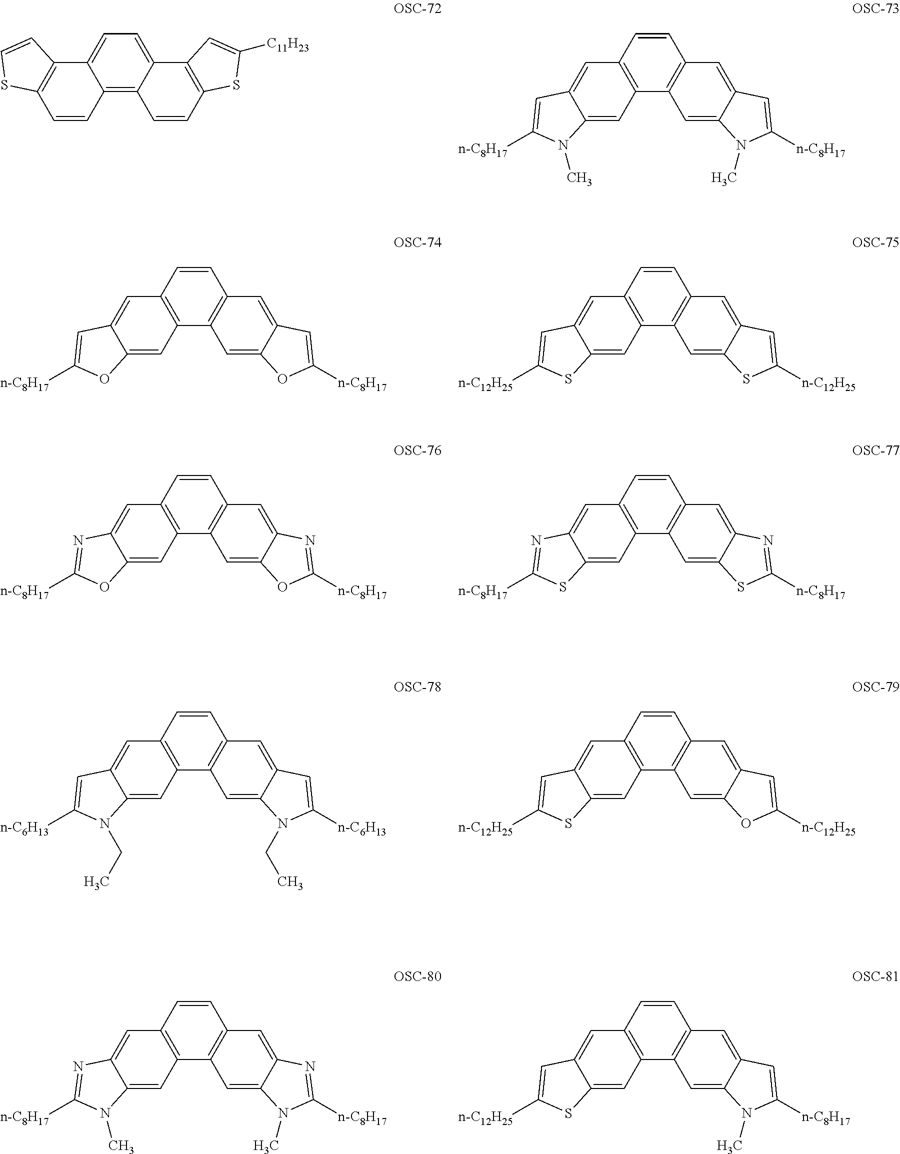

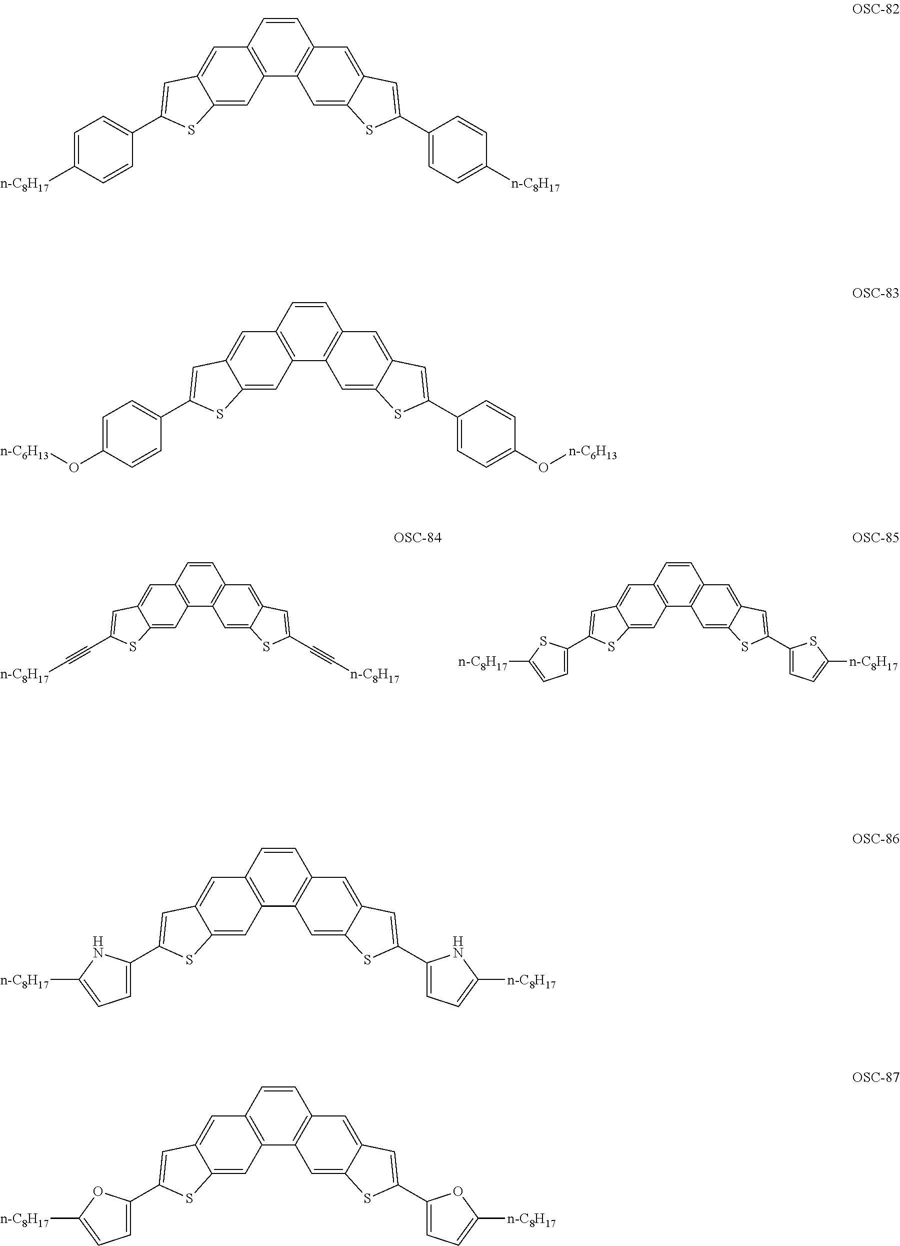

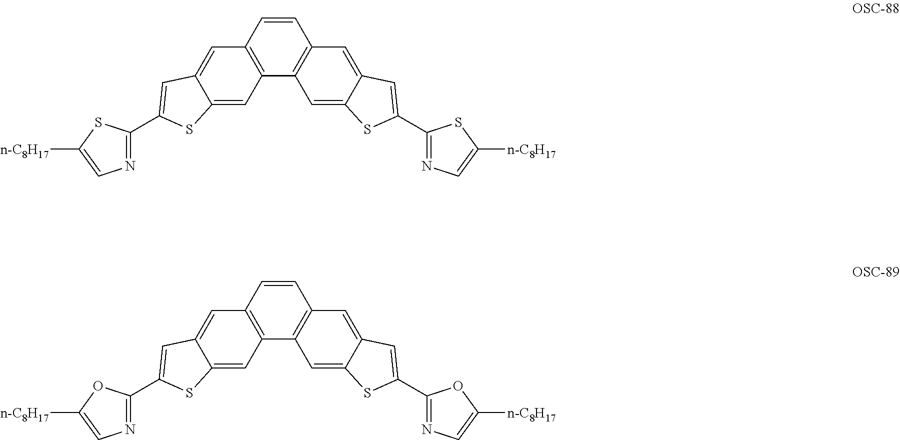

<Component B: Binder Polymer>

The composition for forming an organic semiconductor film of the present invention contains a binder polymer as a component B.

Examples of the component B include polystyrene (PS), poly(α-methyl styrene) (PαMS), poly(methyl methacrylate) (PMMA), polyvinyl phenol (PVP), poly(vinyl alcohol) (PVA), poly(vinyl acetate) (PVAc), polyvinyl chloride (PVC), polyvinylidene fluoride (PVDF), cyanoethyl pullulan (CYPEL), and poly(divinyltetramethyldisiloxane-bis(benzocyclobutene)) (BCB), but the component B is not limited thereto.

[Block Copolymer]

As the component B, a block copolymer may be included. Since the block copolymer causes lamellar phase separation, a crystal particle size of the organic semiconductor becomes large, and thus crystal orientation also becomes high.

The lamellar phase separation refers to a form in which the block copolymer is phase-separated in a linear shape along a plane of a layer. The linear shape may be a straight line shape or a curved shape.

Furthermore, the block copolymer in the present specification includes an unsubstituted block copolymer and a block copolymer having a substituent. Here, the substituent may be on a main chain forming a molecular chain of the block copolymer or may be on a side chain branched from the main chain.

For example, α-methyl styrene is a methyl substitution product of styrene at a main chain, and, based on the concept, a block copolymer having styrene preferably includes a block copolymer having α-methyl styrene.

Two kinds or three or more kinds of blocks constituting the block copolymer may be used. Plural kinds of blocks constituting the block copolymer are not particularly limited as long as a combination of the blocks causes lamellar phase separation, but a combination of blocks which is incompatible with each other is preferable. For example, in a case where the two kinds of blocks constituting the block copolymer are used, an absolute value of difference in solubility parameters (SP values) of the two kinds of blocks is preferably 0.5 to 4.0 MPa^{1/2} and more preferably 0.5 to 3.0 MPa^{1/2}. The SP value is the same as a SP value in the description of the component C which will be described later.

In the present specification, a SP value of a specific block of the block copolymer is a SP value of a repeating unit constituting the specific block (in other words, homopolymer formed only of a specific repeating unit, where a crosslinkable group, which will be described later, may be introduced into a part of a monomer component.). For example, when a SP value of a repeating unit (styrene unit) of polystyrene is 20.8 MPa^{1/2} and a SP value of a repeating unit (methyl methacrylate unit) of polymethyl methacrylate is 20.5 MPa^{1/2}, an absolute value of SP value difference between blocks in a copolymer obtained by bonding the two blocks of polystyrene and polymethyl methacrylate is 0.3 MPa^{1/2}.

When the SP value of the specific block is calculated, in a case where the specific block includes a monomer component having a crosslinkable group, which will be described later, the monomer unit having the crosslinkable group is considered not to exist. That is, in a case where the specific block includes a monomer unit having a crosslinkable group, the specific block is regarded as a block including repeating unit formed of monomer units excluding the monomer unit having the crosslinkable group, and then the SP value thereof is calculated.

A mass ratio of respective blocks constituting the block copolymer is not particularly limited, but in the block copolymer including two kinds of blocks, a ratio of number-average molecular weights of the blocks is preferably 25:75 to 75:25, more preferably 40:60 to 60:40, and even more preferably 45:55 to 55:45. By setting the ratio to the above range, it is possible to form a lamellar phase separation structure which is a preferable phase separation form more reliably and more efficiently.

The block copolymer used in the present invention is also preferably a block copolymer in which a crosslinkable group may be introduced into a part of a monomer component constituting the block copolymer. The crosslinkable group is not particularly limited as long as the group causes a cross-linked structure to be introduced into the block copolymer, and examples thereof which can be suitably used include a group selected from an epoxy group and an oxetane group. In this case, a cross-linked structure is formed by heating the block copolymer in the presence of an acid catalyst (thermal acid generator such as diphenyliodonium hexafluorophosphate) or a curing agent (compound having two or more active hydrogens, for example, diamine, dicarboxylic acid, or bisphenol). Therefore, when heating is performed to microphase-separate a block copolymer layer, it is possible to form the cross-linked structure simultaneously.

Due to the cross-linked structure included in the block copolymer in which a microphase separation layer is formed, solvent resistance is improved. Therefore, when an organic semiconductor layer is applied thereon to form a film, the block copolymer is less likely to be affected by a solvent constituting a coating liquid, and thus production efficiency and performance stability of the organic semiconductor element are further improved. In a case where the block copolymer in which a microphase separation layer is formed has the cross-linked structure, an amount of monomer components containing a crosslinkable group is preferably 1 to 20% by mole and more preferably 1 to 10% by mole, in total molar amount of all monomer components constituting the block copolymer.

Examples of the block copolymer used in the present invention include a block copolymer obtained by bonding a block including a repeating unit having styrene and a styrene derivative as a monomer component to a block including a repeating unit having (meth)acrylic acid ester as a monomer component; a block copolymer obtained by bonding a block including a repeating unit having styrene and a styrene derivative as a monomer component to a block including polysiloxane and a polysiloxane derivative; and a block copolymer obtained by bonding a block including polyalkylene oxide to a block including a repeating unit having (meth)acrylic acid ester as a monomer component.

The (meth)acrylic acid ester which is the monomer component of the block copolymer used in the present invention is preferably selected from (meth)acrylic acid alkyl ester and (meth)acrylic acid hydroxyalkyl ester. The alkyl group in the (meth)acrylic acid alkyl ester is preferably an alkyl group having 1 to 10 carbon atoms. The alkyl group may be linear, branched, or cyclic. Moreover, the hydroxyalkyl group in the (meth)acrylic acid hydroxyalkyl ester preferably has 1 to 10 carbon atoms.

Specific examples of the (meth)acrylic acid ester include methyl (meth)acrylate, ethyl (meth)acrylate, propyl (meth)acrylate, cyclohexyl (meth)acrylate, octyl (meth)acrylate, nonyl (meth)acrylate, hydroxyethyl (meth)acrylate, hydroxypropyl (meth)acrylate, benzyl (meth)acrylate, anthracenyl (meth)acrylate, glycidyl (meth)acrylate, 3,4-epoxycyclohexylmethyl (meth)acrylate, and 3-(trimethoxysilyl)propyl (meth)acrylate.

Examples of the styrene derivative include 2-methyl styrene, 3-methyl styrene, 4-methyl styrene, 4-t-butyl styrene, 4-n-octyl styrene, 2,4,6-trimethyl styrene, 4-methoxy styrene, 4-t-butoxy styrene, 4-hydroxy styrene, 4-nitrostyrene, 3-nitrostyrene, 4-chlorostyrene, 4-fluorostyrene, 4-acetoxyvinyl styrene, 4-vinylbenzyl chloride, 1-vinyl naphthalene, 4-vinyl biphenyl, 9-vinyl anthracene, and ca-methyl styrene.

Examples of the polysiloxane derivative include dimethyl polysiloxane, diethyl polysiloxane, diphenyl polysiloxane, and methylphenyl polysiloxane.

Examples of the polyalkylene oxide include polyethylene oxide, polypropylene oxide, polyisopropylene oxide, and polybutylene oxide.

Preferred examples of the block copolymer used in the present invention include the following block copolymers:

a styrene-alkyl(meth)acrylate block copolymer (the number of the carbon atoms of the alkyl group in the alkyl(meth)acrylate is preferably 1 to 12, more preferably 1 to 8, and even more preferably 1 to 4);

a styrene-(meth)acrylate block copolymer;

a styrene-dialkylsiloxane block copolymer (the number of the carbon atoms of the alkyl group in the dialkylsiloxane is preferably 1 to 12, more preferably 1 to 8, and even more preferably 1 to 4);

a styrene-alkylarylsiloxane block copolymer (the number of the carbon atoms of the alkyl group in the alkylarylsiloxane is preferably 1 to 12, more preferably 1 to 8, and even more preferably 1 to 4, and the number of the carbon atoms of the aryl group in the polyalkylarylsiloxane is preferably 6 to 20, more preferably 6 to 15, and even more preferably 6 to 12, and a phenyl group is even more preferable);

a styrene-diarylsiloxane block copolymer (the number of the carbon atoms of the aryl group in the diarylsiloxane is preferably 6 to 20, more preferably 6 to 15, and even more preferably 6 to 12, and a phenyl group is even more preferable);

a styrene-POSS-substituted alkyl(meth)acrylate block copolymer (the number of the carbon atoms of the alkyl group in the POSS-substituted alkyl(meth)acrylate is preferably 1 to 12, more preferably 1 to 8, and even more preferably 1 to 4);

an alkyl(meth)acrylate-POSS-substituted alkyl(meth)acrylate block copolymer (the number of the carbon atoms of the alkyl group in the alkyl(meth)acrylate and the POSS-substituted alkyl(meth)acrylate is preferably 1 to 12, more preferably 1 to 8, and even more preferably 1 to 4);

a styrene-vinyl pyridine block copolymer;

a styrene-hydroxy styrene block copolymer;

a styrene-ethylene oxide block copolymer; and

a vinylnaphthalene-alkyl(meth)acrylate block copolymer.

The “POSS” refers to silsesquioxane. That is, the block copolymer used in the present invention is preferably the copolymer having a silsesquioxane structure described in JP2012-036078A.

Furthermore, the block copolymer exemplified above as the preferred examples also includes a form in which the crosslinkable group (preferably, an epoxy group and an oxetane group) described above is included in a part of the monomer component constituting the block.

Commercially available products (products manufactured by Polymer Source, Inc. and the like) may be used as the block copolymer, or the block copolymer may be synthesized by known methods using radical polymerization or anionic polymerization.

The weight-average molecular weight (Mw) of the block copolymer used in the present invention is preferably 3,000 to 300,000, more preferably 5,000 to 100,000, and even more preferably 8,000 to 70,000.

The number-average molecular weight (Mn) of the block copolymer used in the present invention is preferably equal to or less than 100,000, more preferably equal to or less than 50,000, even more preferably equal to or less than 25,000, and particularly preferably equal to or less than 20,000. As the Mn of the block copolymer is smaller, a pitch of the lamellar phase separation layer becomes lower. As the pitch of the lamellar phase separation layer is lower, a crystal particle size of the organic semiconductor provided thereon becomes large, and crystal orientation is also improved. Therefore, mobility can be further improved. Moreover, the Mn of the block copolymer used in the present invention is preferably equal to or greater than 3,000, more preferably equal to or greater than 5,000, and even more preferably equal to or greater than 6,000.

A dispersity (Mw/Mn) of the block copolymer used in the present invention is preferably 1.0 to 1.5, more preferably equal to or less than 1.2, even more preferably 1.0 to 1.2, and still more preferably 1.0 to 1.15. The dispersity of the block copolymer used in the present invention is even more preferably equal to or less than 1.15 and still more preferably equal to or less than 1.10, because then the phase separation structure is easily formed.

[Natural Rubber, Synthetic Rubber, Silicone Resin, Thermoplastic Elastomer, and Urea Resin]

The component B is preferably at least one resin selected from the group consisting of natural rubber, synthetic rubber, a silicone resin, a thermoplastic elastomer, and a urea resin, more preferably at least one selected from the group consisting of ethylene-propylene rubber, acrylonitrile-butadiene rubber, hydrogenated nitrile rubber, fluororubber, a perfluoroelastomer, a tetrafluoroethylene propylene copolymer, an ethylene-propylene-diene copolymer, styrene-butadiene rubber, polychloroprene, polyneoprene, butyl rubber, a methyl•phenylsilicone resin, a methyl•phenylvinyl•silicone resin, a methyl•vinyl•silicone resin, a fluorosilicone resin, acrylic rubber, ethylene acrylic rubber, chlorosulfonated polyethylene, chloropolyethylene, an epichlorohydrin copolymer, a polyisoprene-natural rubber copolymer, polyisoprene rubber, a styrene-isoprene block copolymer, a polyester urethane copolymer, a polyether urethane copolymer, a polyetherester thermoplastic elastomer, and polybutadiene rubber, even more preferably at least one selected from the group consisting of ethylene-propylene rubber, an ethylene-propylene-diene copolymer, a polyetherester thermoplastic elastomer, a styrene-isoprene block copolymer, styrene-butadiene rubber, and butyl rubber, still more preferably ethylene-propylene rubber, an ethylene-propylene-diene copolymer, or a polyetherester thermoplastic elastomer, particularly preferably ethylene-propylene rubber or an ethylene-propylene-diene copolymer, and most preferably ethylene-propylene rubber. If the above aspect is adopted, mobility and heat stability of the obtained organic semiconductor are further improved.

Diene used in synthesis of the ethylene-propylene-diene copolymer is not particularly limited, and is preferably 5-ethylidene-2-norbornene (ENB), dicyclopentadiene (DCPD), and 1,4-hexadiene (HD) and more preferably 5-ethylidene-2-norbornene.

The glass transition temperature (Tg) of the component B is preferably equal to or lower than 0° C., more preferably −100° C. to −30° C., even more preferably −90° C. to −35° C., particularly preferably −80° C. to −40° C., and most preferably −70° C. to −45° C. If the above aspect is adopted, mobility and heat stability of the obtained organic semiconductor are further improved.

The glass transition temperature (Tg) of the polymer in the present invention is a value measured by performing differential scanning calorimetry (DSC) on a substance obtained by heating and drying an aqueous dispersion of polymer particles.

For example, the glass transition temperature is measured under a condition of a temperature raising rate of 5° C./min, using a differential scanning calorimeter (manufactured by Mac Science Co., Ltd.: DSC3110, THERMAL ANALYSIS SYSTEM 001), and the temperature at a shoulder on the low temperature side of a decalescent point corresponding to a Tg in the obtained chart may be regarded as a Tg.

An elastic recovery of the component B is preferably equal to or less than 30%, more preferably 1% to 25%, even more preferably 1% to 22%, and particularly preferably 1% to 20%. If the elastic recovery is within the above range, heat stability of the obtained organic semiconductor are further improved. Presumably, due to the use of the polymer having the elastic recovery in the above range, the polymer is expanded by following thermal expansion of the organic semiconductor at the time of heating, but polymer is not contracted at the time of cooling, and thus the stress is relaxed.

The elastic recovery of the polymer in the present invention means a value obtained as follows.

The elastic recovery is measured by a indentation hardness test. A triangular pyramid indenter (Berkovich indenter) made of diamond with a vertex angle of 115 degrees, as an indenter, is pushed into a sample surface, and a relationship between displacement and a load applied at that time is determined. According to specific measurement technique, HM-2000 type hardness meter manufactured by FISCHER INSTRUMENTS K.K. is pushed into a sample applied on glass for 10 seconds up to the maximum load of 5 mN, and then the state is maintained for 5 seconds. The total workload pressed at this time is regarded as Wt(N·m). Thereafter, the load is removed for 10 seconds, and the workload recovered from elastic deformation is regarded as We(N·m). We/Wt indicated by a ratio of these workloads is regarded as an elastic recovery (%).

The surface energy of the component B is preferably equal to or lower than 30 mN/m², more preferably 10 mN/m² to 30 mN/m², even more preferably 15 mN/m² to 30 mN/m², and particularly preferably 20 mN/m² to 30 mN/m². If the surface energy is within the above range, heat stability of the obtained organic semiconductor are further improved.

Although the mechanism is unclear, the reason for this is presumably that, in a case where the surface energy is within the above range, adhesiveness between the organic semiconductor and the substrate and adhesiveness between the organic semiconductor and the electrode are favorable.

The surface energy of the polymer in the present invention means a value obtained as follows.

First, a 1% polymer solution is added dropwise onto a glass substrate, and the substrate was coated with the solution by spin coating (1,000 rpm, 120 seconds), followed by heating for 30 minutes at 150° C., thereby forming a polymer film.

Then, in order to perform contact angle measurement (for example, a contact angle gauge DM-501 manufactured by Kyowa Interface Science Co., LTD. can be used), a contact angle of water and diiodomethane with respect to the surface of the polymer film is measured.

A surface energy dispersion component (γ_{S}^{d}) and a polar component (γ_{S}^{h}) are determined from Owens expression and Young expression which are indicated by the following Expression B′ and an extended expression of Fowkes expression, using the obtained contact angle and surface tension value of the liquid, and the sum of the both components is regarded as a surface energy (γ_{S}).

γ_{L}(1+cos θ)=2(γ_{S}^{d}γ_{L}^{d})^{1/2}+2(γ_{S}^{h}γ_{L}^{h})^{1/2} (B′)

γ_{S}=γ_{S}^{d}+γ_{S}^{h}
γ_{L}: Surface tension of contact medium
γ_{L}^{d}: Surface tension dispersion component of contact medium
γ_{L}^{h}: Surface tension polar component of contact medium
γ_{S}: Surface energy
γ_{S}^{d}: Surface energy dispersion component
γ_{S}^{h}: Surface energy polar component

The weight-average molecular weight of the component B is not particularly limited, and is preferably 1,000 to 2,000,000, more preferably 3,000 to 1,000,000, and even more preferably 5,000 to 600,000.

The obtained organic semiconductor film preferably has a portion in which at least the component A and the component B are mixed together, and more preferably has a portion which has a crystal structure of the component A and a portion in which at least the component A and the component B are mixed together.

It is preferable that the component B exhibits solubility higher than the solubility of the component A in a used solvent. If the above aspect is adopted, mobility and heat stability of the obtained organic semiconductor are further improved.

A content of the component B in the composition for forming an organic semiconductor film of the present invention is, with respect to 100 parts by mass of the content of the component A, preferably 1 to 200 parts by mass, more preferably 10 to 150 parts by mass, and even more preferably 20 to 120 parts by mass. If the content is within the above range, mobility and heat stability of the obtained organic semiconductor are further improved.

<Component C: Solvent Having Naphthalene Structure>

The composition for forming an organic semiconductor film of the present invention contains a solvent having a naphthalene structure, as a component C.

The component C is not particularly limited as long as the component has a naphthalene structure, and known solvents can be used.

As the component C, a compound in which at least one hydrogen atom in the naphthalene is substituted with a methyl group, a phenyl group, a nitro group, or a halogen atom is preferably used.

Specifically, 2-isopropyl naphthalene (boiling point of 261° C. and SP value of 19.0 MPa^{1/2}), 1-methyl naphthalene (boiling point of 204° C. and SP value of 20.0 MPa^{1/2}), 1-ethyl naphthalene (boiling point of 260° C. and SP value of 19.6 MPa^{1/2}), 2-ethyl naphthalene (boiling point of 251° C. and SP value of 19.6 MPa^{1/2}), 1,6-dimethyl naphthalene (boiling point of 265° C. and SP value of 19.4 MPa^{1/2}), 1-chloronaphthalene (boiling point of 259° C. and SP value of 20.8 MPa^{1/2}), and 1-fluoronaphthalene (boiling point of 215° C. and SP value of 20.3 MPa^{1/2}) are more preferable, and 1-chloronaphthalene is even more preferable in terms of the level of the boiling point.

The boiling point of the component C is preferably 170° C. to 280° C. and more preferably 200° C. to 260° C.

The SP value of the component C is preferably 18.0 to 22.0 MPa^{1/2} and more preferably 19.0 to 21.0 MPa^{1/2}.

The “SP value” in the present invention means a “value of a solubility parameter”. The SP value mentioned in the present invention is the Hansen solubility parameter according to expressions described in Hansen solubility parameter: A User's Handbook, Second Edition, C. M. Hansen (2007), Taylor and Francis Group, LLC (HSPiP manual), and a value obtained by calculating the SP value from the following expression using “Hansen Solubility Parameters in Practice, HSPiP, the 3^{rd} edition” (software version 4.0.05) is used.

(SP value)²=(δHd)²+(δHp)²+(δHh)²

Hd: dispersion contribution

Hp: polarity contribution

Hh: hydrogen bond contribution

In addition, one kind of component C may be used singly, or plural kinds thereof may

be used in combination.

<Component D: Solvent Having Lower SP Value than that of Component C by 2.0 MPa^{1/2} or Greater and Lower Boiling Point than that of Component C>

The composition for forming an organic semiconductor film of the present invention contains a solvent having a lower SP value than that of the component C by 2.0 MPa^{1/2} or greater and a lower boiling point than that of the component C, as a component D.

It is considered that due to a SP value of the component D lower than that of the component C, wettability of the composition become high, and due to a boiling point lower than that of the component C, the component D is volatilized earlier than the component C when forming the organic semiconductor element. Presumably, for the reason, mobility of the organic semiconductor element is improved.

The component D is preferably alkane or cycloalkane having 6 to 20 carbon atoms or alkylbenzene.

The alkylbenzene refers to benzene in which one or more hydrogens in a benzene ring is substituted with an alkyl group.

Specific examples of the component D include butyl cyclohexane (boiling point of 178° C. and SP value of 16.3 MPa^{1/2}), cis-decaline (boiling point of 195.7° C. and SP value of 16.8 MPa^{1/2}), methoxy cyclohexane (boiling point of 135° C. and SP value of 17.3 MPa^{1/2}), m-diethylbenzene (boiling point of 181° C. and SP value of 17.7 MPa^{1/2}), 1,2-dichlorobenzene (boiling point of 181° C. and SP value of 18.4 MPa^{1/2}), 4-methoxy toluene (boiling point of 175° C. and SP value of 19.6 MPa^{1/2}), and amyl benzene (boiling point of 205° C. and SP value of 17.5 MPa^{1/2}), and m-diethylbenzene, amyl benzene, and cis-decaline are preferable.

Furthermore, the boiling point of the component D may be lower than that of the component C, and is preferably lower than that of the component C by 5° C. or higher and more preferably lower than that of the component C by 10° C. or higher.

The boiling point of the component D is preferably 160° C. to 220° C. and more preferably 180° C. to 205° C.

The SP value of the component D is lower than the SP value of the component C by 2.0 MPa^{1/2} or greater, preferably by 2.3 MPa^{1/2} or greater, and more preferably by 3.3 MPa^{1/2} or greater.

The SP value of the component D is preferably 15.0 to 20.0 MPa^{1/2} and more preferably 16.0 to 18.0 MPa^{1/2}.

A proportion of the component D with respect to the total content of the component C and the component D is preferably 5% to 50% by volume, more preferably 10% to 30% by volume, and even more preferably 19% to 25% by volume.

The proportion of the component D indicates a value obtained by dividing a volume of the component D at 25° C. before mixing by the sum of volumes of the component C and the component D at 25° C. before mixing.

<Other Components>

The composition for forming an organic semiconductor film of the present invention may contain components other than the component A to the component D.

As other components, known additives and the like can be used.

In the composition for forming an organic semiconductor film of the present invention, a content of the components other than the components A to D is preferably equal to or less than 10% by mass, more preferably equal to or less than 5% by mass, even more preferably equal to or less than 1% by mass, and particularly preferably equal to or less than 0.1% by mass. If the content of other components is within the above range, film formability is improved, and mobility and heat stability of the obtained organic semiconductor are further improved.

<Physical Properties of Organic Semiconductor Film Composition>

A content of the component A in the composition for forming an organic semiconductor film of the present invention is preferably 0.01% to 80% by mass, more preferably 0.05% to 10% by mass, and even more preferably 0.1% to 5% by mass, and a content of the component B is preferably 0.01% to 80% by mass, more preferably 0.02% to 10% by mass, and even more preferably 0.03% to 5% by mass. If the content of each of the components A and B is within the above range, coating properties become excellent, and an organic semiconductor film can be easily formed.

The viscosity of the composition for forming an organic semiconductor film according to the present invention is not particularly limited. In view of further improving coating properties, the viscosity is preferably 3 to 100 mPa·s, more preferably 5 to 50 mPa·s, and even more preferably 9 to 40 mPa·s. The viscosity in the present invention is viscosity at 25° C.

As a method for measuring viscosity, a method based on JIS Z8803 is preferable.

A method for manufacturing the composition for forming an organic semiconductor film of the present invention is not particularly limited, and known methods can be adopted. For example, by simultaneously or sequentially adding a predetermined amount of the component A and the component B to a solvent in which the component C and the component D are mixed and appropriately stirring the mixture, a desired composition can be obtained.

(Organic Semiconductor Film and Organic Semiconductor Element)

The organic semiconductor film of the present invention contains an organic semiconductor and a binder polymer, in which the organic semiconductor has a condensed polycyclic aromatic group, the number of rings in the condensed polycyclic aromatic group is equal to or greater than 4, at least two rings in the condensed polycyclic aromatic group contains at least one atom selected from the group consisting of a sulfur atom, a nitrogen atom, a selenium atom, and an oxygen atom, and the condensed polycyclic aromatic group has, as a partial structure, at least one structure selected from the group consisting of a benzene ring, a naphthalene ring, and a phenanthrene ring.

The organic semiconductor and the binder polymer have the same definitions as those of the component A in the composition for forming an organic semiconductor film of the present invention and the component B in the composition for forming an organic semiconductor film of the present invention, respectively, and the preferred aspects thereof are also the same as those of the components, respectively.

The organic semiconductor element of the present invention contains an organic semiconductor and a binder polymer, in which the organic semiconductor has a condensed polycyclic aromatic group, the number of rings in the condensed polycyclic aromatic group is equal to or greater than 4, at least two rings in the condensed polycyclic aromatic group contains at least one atom selected from the group consisting of a sulfur atom, a nitrogen atom, a selenium atom, and an oxygen atom, and the condensed polycyclic aromatic group has, as a partial structure, at least one structure selected from the group consisting of a benzene ring, a naphthalene ring, and a phenanthrene ring.

The organic semiconductor and the binder polymer have the same definitions as those of the component A in the composition for forming an organic semiconductor film of the present invention and the component B in the composition for forming an organic semiconductor film of the present invention, respectively, and the preferred aspects thereof are also the same as those of the components, respectively.

The organic semiconductor element in the first embodiment of the present invention is preferably an organic semiconductor element having an organic semiconductor film formed using the composition for forming an organic semiconductor film of the present invention. According to the first embodiment, film formability is improved, and mobility and heat stability of the obtained organic semiconductor are further improved.

The organic semiconductor element in the second embodiment of the present invention is an organic semiconductor element having a layer, which contains the polymer, between a layer containing the aforementioned organic semiconductor and an insulating film. According to the second embodiment, productivity and costs are further improved.

In the second embodiment, the layer containing the organic semiconductor is preferably a layer composed of the aforementioned organic semiconductor.

Furthermore, in the second embodiment, the insulating film is preferably a gate insulating film.

In addition, in the second embodiment, the layer containing the polymer is preferably a layer composed of the polymer.

The organic semiconductor film of the present invention and the organic semiconductor element of the present invention are preferably manufactured by using the composition for forming an organic semiconductor film of the present invention.

A method for manufacturing an organic semiconductor film or an organic semiconductor element by using the composition for forming an organic semiconductor film of the present invention is not particularly limited, and known methods can be adopted. Examples thereof include a method for manufacturing an organic semiconductor film by applying the composition onto a predetermined substrate and performing a drying treatment, if necessary.

The method of applying the composition onto a substrate is not particularly limited, and known methods can be adopted. Examples thereof include an ink jet printing method, a flexographic printing method, a bar coating method, a spin coating method, a knife coating method, a doctor blade method, and the like. Among these, an ink jet printing method and a flexographic printing method are preferable.

Suitable examples of the flexographic printing method include an aspect in which a photosensitive resin plate is used as a flexographic printing plate. By printing the composition onto a substrate according to the aspect, a pattern can be easily formed.

Among the above methods, the method for manufacturing an organic semiconductor film of the present invention and the method for manufacturing an organic semiconductor element of the present invention preferably include a coating step of coating a substrate with the composition for forming an organic semiconductor film of the present invention. The composition for forming an organic semiconductor film of the present invention more preferably contains a solvent, and the method for manufacturing an organic semiconductor film of the present invention and the method for manufacturing an organic semiconductor element of the present invention more preferably includes a coating step of coating a substrate with the composition for forming an organic semiconductor film of the present invention and a removing step of removing the solvent from the composition with which the substrate is coated.

The drying treatment in the removing step is a treatment performed if necessary, and the optimal treatment conditions are appropriately selected according to the type of the components A and the solvent used. In view of further improving mobility and heat stability of the obtained organic semiconductor and improving productivity, a heating temperature is preferably 30° C. to 100° C. and more preferably 40° C. to 80° C., and a heating time is preferably 10 to 300 minutes and more preferably 30 to 180 minutes.

A film thickness of the formed organic semiconductor film is not particularly limited. From the viewpoint of mobility and heat stability of the obtained organic semiconductor, the film thickness is preferably 10 to 500 nm and more preferably 30 to 200 nm.

The organic semiconductor film manufactured from the composition of the present invention can be suitably used in an organic semiconductor element, and can be particularly suitably used in an organic transistor (organic thin film transistor).

The organic semiconductor element is not particularly limited, but is preferably an organic semiconductor element having 2 to 5 terminals, even more preferably an organic semiconductor element having 2 or 3 terminals.

Furthermore, the organic semiconductor element is preferably an element which does not use a photoelectric function.

Examples of a 2-terminal element include a rectifier diode, a constant voltage diode, a PIN diode, a Schottky barrier diode, a surge protection diode, a diac, a varistor, a tunnel diode, and the like.

Examples of a 3-terminal element include a bipolar transistor, a Darlington transistor, a field effect transistor, insulated gate bipolar transistor, a uni-junction transistor, a static induction transistor, a gate turn-off thyristor, a triac, a static induction thyristor, and the like.

Among these, a rectifier diode and transistors are preferable, and a field effect transistor is more preferable.

Preferred examples of the field effect transistor include an organic thin film transistor.

An aspect of the organic thin film transistor of the present invention will be described with reference to a drawing.

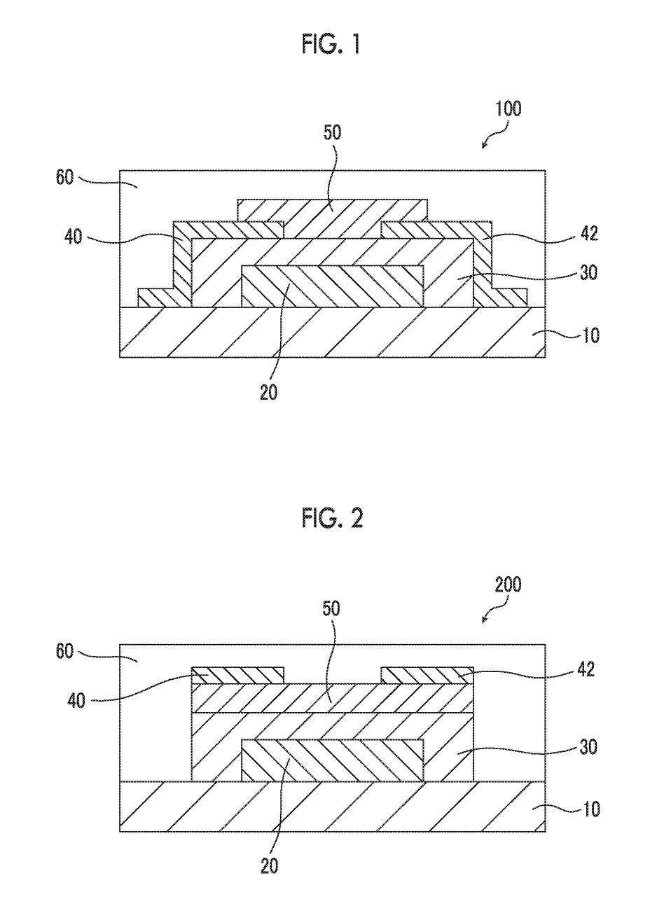

FIG. 1 is a schematic cross-sectional view of an aspect of an organic semiconductor element (organic thin film transistor (TFT)) of the present invention.

In FIG. 1, an organic thin film transistor 100 includes a substrate 10, a gate electrode 20 disposed on the substrate 10, a gate insulating film 30 covering the gate electrode 20, a source electrode 40 and a drain electrode 42 which contact a surface of the gate insulating film 30 that is on the side opposite to the gate electrode 20 side, an organic semiconductor film 50 covering a surface of the gate insulating film 30 between the source electrode 40 and the drain electrode 42, and a sealing layer 60 covering each member. The organic thin film transistor 100 is a bottom gate-bottom contact type organic thin film transistor.

In FIG. 1, the organic semiconductor film 50 corresponds to a film formed of the composition described above.

Hereinafter, the substrate, the gate electrode, the gate insulating film, the source electrode, the drain electrode, the organic semiconductor film, the sealing layer, and methods for forming each of these will be specifically described.

<Substrate>

The substrate plays a role of supporting the gate electrode, the source electrode, the drain electrode, and the like which will be described later.

The type of the substrate is not particularly limited, and examples thereof include a plastic substrate, a glass substrate, a ceramic substrate, and the like. Among these, from the viewpoint of applicability to each device and costs, a glass substrate or a plastic substrate is preferable.

Examples of materials of the plastic substrate include a thermosetting resin (for example, an epoxy resin, a phenol resin, a polyimide resin, or a polyester resin (for example, polyethylene terephthalate (PET) or polyethylene naphthalate (PEN)) and a thermoplastic resin (for example, a phenoxy resin, a polyethersulfone, polysulfone, or polyphenylene sulfone).

Examples of materials of the ceramic substrate include alumina, aluminum nitride, zirconia, silicon, silicon nitride, silicon carbide, and the like.

Examples of materials of the glass substrate include soda lime glass, potash glass, borosilicate glass, quartz glass, aluminosilicate glass, lead glass, and the like.

<Gate Electrode, Source Electrode, and Drain Electrode>

Examples of materials of the gate electrode, the source electrode, and the drain electrode include a metal such as gold (Au), silver, aluminum (Al), copper, chromium, nickel, cobalt, titanium, platinum, tantalum, magnesium, calcium, barium, or sodium; a conductive oxide such as InO₂, SnO₂, or indium tin oxide (ITO); a conductive polymer such as polyaniline, polypyrrole, polythiophene, polyacetylene, or polydiacetylene; a semiconductor such as silicon, germanium, or gallium arsenide; a carbon material such as fullerene, carbon nanotubes, or graphite; and the like. Among these, a metal is preferable, and silver and aluminum are more preferable.

A thickness of each of the gate electrode, the source electrode, and the drain electrode is not particularly limited, but is preferably 20 to 200 nm.

A method for forming the gate electrode, the source electrode, and the drain electrode is not particularly limited, but examples thereof include a method of vacuum vapor-depositing or sputtering an electrode material onto a substrate, a method of coating a substrate with a composition for forming an electrode, a method of printing a composition for forming an electrode onto a substrate, and the like. Furthermore, in a case where the electrode is patterned, examples of the patterning method include a photolithography method; a printing method such as ink jet printing, screen printing, offset printing, or relief printing; a mask vapor deposition method; and the like.

<Gate Insulating Film>

Examples of materials of the gate insulating film include a polymer such as polymethyl methacrylate, polystyrene, polyvinylphenol, polyimide, polycarbonate, polyester, polyvinylalcohol, polyvinyl acetate, polyurethane, polysulfone, polybenzoxazole, polysilsesquioxane, an epoxy resin, or a phenol resin; an oxide such as silicon dioxide, aluminum oxide, or titanium oxide; a nitride such as silicon nitride; and the like. Among these materials, in view of the compatibility with the organic semiconductor film, a polymer is preferable.

In a case where a polymer is used as the material of the gate insulating film, it is preferable to use a cross-linking agent (for example, melamine) in combination. If the cross-linking agent is used in combination, the polymer is cross-linked, and durability of the formed gate insulating film is improved.

A film thickness of the gate insulating film is not particularly limited, but is preferably 100 to 1,000 nm.

A method for forming the gate insulating film is not particularly limited, but examples thereof include a method of coating a substrate, on which the gate electrode is formed, with a composition for forming a gate insulating film, a method of vapor-depositing or sputtering the material of the gate insulating film onto a substrate on which the gate electrode is formed, and the like. A method for coating the aforementioned substrate with the composition for forming a gate insulating film is not particularly limited, and it is possible to use a known method (a bar coating method, a spin coating method, a knife coating method, or a doctor blade method).

In a case where the gate insulating film is formed by coating the substrate with the composition for forming a gate insulating film, for the purpose of removing the solvent, causing cross-linking, or the like, the composition may be heated (baked) after coating.

<Organic Semiconductor Film>

The organic semiconductor film of the present invention is a film formed of the composition for forming an organic semiconductor film of the present invention.

A method for forming the organic semiconductor film is not particularly limited. By applying the aforementioned composition onto the source electrode, the drain electrode, and the gate insulating film and, if necessary, performing a drying treatment, a desired organic semiconductor film can be formed.

<Polymer Layer>

The organic semiconductor element of the present invention preferably has the aforementioned polymer layer between a layer containing the aforementioned organic semiconductor and an insulating film, and more preferably has the aforementioned polymer layer between the aforementioned organic semiconductor and the gate insulating film. A film thickness of the polymer layer is not particularly limited, but is preferably 20 to 500 nm. The polymer layer should be a layer containing the polymer, and is preferably a layer composed of the polymer.

A method for forming the polymer layer is not particularly limited, and it is possible to use a known method (a bar coating method, a spin coating method, a knife coating method, a doctor blade method, or an ink jet method).

In a case where the polymer layer is formed by coating the substrate with the composition for forming a polymer layer, for the purpose of removing the solvent, causing cross-linking, or the like, the composition may be heated (baked) after coating.

<Sealing Layer>

From the viewpoint of durability, the organic thin film transistor of the present invention preferably includes a sealing layer as an outermost layer. In the sealing layer, a known sealant can be used.

A thickness of the sealing layer is not particularly limited, but is preferably 0.2 to 10 μm.

A method for forming the sealing layer is not particularly limited, but examples thereof include a method of coating a substrate, on which the gate electrode, the gate insulating film, the source electrode, the drain electrode, and the organic semiconductor film are formed, with a composition for forming a sealing layer, and the like. Specific examples of the method of coating the substrate with the composition for forming a sealing layer are the same as the examples of the method of coating the substrate with the composition for forming a gate insulating film. In a case where the organic semiconductor film is formed by coating the substrate with the composition for forming a sealing layer, for the purpose of removing the solvent, causing cross-linking, or the like, the composition may be heated (baked) after coating.

FIG. 2 is a schematic cross-sectional view of another aspect of the organic semiconductor element (organic thin film transistor) of the present invention.

In FIG. 2, an organic thin film transistor 200 includes the substrate 10, the gate electrode 20 disposed on the substrate 10, the gate insulating film 30 covering the gate electrode 20, the organic semiconductor film 50 disposed on the gate insulating film 30, the source electrode 40 and the drain electrode 42 disposed on the organic semiconductor film 50, and the sealing layer 60 covering each member. Herein, the source electrode 40 and the drain electrode 42 are formed using the aforementioned composition of the present invention. The organic thin film transistor 200 is a top contact-type organic thin film transistor.

The substrate, the gate electrode, the gate insulating film, the source electrode, the drain electrode, the organic semiconductor film, and the sealing layer are as described above.

In FIGS. 1 and 2, the aspects of the bottom gate-bottom contact type organic thin film transistor and the bottom gate-top contact type organic thin film transistor were specifically described. However, the composition of the present invention can also be applied to a top gate-bottom contact type organic thin film transistor and a top gate-top contact type organic thin film transistor.

The aforementioned organic thin film transistor can be suitably used in electronic paper, a display device, and the like.

### EXAMPLES

Hereinafter, the present invention will be more specifically described based on examples. The materials and the amount thereof used, the proportion of the materials, the content and procedure of treatments, and the like described in the following examples can be appropriately changed within a scope that does not depart from the gist of the present invention. Accordingly, the scope of the present invention is not limited to the following specific examples. Herein, unless otherwise specified, “part” and “%” are based on mass.

The SP value is the Hansen solubility parameter according to expressions described in Hansen solubility parameter: A User's Handbook, Second Edition, C. M. Hansen (2007), Taylor and Francis Group, LLC (HSPiP manual), and a value obtained by calculating the SP value from the following expression using “Hansen Solubility Parameters in Practice, HSPiP, the 3^{rd} edition” (software version 4.0.05) is used.

(SP value)²=(δHd)²+(δHp)²+(δHh)²

(In the expression, Hd represents a dispersion contribution, Hp represents a polarity contribution, and Hh represents a hydrogen bond contribution.)

The surface energy is measured by a method described below. A 1% polymer solution is added dropwise onto a glass substrate, and the substrate was coated with the solution by spin coating (1,000 rpm, 120 seconds), followed by heating for 30 minutes at 150° C., thereby forming a polymer film. Contact angles of water and diiodomethane with respect to the surfaces of various polymer films are measured using a contact angle gauge DM-501 manufactured by Kyowa Interface Science Co., LTD. A surface energy dispersion component (γ_{S}^{d}) and a polar component (γ_{S}^{h}) are determined from Owens expression and Young expression which are an extended expression of Fowkes expression, using the obtained contact angle and surface tension value of the liquid, and the sum of the both components is regarded as a surface energy (γ_{S}).

### Examples 1 to 30 and Comparative Examples 1 to 7

<Preparation of Composition for Forming Organic Semiconductor Film>

The components A to D listed in Table 1 were weighed out in a glass vial at a predetermined ratio listed in the following Table 1 and stirred and mixed together for 10 minutes by using MIX ROTOR (manufactured by AS ONE Corporation). The mixture was filtered through a 0.5 μm membrane filter, thereby obtaining a composition for forming an organic semiconductor film. The “-” in Table 1 means that other components were not added to the composition, and the numerical values in the “Concentration” columns of the component A and the component B represents concentration (% by mass) of each of components with respect to a total mass of the composition. In addition, the “Mixing ratio of component D” represents a proportion (% by volume) of the component D with respect to the total value of volumes of the component C and the component D used in a solvent, and the “ASP” represents a difference in SP values of the component C and the component D.

<Formation of TFT Element>

A bottom gate-bottom contact type TFT element was formed in the following manner.

[Formation of Gate Electrode]

A silver nanoink (H-1, manufactured by Mitsubishi Materials Corporation) was printed on an alkali-free glass substrate (5 cm×5 cm) by an ink jet method using DMP 2831 (1 pL head, manufactured by FUJIFILM GRAPHIC SYSTEMS CO., LTD., inkjet printer), thereby forming a wiring pattern having a width of 100 μm and a film thickness of 100 nm. Then, the wiring pattern was fired in the atmosphere on a hot plate for 90 minutes at 200° C., thereby forming gate electrode wiring.

[Formation of Gate Insulating Film]

5 parts by mass of polyvinyl phenol (Mw of 25,000, manufactured by Sigma-Aldrich Co. LLC.), 5 parts by mass of melamine, and 90 parts by mass of polyethylene glycol monomethyl ether acetate were stirred and mixed together and filtered through a 0.2 μm membrane filter, thereby preparing a solution. The obtained solution was added dropwise onto the glass substrate on which a gate electrode was prepared, and the substrate was coated with the solution by spin coating (1,000 rpm, 120 seconds), followed by heating for 30 minutes at 150° C., thereby forming a gate insulating film.

[Formation of Source and Drain (SD) Electrode]

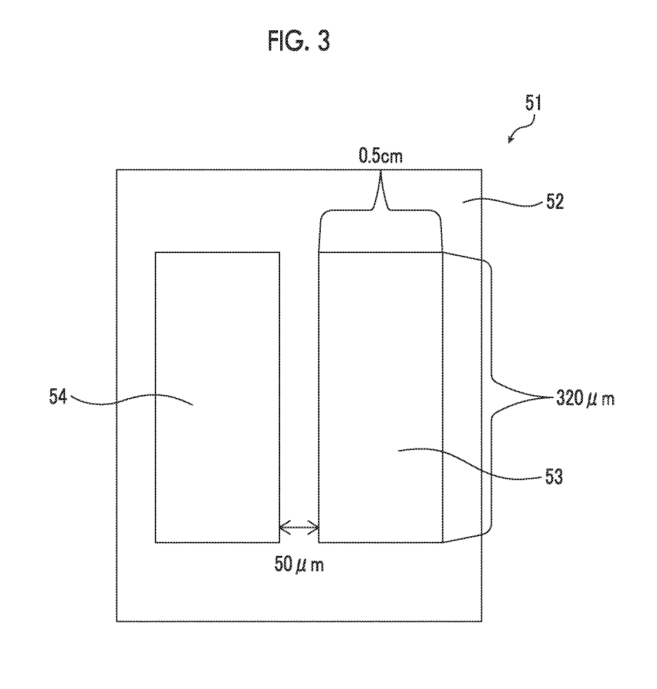

A metal mask having a plurality of patterns shown in FIG. 3 was loaded on the center of the substrate coated with the aforementioned insulating film and irradiated with UV (ultraviolet rays) ozone for 30 minutes. In this way, opening portions of the mask were modified and became a hydrophilic processed surface. In the periphery of the modified portions, through ink jet printing using DMP 2831 (1 pL head), patterns of a source and drain electrode having a channel length of 50 μm and a channel width of 320 μm were formed. The obtained substrate was fired for 90 minutes at 200° C. on a hot plate in a N₂ atmosphere (in a glove box, an environment having an oxygen concentration of equal to or less than 20 ppm), thereby forming a copper electrode having a film thickness of 200 nm.

[Organic Semiconductor Layer: Ink Jet Method]

The substrate on which the aforementioned source and drain electrode was formed was coated with the composition for forming an organic semiconductor film prepared as above by an ink jet method. By using DPP 2831 (manufactured by Fujifilm Graphic Systems) as an ink jet device and a 10 pL head, a solid film was formed at a jetting frequency of 2 Hz and a dot pitch of 20 μm. Then, the film was dried for 1 hour at 70° C., thereby preparing an organic semiconductor film.

[Organic Semiconductor Layer: Flexographic Printing Method]

The substrate on which the aforementioned source and drain electrode was formed was coated with the composition for forming an organic semiconductor film prepared as above by a flexographic printing method. As a printing device, a flexographic printability tester F1 (manufactured by IGT Testing Systems K.K.) was used, and as a flexographic resin plate, AFP DSH 1.70% (manufactured by Asahi Kasei Corporation.)/solid image was used. Printing was performed at a transport rate of 0.4 m/sec under a pressure between the plate and the substrate of 60 N, and then the substrate was dried as it was for 2 hours at a room temperature of lower than 40° C., thereby preparing an organic semiconductor film.

<Evaluation>

[Measurement of Mobility]

By using a semiconductor characteristic evaluation device B2900A (manufactured by Agilent Technologies), carrier mobility was measured. According to the value of the mobility, the organic semiconductor films were scored on a scale of 1 to 5. As the value of mobility is greater, the performance as the organic semiconductor becomes better.

5: a mobility of equal to or greater than 0.2 cm²/Vs

4: a mobility of equal to or greater than 0.1 cm²/Vs and less than 0.2 cm²/Vs

3: a mobility of equal to or greater than 0.02 cm²/Vs and less than 0.1 cm²/Vs

2: a mobility of equal to or greater than 0.002 cm²/Vs and less than 0.02 cm²/Vs

1: a mobility of less than 0.002 cm²/Vs

[Evaluation of Heat Stability]

The TFT element used for preparing an organic semiconductor film were further heated for 1 hour at 120° C., and then a change of mobility was evaluated. Specifically, for each of the 30 organic transistors, a difference between a mobility Y after heating and a mobility X before heating was divided by the mobility X, and the thus obtained value was multiplied by 100 [{(Y−X)/X}×100]. The values obtained in this way were averaged, and the average was taken as a rate of change. As the rate of change is less, the heat stability becomes better.

5: a rate of change of less than 20%

4: a rate of change of equal to or greater than 20% and less than 30%

3: a rate of change of equal to or greater than 30% and less than 50%

2: a rate of change of equal to or greater than 50% and less than 100%

1: a rate of change of equal to or greater than 100%

The evaluation results are summarized in Table 1.

TABLE 1

| | Component A | | | | | | | | Mixing | | | | | |
|---|---|---|---|---|---|---|---|---|---|---|---|---|---|---|
| | Type of | | Component D | | | Component C | | | ratio of | Component B | | | | |
| | semicon- | Concen- | Type of | Boiling | SP | Type of | Boiling | SP | component | Type of | Concen- | | Mo- | Heat |
| | ductor | tration | solvent | point | value | solvent | point | value | D | polymer | tration | ΔSP | bility | stability |
| Comparative | osc15 | 0.2 | — | — | — | C-1 | 259 | 20.8 | — | PaMS | 0.1 | — | 2 | 2 |
| Example 1 | | | | | | | | | | | | | | |
| Comparative | osc15 | 0.2 | — | — | — | C-1 | 259 | 20.8 | — | EPT0045 | 0.1 | — | 2 | 2 |
| Example 2 | | | | | | | | | | | | | | |
| Comparative | osc15 | 0.2 | D-2 | 205 | 17.5 | — | — | — | — | EPT0045 | 0.1 | — | 2 | 2 |
| Example 3 | | | | | | | | | | | | | | |
| Comparative | osc15 | 0.2 | D-1 | 181 | 17.7 | C-1 | 259 | 20.8 | 20 | — | — | 3.1 | 3 | 2 |
| Example 4 | | | | | | | | | | | | | | |
| Comparative | osc15 | 0.2 | D-2 | 205 | 17.5 | C-1 | 259 | 20.8 | 20 | — | — | 3.3 | 3 | 2 |
| Example 5 | | | | | | | | | | | | | | |
| Comparative | osc15 | 0.2 | D-2 | 205 | 17.5 | C-4 | 175 | 19.5 | 20 | PaMS | 0.1 | 2.0 | 3 | 2 |
| Example 6 | | | | | | | | | | | | | | |
| Comparative | osc15 | 0.2 | D-1 | 181 | 17.7 | C-5 | 181 | 18.4 | 20 | PaMS | 0.1 | 0.7 | 3 | 2 |
| Example 7 | | | | | | | | | | | | | | |
| Example 1 | osc15 | 0.2 | D-1 | 181 | 17.7 | C-1 | 259 | 20.8 | 20 | PaMS | 0.1 | 3.1 | 3 | 4 |
| Example 2 | osc15 | 0.2 | D-1 | 181 | 17.7 | C-1 | 259 | 20.8 | 20 | Polystyrene | 0.1 | 3.1 | 3 | 4 |
| Example 3 | osc15 | 0.2 | D-2 | 205 | 17.5 | C-1 | 259 | 20.8 | 20 | EPT0045 | 0.1 | 3.3 | 5 | 5 |
| Example 4 | osc15 | 0.2 | D-1 | 181 | 17.7 | C-1 | 259 | 20.8 | 20 | EPT0045 | 0.1 | 3.1 | 4 | 5 |
| Example 5 | osc15 | 0.2 | D-3 | 196 | 16.8 | C-1 | 259 | 20.8 | 20 | EPT0045 | 0.1 | 4.0 | 4 | 4 |
| Example 6 | osc15 | 0.2 | D-3 | 196 | 16.8 | C-1 | 259 | 20.8 | 20 | EP22 | 0.1 | 4.0 | 5 | 5 |
| Example 7 | osc15 | 0.2 | D-3 | 196 | 16.8 | C-1 | 259 | 20.8 | 20 | EP43 | 0.1 | 4.0 | 5 | 5 |
| Example 8 | osc15 | 0.2 | D-3 | 196 | 16.8 | C-2 | 204 | 20 | 20 | EPT0045 | 0.1 | 3.2 | 4 | 3 |
| Example 9 | osc15 | 0.2 | D-1 | 181 | 17.7 | C-2 | 204 | 20 | 20 | EP22 | 0.1 | 2.3 | 4 | 3 |
| Example 10 | osc15 | 0.2 | D-2 | 205 | 17.5 | C-2 | 204 | 20 | 20 | EP43 | 0.1 | 2.5 | 4 | 4 |
| Example 11 | osc1 | 0.2 | D-3 | 196 | 16.8 | C-3 | 215 | 20.3 | 20 | EP22 | 0.1 | 3.5 | 4 | 4 |
| Example 12 | osc2 | 0.2 | D-3 | 196 | 16.8 | C-3 | 215 | 20.3 | 20 | EP22 | 0.1 | 3.5 | 4 | 5 |
| Example 13 | osc3 | 0.2 | D-3 | 196 | 16.8 | C-3 | 215 | 20.3 | 20 | EP22 | 0.1 | 3.5 | 5 | 4 |
| Example 14 | osc4 | 0.2 | D-3 | 196 | 16.8 | C-3 | 215 | 20.3 | 20 | EP22 | 0.1 | 3.5 | 4 | 5 |
| Example 15 | osc5 | 0.2 | D-3 | 196 | 16.8 | C-3 | 215 | 20.3 | 20 | EP22 | 0.1 | 3.5 | 5 | 4 |
| Example 16 | osc6 | 0.2 | D-3 | 196 | 16.8 | C-3 | 215 | 20.3 | 20 | EP43 | 0.1 | 3.5 | 5 | 4 |
| Example 17 | osc7 | 0.2 | D-1 | 181 | 17.7 | C-3 | 215 | 20.3 | 20 | EP43 | 0.1 | 2.6 | 4 | 5 |
| Example 18 | osc8 | 0.2 | D-1 | 181 | 17.7 | C-3 | 215 | 20.3 | 20 | EP43 | 0.1 | 2.6 | 4 | 5 |
| Example 19 | osc9 | 0.2 | D-1 | 181 | 17.7 | C-3 | 215 | 20.3 | 20 | EP43 | 0.1 | 2.6 | 5 | 4 |
| Example 20 | osc10 | 0.2 | D-1 | 181 | 17.7 | C-3 | 215 | 20.3 | 20 | EP43 | 0.1 | 2.6 | 5 | 4 |
| Example 21 | osc11 | 0.2 | D-1 | 181 | 17.7 | C-3 | 215 | 20.3 | 20 | EP43 | 0.1 | 2.6 | 5 | 4 |
| Example 22 | osc12 | 0.2 | D-1 | 181 | 17.7 | C-3 | 215 | 20.3 | 20 | EP43 | 0.1 | 2.6 | 5 | 4 |
| Example 23 | osc13 | 0.2 | D-2 | 205 | 17.5 | C-1 | 259 | 20.8 | 20 | EPT0045 | 0.1 | 3.3 | 5 | 4 |
| Example 24 | osc14 | 0.2 | D-2 | 205 | 17.5 | C-1 | 259 | 20.8 | 20 | EPT0045 | 0.1 | 3.3 | 5 | 4 |
| Example 25 | osc16 | 0.2 | D-2 | 205 | 17.5 | C-1 | 259 | 20.8 | 20 | EPT0045 | 0.1 | 3.3 | 4 | 5 |
| Example 26 | osc17 | 0.2 | D-2 | 205 | 17.5 | C-1 | 259 | 20.8 | 20 | EPT0045 | 0.1 | 3.3 | 5 | 4 |
| Example 27 | osc18 | 0.2 | D-2 | 205 | 17.5 | C-1 | 259 | 20.8 | 20 | EPT0045 | 0.1 | 3.3 | 5 | 4 |
| Example 28 | osc15 | 0.2 | D-3 | 196 | 16.8 | C-1 | 259 | 20.8 | 20 | EP43 | 0.05 | 4.0 | 5 | 5 |
| Example 29 | osc15 | 0.2 | D-3 | 196 | 16.8 | C-1 | 259 | 20.8 | 20 | EP43 | 0.2 | 4.0 | 4 | 4 |
| Example 30 | osc15 | 0.2 | D-3 | 196 | 16.8 | C-1 | 259 | 20.8 | 20 | EP43 | 0.3 | 4.0 | 3 | 4 |

The abbreviations listed in Table 1 are as described below.

OSC-1 to OSC-17 used in examples are the same compounds as OSC-1 to OSC-17 described above.

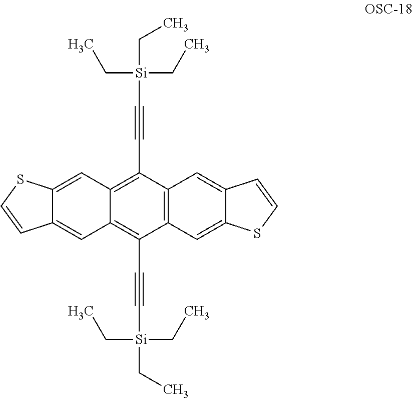 [SMILES: CC[Si](C#Cc1c2cc3ccsc3cc2c(C#C[Si](CC)(CC)CC)c2cc3ccsc3cc12)(CC)CC]

The synthetic methods and the manufacturers of the organic semiconductors (OSC-1 to OSC-18) were obtained as below.

OSC-1 was synthesized with reference to Journal of American Chemical Society, 116, 925 (1994), Journal of Chemical Society, 221 (1951), and the like.

OSC-2 was synthesized with reference to known documents (Org. Lett., 2001, 3, 3471, Macromolecules, 2010, 43, 6264, and Tetrahedron, 2002, 58, 10197).

OSC-3 was synthesized with reference to JP2012-513459A, JP2011-46687A, Journal of Chemical Research. miniprint, 3, 601-635 (1991), Bull. Chem. Soc. Japan, 64, 3682-3686 (1991), Tetrahedron Letters, 45, 2801-2803 (2004), and the like.

OSC-4 was synthesized with reference to EP2251342A, EP2301926A, EP2301921A, KR10-2012-0120886A, and the like.

OSC-5 was synthesized with reference to known documents (J. Org. Chem., 2011, 696, Org. Lett., 2001, 3, 3471, Macromolecules, 2010, 43, 6264, J. Org. Chem., 2013, 78, 7741, and Chem. Eur. J., 2013, 19, 3721).

OSC-6 was synthesized with reference to known documents (Bull. Chem. Soc. Jpn., 1987, 60, 4187, J. Am. Chem. Soc. 2011, 133, 5024, and Chem. Eur. J. 2013, 19, 3721).

OSC-7 and OSC-8 were synthesized with reference to known documents (Macromolecules, 2010, 43, 6264-6267 and J. Am, Chem. Soc., 2012, 134, 16548-16550).

OSC-9 was synthesized with reference to document A (K. Muellen, Chem. Commun., 2008, 1548-1550.), document B (K. Takimiya, Org. Lett., 2007, 9, 4499-4502.), document C (Rao; Tilak, Journal of Scientific and Industrial Research, 1958, vol. 17 B, p. 260-265), and document D (Ghaisas; Tilak, Journal of Scientific and Industrial Research, 1955, vol. 14 B, p. 11).

OSC-10 to OSC-13 were synthesized with reference to a known document (Journal of American Chemical Society, 129, 15732 (2007)).

OSC-14 was synthesized based on the method described in WO2005/087780A.

OSC-15 was synthesized based on the method described in JP2009-190999A.

OSC-16 was synthesized based on the method described in JP2012-206953A.

As OSC-17, C8BTBT (manufactured by Sigma-Aldrich Co. LLC.) was used.

As OSC-18, 5,11-bis(triethylsilylethynyl)anthradithiophene (manufactured by Sigma-Aldrich Co. LLC.) was used.

D-1: m-Diethylbenzene (D0478, manufactured by Tokyo Chemical Industry Co., Ltd.)

D-2: Amyl benzene (A0449, manufactured by Tokyo Chemical Industry Co., Ltd.)

D-3: cis-Decaline (D0009, manufactured by Tokyo Chemical Industry Co., Ltd.)

C-1: 1-Chloronaphthalene (C0212, manufactured by Tokyo Chemical Industry Co., Ltd.)

C-2: 1-Methyl naphthalene (132-10065, manufactured by Wako Pure Chemical Industries, Ltd.)

C-3: 1-Fluoronaphthalene (F0212, manufactured by Tokyo Chemical Industry Co., Ltd.)

C-4: 4-Methoxy toluene (038-09725, manufactured by Wako Pure Chemical Industries, Ltd.)

C-5: 1,2-Dichlorobenzene (D1116, manufactured by Tokyo Chemical Industry Co., Ltd.)

EPT0045: Ethylene-propylene rubber, manufactured by Mitsui Chemicals, Inc., surface energy of 23 mN/m

PaMS: Poly(α-methyl styrene), weight-average molecular weight of 400,000, manufactured by Sigma-Aldrich Co. LLC., surface energy of 34 mN/m

EP22: Ethylene-propylene rubber, JSR EP22, manufactured by JSR Corporation, surface energy of 24 mN/m

EP43: Ethylene-propylene rubber, JSR EP43, manufactured by JSR Corporation, surface energy of 29 mN/m

Polystyrene: weight-average molecular weight of 400,000, manufactured by Sigma-Aldrich Co. LLC., surface energy of 38 mN/m

### EXPLANATION OF REFERENCES

10: substrate
20: gate electrode
30: gate insulating film
40: source electrode
42: drain electrode
50: organic semiconductor film
51: metal mask
52: mask portion
53, 54: opening portion
60: sealing layer
100, 200: organic thin film transistor

What is claimed is:

1. A composition for forming an organic semiconductor film comprising:
an organic semiconductor as a component A;
a binder polymer as a component B;
a solvent having a naphthalene structure as a component C; and
a solvent having a lower SP value than that of the component C by 2.0 MPa^{1/2} or greater and a lower boiling point than that of the component C, as a component D,
wherein the organic semiconductor has a condensed polycyclic aromatic group, the number of rings in the condensed polycyclic aromatic group is equal to or greater than 4, at least two rings in the condensed polycyclic aromatic group contains at least one atom selected from the group consisting of a sulfur atom, a nitrogen atom, a selenium atom, and an oxygen atom, and the condensed polycyclic aromatic group has, as a partial structure, at least one structure selected from the group consisting of a benzene ring, a naphthalene ring, and a phenanthrene ring.

2. The composition for forming an organic semiconductor film according to claim 1, wherein the component D is alkane or cycloalkane having 6 to 20 carbon atoms.

3. The composition for forming an organic semiconductor film according to claim 1, wherein the component D is alkylbenzene.

4. The composition for forming an organic semiconductor film according to claim 1, wherein surface energy E of the component B is equal to or lower than 30 mN/m².

5. The composition for forming an organic semiconductor film according to claim 1, wherein the component B is at least one resin selected from the group consisting of natural rubber, synthetic rubber, a silicone resin, a thermoplastic elastomer, and a urea resin.

6. The composition for forming an organic semiconductor film according to claim 1, wherein the component B is at least one selected from the group consisting of ethylene-propylene rubber, acrylonitrile-butadiene rubber, hydrogenated nitrile rubber, fluororubber, a perfluoroelastomer, a tetrafluoroethylene propylene copolymer, an ethylene-propylene-diene copolymer, styrene-butadiene rubber, polychloroprene, polyneoprene, butyl rubber, a methyl•phenylsilicone resin, a methyl•phenylvinyl•silicone resin, a methyl•vinyl•silicone resin, a fluorosilicone resin, acrylic rubber, ethylene acrylic rubber, chlorosulfonated polyethylene, chloropolyethylene, an epichlorohydrin copolymer, a polyisoprene-natural rubber copolymer, polyisoprene rubber, a styrene-isoprene block copolymer, a polyester urethane copolymer, a polyether urethane copolymer, a polyetherester thermoplastic elastomer, and polybutadiene rubber.

7. The composition for forming an organic semiconductor film according to claim 1, wherein the number of rings in the condensed polycyclic aromatic group is 5 or 6.

8. The composition for forming an organic semiconductor film according to claim 1,
wherein the organic semiconductor contains at least two heterocyclic rings, and
the heterocyclic rings each contain one heteroatom.

9. The composition for forming an organic semiconductor film according to claim 1, wherein the organic semiconductor contains at least one kind of compound represented by any one of Formulae 1 to 16, 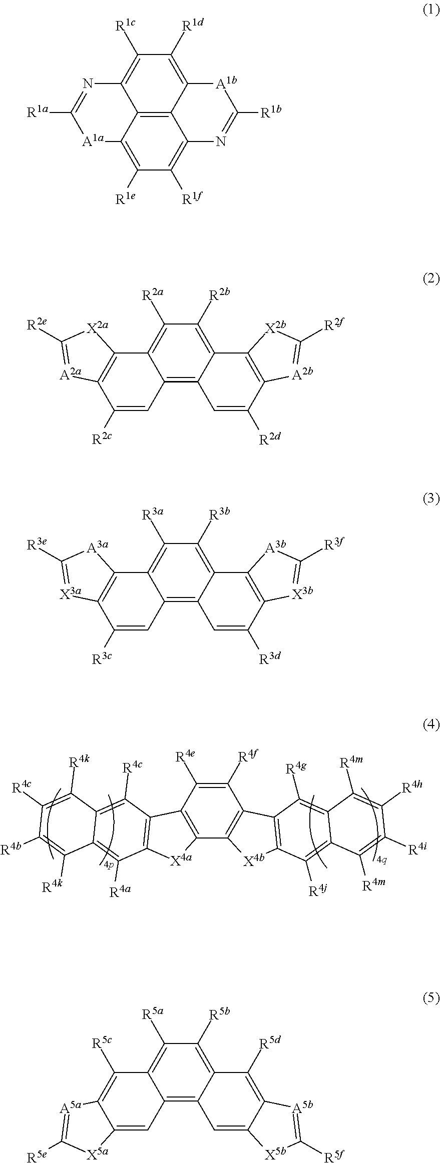 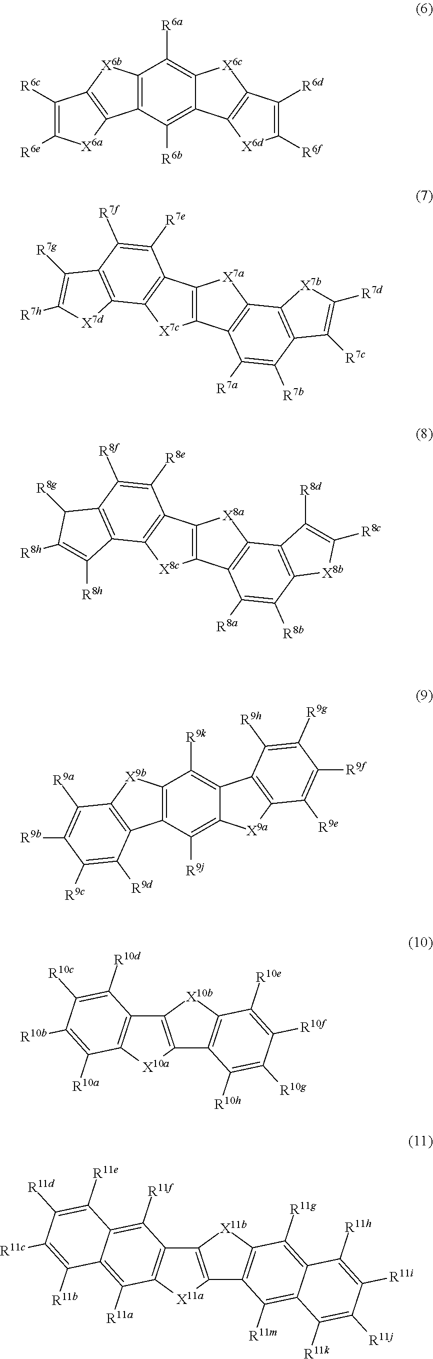 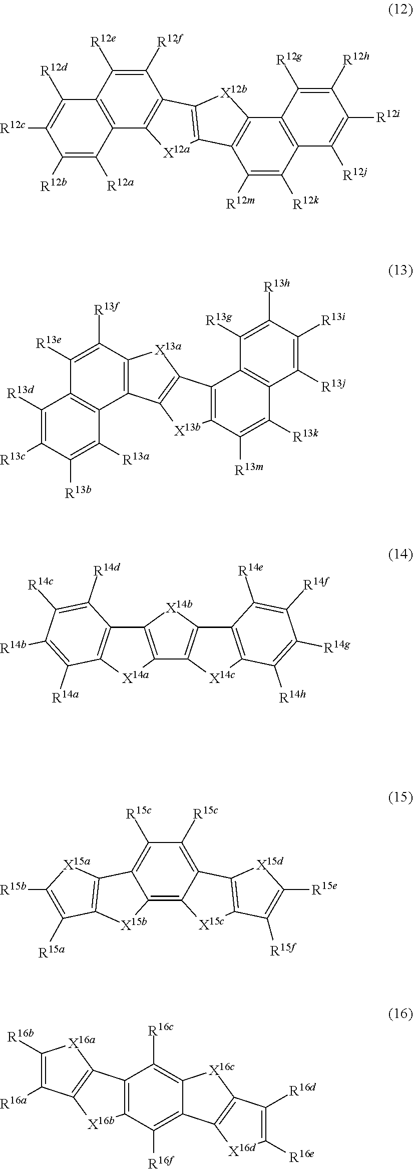
in Formula 1, A^{1a} and A^{1b} each independently represent a S atom, an O atom, or a Se atom, R^{1a} to R^{1f} each independently represent a hydrogen atom or a substituent, and at least one of R^{1a}, R^{1b}, R^{1c}, R^{1d}, R^{1e}, or R^{1f} is a group represented by the following Formula W,
-L^{W}-R^{W} (W)
in Formula W, L^{W} represents a divalent linking group which is represented by any one of the following Formula L-1 to L-25 or a divalent linking group in which two or more divalent linking groups represented by any one of the following Formulae L-1 to L-25 are bonded to each other, and R^{W} represents an alkyl group, a cyano group, a vinyl group, an ethynyl group, an oxyethylene group, an oligo-oxyethylene group in which a repetition number v of an oxyethylene unit is equal to or greater than 2, a siloxane group, an oligosiloxane group having two or more silicon atoms, or a trialkylsilyl group, 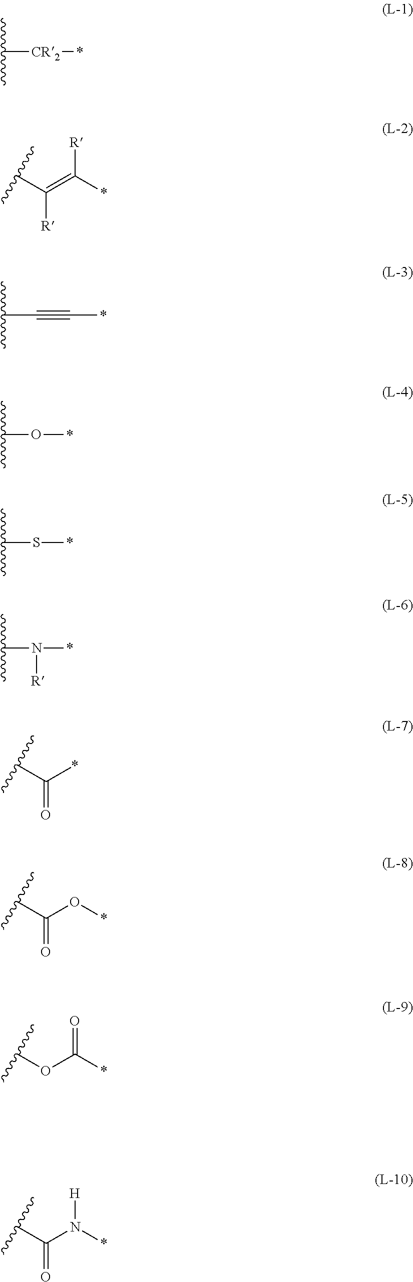 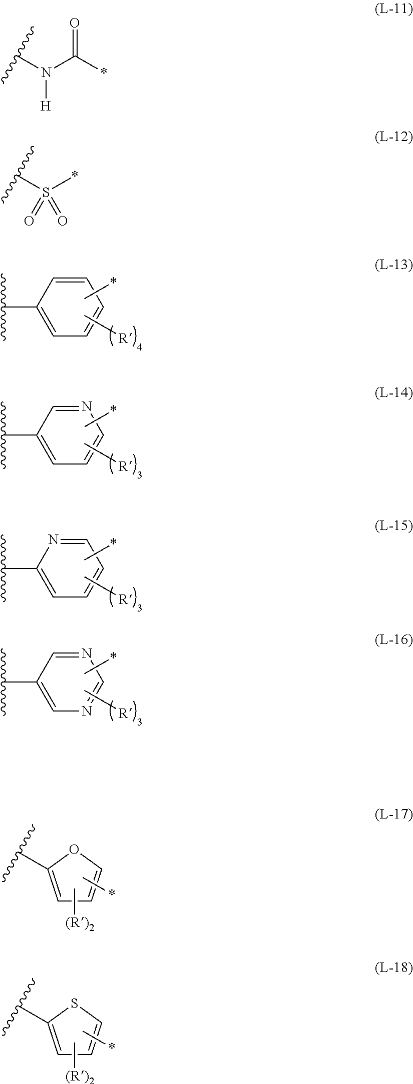 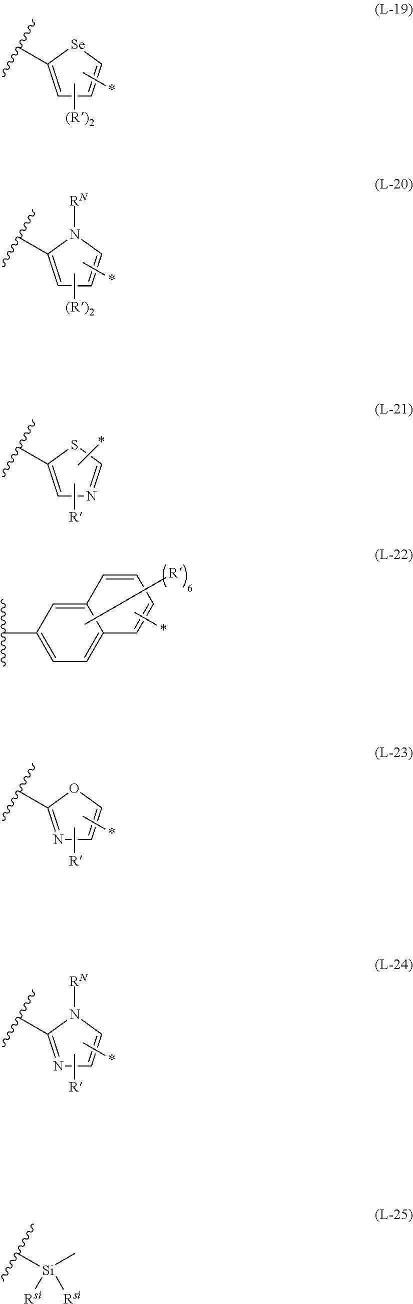
in Formulae L-1 to L-25, * represents a binding position for R^{W}, the portion of a wavy line represents the other binding position, R′ in Formulae L-1, L-2, L-6, and L-13 to L-24 each independently represent a hydrogen atom or a substituent, R^{N} in Formulae L-20 and L-24 represents a hydrogen atom or a substituent, and R^{si} in Formula L-25 each independently represent a hydrogen atom, an alkyl group, an alkenyl group, or an alkynyl group,
in Formula 2, X^{2a} and X^{2b} each independently represent NR²¹, an O atom, or a S atom, A^{2a} represents CR^{2g} or a N atom, A^{2b} represents CR^{2h} or a N atom, R²ⁱ represents a hydrogen atom, an alkyl group, an alkenyl group, an alkynyl group, or an acyl group, R^{2a} to R^{2h} each independently represent a hydrogen atom or a substituent, and at least one of R^{2a}, R^{2b}, R^{2c}, R^{2d}, R^{2e}, R^{2f}, R^{2g}, or R^{2h} is a group represented by Formula W,
in Formula 3, X^{3a} and X^{3b} each independently represent a S atom, an O atom, or NR^{3g}, A^{3a} and A^{3b} each independently represent CR^{3h} or a N atom, R^{3a} to R^{3h} each independently represent a hydrogen atom or a substituent, and at least one of R^{3a}, R^{3b}, R^{3c}, R^{3d}, R^{3e}, R^{3f}, R^{3g}, or R^{3h} is a group represented by Formula W,
in Formula 4, X^{4a} and X^{4b} each independently represent an O atom, a S atom, or a Se atom, 4p and 4q each independently represent an integer of 0 to 2, R^{4a} to R^{4j}, R^{4k}, and R^{4m} each independently represent a hydrogen atom, a halogen atom, or a group represented by Formula W, at least one of R^{4a}, R^{4b}, R^{4c}, R^{4d}, R^{4e}, R^{4f}, R^{4g}, R^{4h}, R⁴ⁱ, R^{4j}, R^{4k}, or R^{4m} is a group represented by Formula W, and in a case where at least one of R^{4e} or R^{4f} is a group represented by Formula W, L^{W} in Formula W represented by R^{4e} and R^{4f} is a divalent linking group represented by Formula L-2 or L-3,
in Formula 5, X^{5a} and X^{5b} each independently represent NR⁵ⁱ, an O atom, or a S atom, A^{5a} represents CR^{5g} or a N atom, A^{5b} represents CR^{5h} or a N atom, R⁵ⁱ represents a hydrogen atom, an alkyl group, an alkenyl group, an alkynyl group, an acyl group, an aryl group, or a heteroaryl group, R^{5a} to R^{5h} each independently represent a hydrogen atom or a substituent, and at least one of R^{5a}, R^{5b}, R^{5c}, R^{5d}, R^{5e}, R^{5f}, R^{5g}, or R^{5h} is a group represented by Formula W,
in Formula 6, X^{6a} to X^{6d} each independently represent NR^{6g}, an O atom, or a S atom, R^{6g} represents a hydrogen atom, an alkyl group, an alkenyl group, an alkynyl group, an acyl group, an aryl group, or a heteroaryl group, R^{6a} to R^{6f} each independently represent a hydrogen atom or a substituent, and at least one of R^{6a}, R^{6b}, R^{6c}, R^{6d}, R^{6e}, or R^{6f} is a group represented by Formula W,
in Formula 7, X^{7a} and X^{7c} each independently represent a S atom, an O atom, a Se atom, or NR⁷ⁱ, X^{7b} and X^{7d} each independently represent a S atom, an O atom, or a Se atom, R^{7a} to R⁷ⁱ each independently represent a hydrogen atom or a substituent, and at least one of R^{7a}, R^{7b}, R^{7c}, R^{7d}, R^{7e}, R^{7f}, R^{7g}, R^{7h}, or R⁷ⁱ is a group represented by Formula W,
in Formula 8, X^{8a} and X^{8c} each independently represent a S atom, an O atom, a Se atom, or NR⁸ⁱ, X^{8b} and X^{8d} each independently represent a S atom, an O atom, or a Se atom, R^{8a} to R⁸ⁱ each independently represent a hydrogen atom or a substituent, and at least one of R^{8a}, R^{8b}, R^{8c}, R^{8d}, R^{8e}, R^{8f}, R^{8g}, R^{8h}, or R⁸ⁱ is a group represented by Formula W,
in Formula 9, X^{9a} and X^{9b} each independently represent an O atom, a S atom, or a Se atom, R^{9c}, R^{9d}, and R^{9g} to R^{9j} each independently represent a hydrogen atom, a halogen atom, or a group represented by Formula W, and R^{9a}, R^{9b}, R^{9e}, and R^{9f} each independently represent a hydrogen atom or a substituent,
in Formula 10, R^{10a} to R^{10h} each independently represent a hydrogen atom or a substituent, at least one of R^{10a}, R^{10b}, R^{10c}, R^{10d}, R^{10e}, R^{10f}, R^{10g}, or R^{11h} represents a substituent represented by Formula W, X^{10a} and X^{10b} each independently represent a S atom, an O atom, a Se atom, or NR¹⁰ⁱ, and R¹⁰ⁱ each independently represents a hydrogen atom or a group represented by Formula W,
in Formula 11, X^{11a} and X^{11b} each independently represent a S atom, an O atom, a Se atom, or NR¹¹ⁿ, R^{11a} to R^{11k}, R^{11m}, and R¹¹ⁿ each independently represent a hydrogen atom or a substituent, and at least one of R^{11a}, R^{11b}, R^{11c}, R^{11d}, R^{11e}, R^{11f}, R^{11g}, R^{11h}, R¹¹ⁱ, R^{11j}, R^{11k}, R^{11m}, or R¹¹ⁿ is a group represented by Formula W,
in Formula 12, X^{12a} and X^{12b} each independently represent a S atom, an O atom, a Se atom, or NR¹²ⁿ, R^{12a} to R^{12k}, R^{12m}, and R¹²ⁿ each independently represent a hydrogen atom or a substituent, and at least one of R^{12a}, R^{12b}, R^{12c}, R^{12d}, R^{12e}, R^{12f}, R^{12g}, R^{12h}, R¹²ⁱ, R^{12j}, R^{12k}, R^{12m}, or R¹²ⁿ is a group represented by Formula W,
in Formula 13, X^{13a} and X^{13b} each independently represent a S atom, an O atom, a Se atom, or NR¹³ⁿ, R^{13a} to R^{13k}, R^{13m}, and R¹³ⁿ each independently represent a hydrogen atom or a substituent, and at least one of R^{13a}, R^{13b}, R^{13c}, R^{13d}, R^{13e}, R^{13f}, R^{13g}, R^{13h}, R¹³ⁱ, R^{13j}, R^{13k}, R^{13m}, or R¹³ⁿ is a group represented by Formula W,
in Formula 14, X^{14a} to X^{14c} each independently represent a S atom, an O atom, a Se atom, or NR¹⁴ⁱ, R^{14a} to R¹⁴ⁱ each independently represent a hydrogen atom or a substituent, and at least one of R^{14a}, R^{14b}, R^{14c}, R^{14d}, R^{14e}, R^{14f}, R^{14g}, R^{14h}, or R¹⁴ⁱ is a group represented by Formula W,
in Formula 15, X^{15a} to X^{15d} each independently represent a S atom, an O atom, a Se atom or NR^{15g}, R^{15a} to R^{15g} each independently represent a hydrogen atom or a substituent, and at least one of R^{15a}, R^{15b}, R^{15c}, R^{15d}, R^{15e}, R^{15f} or R^{15g} is a group represented by Formula W, and
in Formula 16, X^{16a} to X^{16d} each independently represent a S atom, an O atom, a Se atom, or NR^{16g}, R^{16a} to R^{16g} each independently represent a hydrogen atom or a substituent, and at least one of R^{16a}, R^{16b}, R^{16c}, R^{16d}, R^{16e}, R^{16f}, or R^{16g} is a group represented by Formula W.

10. The composition for forming an organic semiconductor film according to claim 9, wherein the organic semiconductor contains at least one kind of compound represented by any one of Formulae 1 to 9 and 15.

11. A method for manufacturing an organic semiconductor element, comprising:
a coating step of coating a substrate with the composition for forming an organic semiconductor film according to claim 1.

12. An organic semiconductor element which is manufactured by the method for manufacturing an organic semiconductor element according to claim 11.
